(19) United States
(12) Patent Application Publication
(10) Pub. No.: US 2026/0353639 A1
(43) Pub. Date: Nov. 5, 2026

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tsutomu MURAKAWA, Isehara (JP); Hiromi SAWAI, Kawasaki (JP)

(21) Appl. No.: 19/486,440

(22) PCT Filed: Jun. 3, 2024
(86) PCT No.: PCT/IB2024/055388

§ 371 Date: Nov. 21, 2025

(30) Foreign Application Priority Data
Jun. 9, 2023 (JP) 2023-095848

(51) Int. Cl. H10B 12/00; H10B 80/00; H10D 1/68; H10D 30/67; H10D 80/30

(52) U.S. Cl. CPC H10B 12/33; H10B 12/036; H10B 12/05; H10D 1/716; H10D 30/6728; H10D 30/6731; H10D 30/6737; H10B 80/00; H10D 80/30

(57) ABSTRACT

A semiconductor device that operates at high speed is provided. The semiconductor device includes first to third insulators, a capacitor, and a transistor over the capacitor; the capacitor includes a first conductor, a fourth insulator over the first conductor, and a second conductor over the fourth insulator; the first insulator is positioned over the second conductor; the second insulator is provided with a first opening portion; the first conductor, the fourth insulator, the second conductor, and the first insulator are positioned in the first opening portion; the transistor includes a third conductor over the first insulator, a fourth conductor over the third conductor, an oxide semiconductor over the first insulator, a fifth insulator over the oxide semiconductor, and a fifth conductor over the fifth insulator; the third conductor, the third insulator, and the fourth conductor are provided with a second opening portion; the oxide semiconductor, the fifth insulator, and the fifth conductor are positioned in the second opening portion; the third conductor is in contact with the top surface of the second conductor; the oxide semiconductor is in contact with a side surface of the third conductor and a side surface of the fourth conductor; and the fifth conductor is positioned to overlap with the first insulator.

### TECHNICAL FIELD

One embodiment of the present invention relates to a semiconductor device, a memory device, and an electronic appliance. Another embodiment of the present invention relates to a method for manufacturing the semiconductor device.

Note that one embodiment of the present invention is not limited to the above technical field. Examples of the technical field of one embodiment of the present invention include a semiconductor device, a display device, a light-emitting device, a power storage device, a memory device, an electronic appliance, a lighting device, an input device (e.g., a touch sensor), an input/output device (e.g., a touch panel), a method for driving any of them, and a method for manufacturing any of them.

Note that in this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be sometimes said that a display device (e.g., a liquid crystal display device and a light-emitting display device), a projection device, a lighting device, an electro-optical device, a power storage device, a memory device, a semiconductor circuit, an imaging device, an electronic appliance, and the like include a semiconductor device.

### BACKGROUND ART

In recent years, semiconductor devices have been developed, and LSIs (Large Scale Integrations), CPUs (Central Processing Units), memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a material of a semiconductor thin film applicable to the transistor, and an oxide semiconductor has been attracting attention as another material.

It is known that a transistor using an oxide semiconductor has extremely low leakage current in a non-conduction state. For example, Patent Document 1 discloses a low-power-consumption CPU utilizing a feature of low leakage current of the transistor using an oxide semiconductor. For another example, Patent Document 2 discloses a memory device that can retain stored contents for a long time by utilizing a feature of a low leakage current of the transistor using an oxide semiconductor.

In recent years, demand for an integrated circuit with higher density has risen with reductions in size and weight of electronic appliances. In addition, the productivity of a semiconductor device including an integrated circuit is desired to be increased. For example, Patent Document 3 and Non-Patent Document 1 disclose a technique to achieve an integrated circuit with a higher density by making a plurality of memory cells overlap with each other by stacking a first transistor using an oxide semiconductor film and a second transistor using an oxide semiconductor film. For another example, Patent Document 4 discloses a technique to achieve an integrated circuit with a higher density by placing a channel of a transistor using an oxide semiconductor film in the vertical direction.

### REFERENCE

### Patent Document

[Patent Document 1] Japanese Published Patent Application No. 2012-257187.

[Patent Document 2] Japanese Published Patent Application No. 2011-151383.

[Patent Document 3] PCT International Publication No. 2021/053473.

[Patent Document 4] Japanese Published Patent Application No. 2013-211537.

### Non-Patent Document

[Non-Patent Document 1] M. Oota et. al., “3D-Stacked CAAC-In—Ga—Zn Oxide FETs with Gate Length of 72 nm”, IEDM Tech. Dig., 2019, pp. 50-53.

[Non-Patent Document 2] Hiroshi Funakubo, Takanori Mimura, Takao Shimizu, and Takanori Kiguchi, “Elucidation of Fundamental Characteristics of Hafnium Oxide-based Ferroelectrics” [Translated from Japanese.], Applied Physics, Vol. 87, No. 12, pp. 921-925, (2018).

### SUMMARY OF THE INVENTION

### Problems to be Solved by the Invention

An object of one embodiment of the present invention is to provide a semiconductor device that operates at high speed. Another object of one embodiment of the present invention is to provide a semiconductor device with a high on-state current. Another object of one embodiment of the present invention is to provide a semiconductor device that can be miniaturized or highly integrated. Another object of one embodiment of the present invention is to provide a semiconductor device with favorable electrical characteristics. Another object of one embodiment of the present invention is to provide a highly reliable semiconductor device. Another object of one embodiment of the present invention is to provide a semiconductor device with a small variation in electrical characteristics of transistors. Another object of one embodiment of the present invention is to provide a semiconductor device with low power consumption. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device.

Another object of one embodiment of the present invention is to provide a memory device that operates at high speed. Another object of one embodiment of the present invention is to provide a memory device that can be miniaturized or highly integrated. Another object of one embodiment of the present invention is to provide a memory device with a high memory capacity. Another object of one embodiment of the present invention is to provide a memory device with low power consumption. Another object of one embodiment of the present invention is to provide a novel memory device.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device which includes first to third insulators, a capacitor, and a transistor over the capacitor and in which the capacitor includes a first conductor, a fourth insulator over the first conductor, and a second conductor over the fourth insulator, the first insulator is positioned over the second conductor, the second insulator is provided with a first opening portion, at least a part of each of the first conductor, the fourth insulator, the second conductor, and the first insulator is positioned in the first opening portion, the transistor includes a third conductor over the first insulator, a fourth conductor over the third conductor and the third insulator, an oxide semiconductor over the first insulator, a fifth insulator over the oxide semiconductor, and a fifth conductor over the fifth insulator, the third conductor, the third insulator, and the fourth conductor are provided with a second opening portion reaching the first insulator, at least a part of each of the oxide semiconductor, the fifth insulator, and the fifth conductor is positioned in the second opening portion, the third conductor is in contact with a top surface of the second conductor, the oxide semiconductor is in contact with a side surface of the third conductor and a side surface of the fourth conductor, and the fifth conductor is positioned to overlap with the first insulator.

In the above, at least a part of a bottom surface of the oxide semiconductor is preferably removed in the second opening portion.

In the above, the fifth insulator is preferably in contact with a top surface of the first insulator.

In the above, the fourth conductor preferably includes a first layer and a second layer over the first layer, the first layer preferably has higher conductivity than the second layer, and the second layer preferably contains a metal oxide.

In the above, the first layer preferably contains tungsten. In the above, the second layer preferably includes indium.

In the above, a sixth insulator is preferably positioned between the second layer and the fifth conductor.

In the above, the third conductor preferably contains a metal oxide.

In the above, the third conductor preferably contains indium.

In the above, the fourth insulator can contain a metal oxide containing hafnium and zirconium.

In the above, a width of the first opening portion in the vicinity of the top surface of the first insulator is preferably larger than a width of the first opening portion in the vicinity of a bottom surface of the first insulator.

In the above, a depth of the first opening portion is preferably larger than a depth of the second opening portion.

In the above, the top surface of the first insulator and the top surface of the second conductor are preferably flush with each other.

In the above, a side surface of the second conductor, a side surface of the fourth insulator, and a side surface of the third conductor are flush with each other.

### Effect of the Invention

One embodiment of the present invention can provide a semiconductor device that operates at high speed. Another embodiment of the present invention can provide a semiconductor device with a high on-state current. Another embodiment of the present invention can provide a semiconductor device that can be miniaturized or highly integrated. Another embodiment of the present invention can provide a semiconductor device with favorable electrical characteristics. Another embodiment of the present invention can provide a highly reliable semiconductor device. Another embodiment of the present invention can provide a semiconductor device with a small variation in electrical characteristics of transistors. Another embodiment of the present invention can provide a semiconductor device with low power consumption. Another embodiment of the present invention can provide a novel semiconductor device. Another embodiment of the present invention can provide a method for manufacturing a semiconductor device with high productivity. Another embodiment of the present invention can provide a method for manufacturing a novel semiconductor device.

Another embodiment of the present invention can provide a memory device that operates at high speed. Another embodiment of the present invention can provide a memory device that can be miniaturized or highly integrated. Another embodiment of the present invention can provide a memory device with a high memory capacity. Another embodiment of the present invention can provide a memory device with low power consumption. Another embodiment of the present invention can provide a novel memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A and FIG. 1B are cross-sectional views illustrating an example of a semiconductor device.

FIG. 2A is a plan view illustrating an example of a semiconductor device. FIG. 2B and FIG. 2C are cross-sectional views illustrating the example of the semiconductor device. FIG. 2D is a circuit diagram of the example of the semiconductor device.

FIG. 3A and FIG. 3B are cross-sectional views illustrating examples of semiconductor devices.

FIG. 4 is a cross-sectional view illustrating an example of a semiconductor device.

FIG. 5A to FIG. 5D are cross-sectional views illustrating an example of a method for manufacturing a semiconductor device.

FIG. 6A to FIG. 6D are cross-sectional views illustrating the example of the method for manufacturing the semiconductor device.

FIG. 7A to FIG. 7F are cross-sectional views illustrating the example of the method for manufacturing the semiconductor device.

FIG. 8A to FIG. 8F are cross-sectional views illustrating the example of the method for manufacturing the semiconductor device.

FIG. 9A and FIG. 9B are cross-sectional views illustrating an example of a semiconductor device.

FIG. 10A and FIG. 10B are cross-sectional views illustrating an example of a semiconductor device.

FIG. 11A and FIG. 11B are cross-sectional views illustrating an example of a semiconductor device.

FIG. 12A and FIG. 12B are cross-sectional views illustrating an example of a semiconductor device.

FIG. 13A is a plan view illustrating an example of a semiconductor device. FIG. 13B is a cross-sectional view illustrating the example of the semiconductor device.

FIG. 14A, FIG. 14B, FIG. 14C, and FIG. 14D are conceptual diagrams each illustrating a cross section of an oxide semiconductor layer.

FIG. 15 is a diagram illustrating crystal structures of HfO₂ disclosed in Non-Patent Document 2.

FIG. 16 is a block diagram illustrating a structure example of a semiconductor device.

FIG. 17A to FIG. 17E are diagrams each illustrating an example of a circuit structure of a memory cell.

FIG. 18A and FIG. 18B are perspective views each illustrating a structure example of a semiconductor device.

FIG. 19 is a cross-sectional view illustrating an example of a semiconductor device.

FIG. 20 is a cross-sectional view illustrating an example of a semiconductor device.

FIG. 21 is a block diagram illustrating a CPU.

FIG. 22A and FIG. 22B are perspective views of a semiconductor device.

FIG. 23A and FIG. 23B are perspective views of semiconductor devices.

FIG. 24A and FIG. 24B are diagrams each illustrating a hierarchy of a variety of memory devices.

FIG. 25A and FIG. 25B are diagrams each illustrating an example of an electronic appliance, and

FIG. 25C to FIG. 25E are diagrams illustrating an example of a large computer.

FIG. 26 is a diagram illustrating an example of space equipment.

FIG. 27 is a diagram illustrating an example of a storage system that can be used in a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Thus, the disclosed invention is not necessarily limited to the position, size, range, or the like disclosed in the drawings.

Furthermore, especially in a plan view, a perspective view, or the like, the description of some components is omitted for easy understanding of the invention in some cases. The description of some hidden lines is also omitted in some cases.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances. The term “oxide semiconductor” can be interchanged with the term “oxide semiconductor layer” or the term “oxide semiconductor film” depending on the case or the circumstances.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

The term “opening” includes a groove, a slit, and a depressed portion, for example. A region where an opening is formed is referred to as an opening portion in some cases.

In the drawings used in this specification, a sidewall of an insulator in an opening portion in the insulator is illustrated as being perpendicular or substantially perpendicular to a substrate surface or a formation surface, but the sidewall may have a tapered shape.

In this specification and the like, a tapered shape refers to a shape such that at least part of a side surface of a component is inclined to a substrate surface or a formation surface. For example, the tapered shape preferably includes a region where the angle between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or substantially flat with slight unevenness. In this specification and the like, an inverse tapered shape refers to a shape in which a side portion or an upper portion extends beyond a bottom portion in the direction parallel to a substrate.

In this specification and the like, the expression “level” indicates a structure in which levels from a reference surface (e.g., a flat surface such as a substrate surface) are the same in a cross-sectional view. For example, in a manufacturing process of a memory device, planarization treatment (typically, chemical mechanical polishing (CMP) treatment) is performed, whereby the surface of a single layer or the surfaces of a plurality of layers is/are exposed in some cases. In that case, the surfaces on which the CMP treatment is performed are at the same level from a reference surface. Note that a plurality of layers may be at different levels depending on a treatment apparatus, a treatment method, or a material of the treated surfaces, used for the CMP treatment. This case is also regarded as being “level” in this specification and the like. For example, the expression “level” includes the case where two layers (here, a first layer and a second layer) having different levels with respect to a reference surface are included and the difference between the top-surface level of the first layer and the top-surface level of the second layer is less than or equal to 20 nm.

In this specification and the like, the expression “side end portions are aligned” means that outlines of stacked layers at least partly overlap with each other in a plan view. For example, the case of processing an upper layer and a lower layer with the use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “side end portions are aligned”.

In general, it is difficult to clearly differentiate “completely aligned” from “substantially aligned”. Thus, in this specification and the like, the expression “aligned” includes both “completely aligned” and “substantially aligned”.

In this specification and the like, the expression “a first thickness and a second thickness are equal to each other” means that a value obtained by dividing the absolute value of the difference between the first thickness and the second thickness by the first thickness is less than or equal to 0.1. Alternatively, the expression means that a value obtained by dividing the absolute value of the difference between the first thickness and the second thickness by the second thickness is less than or equal to 0.1.

In this specification and the like, the expression “a distance A and a distance B are equal to each other” means that a value obtained by dividing the absolute value of the difference between the distance A and the distance B by the distance A is less than or equal to 0.1. Alternatively, the expression means that a value obtained by dividing the absolute value of the difference between the distance A and the distance B by the distance B is less than or equal to 0.1.

### Embodiment 1

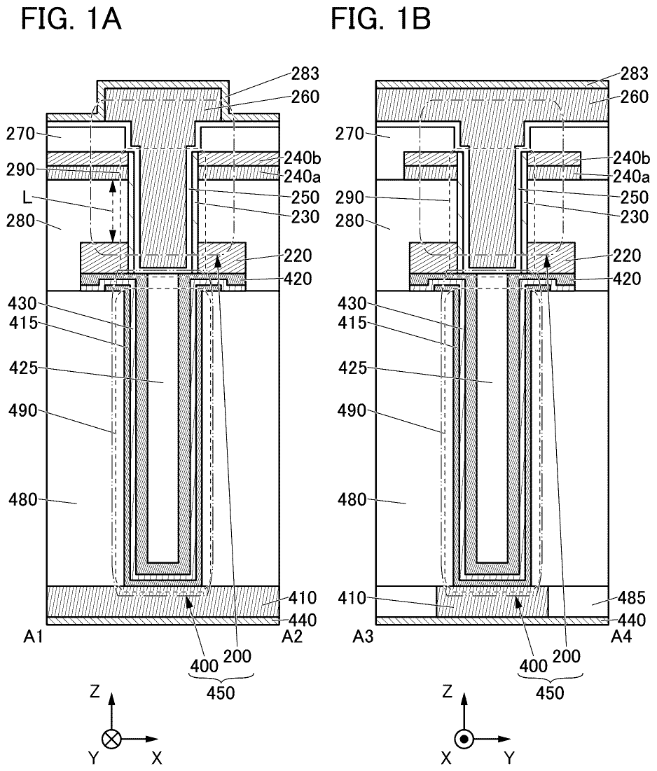

In this embodiment, examples of semiconductor devices of one embodiment of the present invention that can be used as memory devices will be described with reference to FIG. 1A to FIG. 13B.

### <Structure Examples of Semiconductor Devices>

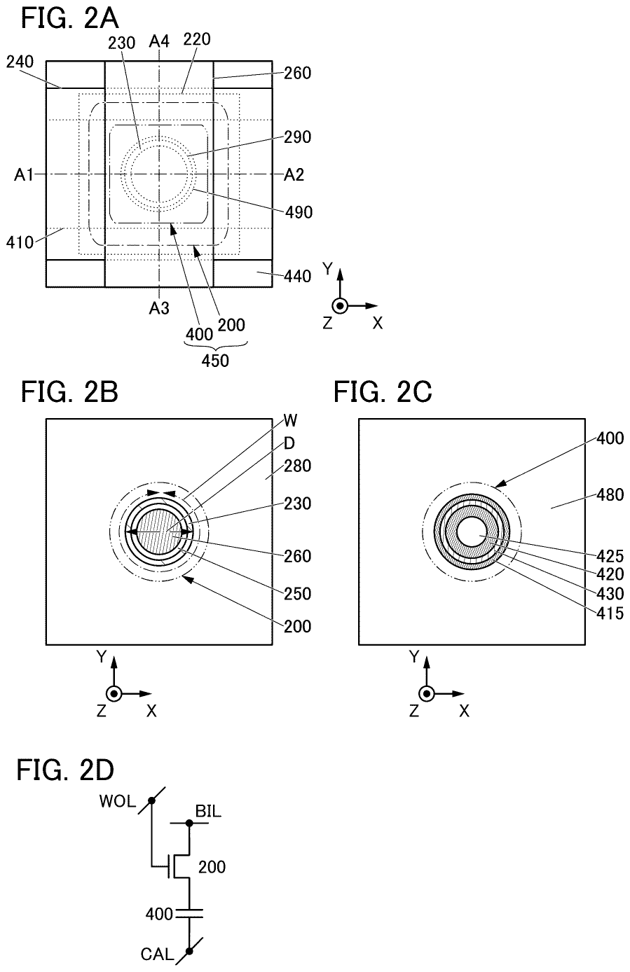

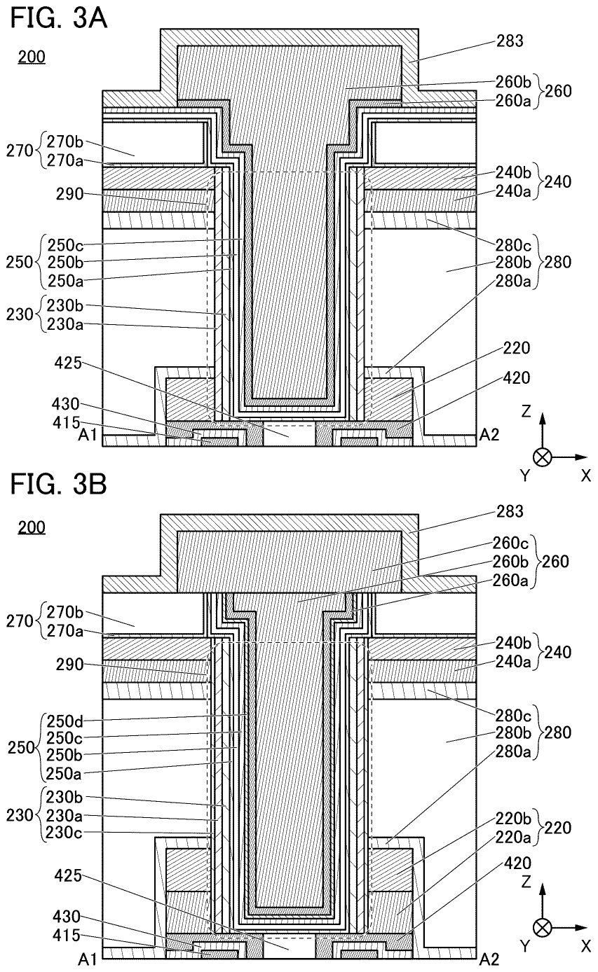

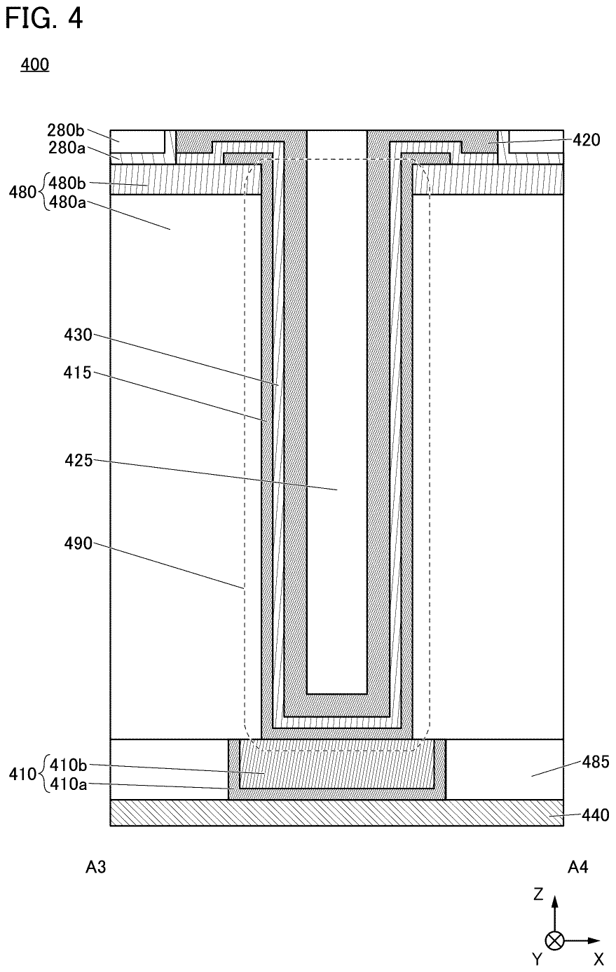

Structure examples of semiconductor devices of one embodiment of the present invention will be described with reference to FIG. 1A to FIG. 4. FIG. 1A to FIG. 2C are a plan view and cross-sectional views of a semiconductor device including a transistor 200 and a capacitor 400. FIG. 2A is a plan view of the semiconductor device. Here, FIG. 1A is a cross-sectional view of a portion indicated by the dashed-dotted line A1-A2 in FIG. 2A. FIG. 1B is a cross-sectional view of a portion indicated by the dashed-dotted line A3-A4 in FIG. 2A. FIG. 2B is a cross-sectional view of part of the transistor 200 along the XY plane in FIG. 2A. FIG. 2C is a cross-sectional view of part of the capacitor 400 along the XY plane in FIG. 2A. Note that some components are omitted in the plan view of FIG. 1A for clarity of the drawing. FIG. 3A and FIG. 3B are enlarged views corresponding to the transistor 200 illustrated in FIG. 1A. FIG. 4 is an enlarged view corresponding to the capacitor 400 illustrated in FIG. 1B. FIG. 2D is a circuit diagram corresponding to the semiconductor device illustrated in FIG. 1 and FIG. 2.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device illustrated in FIG. 1A and FIG. 1B includes an insulator 440 over a substrate (not illustrated), an insulator 485 and a conductor 410 over the insulator 440, an insulator 480 and the capacitor 400 over the insulator 485 and the conductor 410, the transistor 200 over the capacitor 400, an insulator 280 over the insulator 480, an insulator 270 over the insulator 280, and an insulator 283 over the transistor 200. The insulator 440, the insulator 485, the insulator 480, the insulator 280, and the insulator 270 each function as an interlayer insulating film. The insulator 440 also functions as a base insulator.

The transistor 200 includes a conductor 220 over the capacitor 400, a conductor 240 over the insulator 280, an oxide semiconductor 230 in contact with the conductor 220 and the conductor 240, an insulator 250 over the oxide semiconductor 230 and the insulator 270, and a conductor 260 over the insulator 250. The conductor 240 includes a conductor 240a and a conductor 240b over the conductor 240a. The capacitor 400 includes a conductor 415 over the conductor 410, an insulator 430 over the conductor 415, and the conductor 420 over the insulator 430. In addition, an insulator 425 is provided over the conductor 420.

In the transistor 200, the conductor 260 functions as a gate electrode, the insulator 250 functions as a gate insulator, the conductor 220 functions as one of a source electrode and a drain electrode, and the conductor 240 functions as the other of the source electrode and the drain electrode.

In the transistor 200, a metal oxide functioning as a semiconductor (also referred to as an oxide semiconductor) is preferably used as the oxide semiconductor 230 including a channel formation region. A transistor including an oxide semiconductor in its channel formation region, like the transistor 200, is hereinafter referred to as an OS transistor in some cases.

As illustrated in FIG. 1A and FIG. 1B, the insulator 280, the conductor 240a, the conductor 240b, and the conductor 220 are provided with an opening portion 290 reaching the insulator 425 and the conductor 420. Here, a bottom portion of the opening portion 290 is the top surfaces of the insulator 425 and the conductor 420. A sidewall of the opening portion 290 is a side surface of the insulator 280, a side surface of the conductor 240a, a side surface of the conductor 240b, and a side surface of the conductor 220. The opening portion 290 includes an opening portion of the insulator 280, an opening portion of the conductor 240a, an opening portion of the conductor 240b, and an opening portion of the conductor 220. In other words, the opening portion of the insulator 280 in a region overlapping with the insulator 425 and the conductor 420 is part of the opening portion 290, the opening portion of the conductor 240a in a region overlapping with the insulator 425 and the conductor 420 is another part of the opening portion 290, the opening portion of the conductor 240b in a region overlapping with the insulator 425 and the conductor 420 is another part of the opening portion 290, and the opening portion of the conductor 220 in a region overlapping with the insulator 425 and the conductor 420 is the other part of the opening portion 290.

At least parts of the components of the transistor 200 are positioned in the opening portion 290. Specifically, at least part of each of the oxide semiconductor 230, the insulator 250, and the conductor 260 is positioned in the opening portion 290.

Portions of the oxide semiconductor 230, the insulator 250, and the conductor 260 that are positioned in the opening portion 290 reflect at least part of the shape of the opening portion 290. That is, the oxide semiconductor 230 is provided in contact with the sidewall of the opening portion 290, the insulator 250 is provided to cover the oxide semiconductor 230, and the conductor 260 is provided to fill a depressed portion that is defined by the insulator 250 and reflets the shape of the opening portion 290.

Here, the transistor 200 has a structure in which current flows in the vertical direction since one of the source electrode and the drain electrode (here, the conductor 220) is positioned on the lower side and the other of the source electrode and the drain electrode (here, the conductor 240) is positioned on the upper side. That is, in the transistor 200, a channel is formed along a side surface of the opening portion 290 included in the insulator 280. Accordingly, the transistor of one embodiment of the present invention can be referred to as a vertical-channel transistor or a VFET (Vertical Field Effect Transistor).

In the capacitor 400, the conductor 420 functions as one of a pair of electrodes (sometimes referred to as an upper electrode), the conductor 415 functions as the other of the pair of electrodes (sometimes referred to as a lower electrode), and the insulator 430 functions as a dielectric. That is, the capacitor 400 forms a MIM (Metal-Insulator-Metal) capacitor.

As illustrated in FIG. 1A and FIG. 1B, the insulator 480 is provided with an opening portion 490 reaching the conductor 410. At least part of each of the conductor 415, the insulator 430, the conductor 420, and the insulator 425 is positioned in the opening portion 490. Here, the conductor 415, the insulator 430, and the conductor 420 are stacked along the shape of the opening portion 490. The capacitor 400 with such a structure can be referred to as a trench-type capacitor or a trench capacitor. Note that as illustrated in FIG. 1A and FIG. 1B, the insulator 425 is preferably provided to fill a depressed portion that is defined by the conductor 420 and reflects the shape of the opening portion 490.

The capacitor 400 has a structure in which the upper electrode and the lower electrode face each other with the dielectric therebetween on the side surface as well as on the bottom surface of the opening portion 490; thus, the capacitance per unit area can be increased. Thus, the deeper the opening portion 490 is, the larger the capacitance of the capacitor 400 can be. Increasing the capacitance per unit area of the capacitor 400 in this manner enables a stable reading operation of the memory device. This also allows further miniaturization or higher integration of the memory device.

As illustrated in FIG. 1A and FIG. 1B, the transistor 200 is provided to overlap with the capacitor 400. The opening portion 290 where part of the structure of the transistor 200 is provided includes a region overlapping with the opening portion 490 where part of the structure of the capacitor 400 is provided. Here, the conductor 260 preferably overlaps with the insulator 425. The bottom surface of the insulator 250 is preferably in contact with the top surface of the insulator 425. With such a structure, the transistor 200 and the capacitor 400 can be provided without a great increase in the occupation area in a plan view. Accordingly, the area occupied by the semiconductor device can be reduced, leading to high integration.

Here, in a region not overlapping with the opening portion 290, the bottom surface of the conductor 220 is in contact with the top surface of the conductor 420. This allows one of the source electrode and the drain electrode of the transistor 200 to be electrically connected to the upper electrode of the capacitor 400.

The transistor 200 and the capacitor 400 described in this embodiment can be used as a memory cell of a memory device (hereinafter, referred to as a memory cell 450 in some cases). FIG. 2D is a circuit diagram of the memory cell 450. As illustrated in FIG. 2D, in the memory cell 450, one of a source and a drain of the transistor 200 is electrically connected to one electrode of the capacitor 400. The other of the source and the drain of the transistor 200 is connected to a wiring BIL. A gate of the transistor 200 is connected to a wiring WOL. The other electrode of the capacitor 400 is connected to a wiring CAL.

The wiring BIL corresponds to the conductor 240 (the conductor 240a and the conductor 240b), the wiring WOL corresponds to the conductor 260, and the wiring CAL corresponds to the conductor 410. It is preferable that the conductor 260 be provided to extend in the Y direction and the conductor 240 be provided to extend in the X direction, as illustrated in FIG. 2A and the like. In this structure, the wiring BIL and the wiring WOL are provided to intersect with each other. Although the wiring CAL (the conductor 410) is provided to extend in the X direction in FIG. 2A, the present invention is not limited thereto. For example, wiring CAL may be provided to extend in the Y direction or may be provided to have a planar shape.

The transistor 200 and the capacitor 400 are provided to overlap with each other, whereby the area occupied by the memory cell 450 is reduced. When the transistor and the capacitor are provided to overlap with each other as described above, the structures of the transistor and the capacitor are positioned to overlap with each other, which might cause parasitic capacitance, resulting in low operation speed of a memory element. Thus, in this embodiment, by providing the insulator 425 between the conductor 260 and the conductor 420, the distance between the conductor 260 and the conductor 420 is increased in most of the region where the conductor 260 and the conductor 420 overlap with each other. This can reduce the parasitic capacitance between the gate of the transistor 200 and the upper electrode of the capacitor 400. Accordingly, the operation speed of the memory cell 450 including the transistor 200 and the capacitor 400 can be improved.

### [Structure Examples of Transistors]

As illustrated in FIG. 1A and FIG. 1B, the oxide semiconductor 230 included in the transistor 200 is formed along the sidewall of the opening portion 290. The oxide semiconductor 230 is in contact with the side surface of the conductor 240a on the opening portion 290 side, the side surface of the conductor 240b on the opening portion 290 side, the side surface of the insulator 280 on the opening portion 290 side, and the side surface of the conductor 220 on the opening portion 290 side. The oxide semiconductor 230 is not formed to cover the bottom surface of the opening portion 290 and has a cylindrical shape with an opening in the center. It can be said that at least part of the bottom surface of the oxide semiconductor 230 is removed in the opening portion 290.

As described above, the oxide semiconductor 230 is formed in a sidewall shape along the opening portion 290. Thus, the insulator 250 is positioned in contact with the inner side surface of the oxide semiconductor 230, and at the bottom surface of the opening portion 290, the insulator 250 is in contact with the top surface of the conductor 420 and the top surface of the insulator 425. The oxide semiconductor 230 is not formed to cover the conductor 240b and is not in contact with the top surface of the conductor 240b. Here, an upper end portion of the oxide semiconductor 230 is aligned or substantially aligned with the top surface of the conductor 240b in some cases.

When the oxide semiconductor is formed to the bottom surface of the opening portion 290, parasitic capacitance is formed between the oxide semiconductor in the bottom portion of the opening portion 290 and the conductor 420. Parasitic capacitance is formed also between the oxide semiconductor in the bottom portion of the opening portion 290 and the conductor 260. By contrast, when the oxide semiconductor 230 is formed in a sidewall shape as described above, the oxide semiconductor 230 is not formed in the bottom portion of the opening portion 290. Thus, the parasitic capacitance between the oxide semiconductor 230 and the conductor 420 and the parasitic capacitance between the oxide semiconductor 230 and the conductor 260 can be inhibited. Accordingly, a transistor with favorable electrical characteristics can be manufactured and the operation speed of the semiconductor device can be improved.

In the oxide semiconductor 230, a source region and a drain region are formed to sandwich the channel formation region. Here, one of the source region and the drain region includes at least part of a region of the oxide semiconductor 230 that is in contact with the conductor 240. The other of the source region and the drain region includes at least part of a region of the oxide semiconductor 230 that is in contact with the conductor 220. That is, the channel formation region of the transistor 200 is positioned in a region of the oxide semiconductor 230 between the conductor 220 and the conductor 240. In other words, the channel formation region of the transistor 200 is positioned in a region of the oxide semiconductor 230 that is in contact with the insulator 280 or a region in the vicinity thereof.

The channel length of the transistor 200 is the distance between the source region and the drain region. In other words, the channel length of the transistor 200 is determined by the thickness of the insulator 280 over the conductor 220. In FIG. 1A, a channel length L of the transistor 200 is indicated by a dashed double-headed arrow. In the cross-sectional view, the channel length L is the distance between an end portion of a region where the oxide semiconductor 230 is in contact with the conductor 220 and an end portion of a region where the oxide semiconductor 230 is in contact with the conductor 240. The channel length L can also be regarded as the distance between the top surface of the conductor 220 and the bottom surface of the conductor 240a in the cross-sectional view.

FIG. 2B is a cross-sectional view along the XY plane of a region between the conductor 220 and the conductor 240. As illustrated in FIG. 2B, the oxide semiconductor 230, the insulator 250, and the conductor 260 are provided concentrically inside the opening portion 290 of the insulator 280. Thus, the side surface of the conductor 260 provided at the center faces the side surface of the oxide semiconductor 230 with the insulator 250 therebetween. That is, in the region between the conductor 220 and the conductor 240, the entire circumference of the oxide semiconductor 230 serves as the channel formation region.

In this case, when the opening portion 290 does not penetrate the conductor 220 and the top surface of the conductor 220 is flat, the insulator 250 is formed over the conductor 220 and the bottom surface of the conductor 260 is at a higher level than the top surface of the conductor 220. In this case, the contact between the oxide semiconductor 230 and the conductor 220 is bottom contact that is mainly made at the bottom surface of the oxide semiconductor 230. In the vicinity of the conductor 220, the structure in which the oxide semiconductor 230, the insulator 250, and the conductor 260 are provided concentrically as illustrated in FIG. 2B is not formed. Accordingly, an offset region is formed in the oxide semiconductor 230 in the vicinity of the conductor 220, which might degrade electrical characteristics, such as an on-state current, a subthreshold swing value (hereinafter, sometimes referred to as S value), field-effect mobility, and frequency characteristics, of the transistor.

By contrast, as described above, the opening portion 290 is preferably formed to penetrate the conductor 220, and the conductor 260 and the oxide semiconductor 230 are preferably provided to fill the opening portion 290 of the conductor 220. With such a structure, as illustrated in FIG. 3A, the level of the bottom surface of the conductor 260 is lower than the level of the top surface of the conductor 220 in a region not overlapping with the opening portion 290. In this case, the contact between the oxide semiconductor 230 and the conductor 220 is side contact that is mainly made at the side surface of the oxide semiconductor 230. Furthermore, the above-described structure in which the insulator 250 is in contact with the insulator 425 and the conductor 420 allows the level of the bottom surface of the conductor 260 to be lower.

With the above-described structure, the oxide semiconductor 230, the insulator 250, and the conductor 260 can be provided concentrically even in a region in the vicinity of the conductor 220. That is, in the region in the vicinity of the conductor 220, the side surface of the conductor 260 and the side surface of the oxide semiconductor 230 can face each other with the insulator 250 therebetween. Accordingly, the electric field of the conductor 260 functioning as the gate electrode can be sufficiently applied to the oxide semiconductor 230 even in the vicinity of the conductor 220. Thus, formation of an offset region in the oxide semiconductor 230 in the vicinity of the conductor 220 can be inhibited. Accordingly, the electrical characteristics, such as an on-state current, an S value, field-effect mobility, and frequency characteristics, of the transistor 200 can be improved.

A planar transistor, whose channel length is limited by the light exposure limit of lithography, has been difficult to further miniaturize. In the present invention, the channel length can be set by the thickness of the insulator 280 over the conductor 220. Thus, the channel length L of the transistor 200 can be, for example, less than or equal to 1 μm, less than or equal to 500 nm, less than or equal to 100 nm, less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm. For example, when the transistor has an extremely minute structure with the channel length L below the light exposure limit of lithography, the on-state current, S value, frequency characteristics, and the like of the transistor 200 can be improved. For example, when the channel length L is increased, DIBL (Drain Induced Barrier Lowering) can be inhibited and the electrical characteristics can be improved in the transistor 200.

In addition, as described above, the channel formation region, the source region, and the drain region can be formed in the opening portion 290. Thus, the area occupied by the transistor 200 can be smaller than the area occupied by a planar transistor in which a channel formation region, a source region, and a drain region are provided separately on the XY plane. For example, in the transistor 200, the channel length L can be larger than the width in the X direction and the width in the Y direction while the area occupied by the transistor 200 is reduced. Accordingly, high integration of the semiconductor device can be achieved. In the case where the semiconductor device of one embodiment of the present invention is used for a memory device, the memory capacity per unit area can be increased.

As illustrated in FIG. 2B, the entire circumference of the oxide semiconductor 230 serves as the channel formation region in the region between the conductor 220 and the conductor 240. In this case, for example, the channel width of the transistor 200 is determined by the length of the outer circumference of the oxide semiconductor 230. In other words, the channel width of the transistor 200 is determined by the maximum width of the opening portion 290 (the maximum diameter in the case where the opening portion 290 is circular in the plan view). In FIG. 2B, a maximum width D of the opening portion 290 is indicated by a dashed double-dotted double-headed arrow. In FIG. 2B, a channel width W of the transistor 200 is indicated by a dashed-dotted double-headed arrow. By increasing the maximum width D of the opening portion 290, the channel width per unit area can be increased and the on-state current can be increased.

In the case where the opening portion 290 is formed by a lithography method, the maximum width D of the opening portion 290 is limited by the light exposure limit of lithography. In addition, the maximum width D of the opening portion 290 is determined by the thicknesses of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be “D×π”.

In the case where the opening portion 290 is formed to be circular in the plan view, the oxide semiconductor 230, the insulator 250, and the conductor 260 are provided concentrically. This makes the distance between the conductor 260 and the oxide semiconductor 230 substantially uniform, so that a gate electric field can be substantially uniformly applied to the oxide semiconductor 230.

Although this embodiment describes the example in which the opening portion 290 is circular in the plan view, the present invention is not limited thereto. For example, the opening portion 290 in the plan view may have a substantially circular shape such as an elliptical shape, a polygonal shape such as a quadrangular shape, or a polygonal shape such as a quadrangular shape with rounded corners. In that case, the maximum width of the opening portion 290 can be calculated as appropriate in accordance with the shape of the uppermost portion of the opening portion 290. For example, in the case where the opening portion is quadrangular in the plan view, the maximum width of the opening portion 290 can be regarded as the length of a diagonal line of the uppermost portion of the opening portion 290.

The sidewall of the opening portion 290 is preferably perpendicular or substantially perpendicular to the top surface of the insulator 440. Such a structure enables miniaturization or high integration of the semiconductor device.

Although the opening portion 290 is provided such that the sidewall of the opening portion 290 is perpendicular to the top surface of the conductor 220 in FIG. 1A and FIG. 1B, the present invention is not limited thereto. For example, the sidewall of the opening portion 290 is not strictly perpendicular and has a tapered shape in some cases. The taper angle formed by the side surface of the insulator 280, which is part of the sidewall of the opening portion 290, and the top surface of the conductor 220 (which may also be the top surface of the insulator 480 or the top surface of the insulator 440) is preferably 90° or an angle close to 90°. For example, the taper angle is preferably greater than or equal to 75° and less than or equal to 90°.

The taper angle is sometimes less than 75°, less than 70°, less than 65°, or less than 60°. When the sidewall of the opening portion 290 has a tapered shape, the oxide semiconductor 230 and the insulator 250 can be deposited with good coverage.

As the oxide semiconductor 230, a single layer or stacked layers of any of metal oxides described later in the section [Metal oxide] can be used.

As the oxide semiconductor 230, specifically, a metal oxide with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be used. Note that a composition in the neighborhood includes the range of ±30% of an intended atomic ratio. It is preferable to use one or more of gallium, aluminum, and tin as an element M.

The oxide semiconductor 230 may have a structure not containing the element M. For example, a metal oxide used as the oxide semiconductor 230 may be an In-Zn oxide. Specifically, the oxide semiconductor 230 can have a composition of In:Zn=1:1 [atomic ratio] or a composition in the neighborhood thereof, a composition of In:Zn=2:1 [atomic ratio] or a composition in the neighborhood thereof, or a composition of In:Zn=4:1 [atomic ratio] or a composition in the neighborhood thereof. Alternatively, an indium oxide may be used as the oxide semiconductor 230. The oxide semiconductor 230 may contain a slight amount of the element M. Specifically, the oxide semiconductor 230 can have a composition of In:Sn:Zn=4:0.1:1 [atomic ratio] or in the neighborhood thereof, for example.

Analysis of the composition of a metal oxide used as the oxide semiconductor 230 can be performed by, for example, energy dispersive X-ray spectroscopy (EDX), X-ray photoelectron spectroscopy (XPS), inductively coupled plasma-mass spectrometry (ICP-MS), or inductively coupled plasma-atomic emission spectrometry (ICP-AES). Alternatively, some of these analysis methods may be performed in combination. Note that as for an element whose content percentage is low, the actual content percentage may be different from the content percentage obtained by analysis because of the influence of the analysis accuracy. In the case where the content percentage of the element Mis low, for example, the content percentage of the element M obtained by analysis may be lower than the actual content percentage.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method, which enables atomic layers to be deposited one by one, has advantages such as deposition of an extremely thin film, deposition on a component with a high aspect ratio or on a surface with a large step, deposition of a film with few defects such as pinholes, deposition of a film with excellent coverage, and low-temperature deposition. The use of plasma in a PEALD method is sometimes preferable because it enables formation at a lower temperature. Note that a precursor used in an ALD method sometimes contains an element such as carbon or chlorine. Thus, in some cases, a film provided by an ALD method contains a larger amount of an element such as carbon or chlorine than a film provided by another deposition method. Note that these elements can be quantified by XPS or SIMS. The deposition method of the metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike a deposition method in which particles ejected from a target or the like are deposited, an ALD method is a deposition method in which a film is formed by reaction at a surface of an object to be processed. Thus, the ALD method is a deposition method that enables good step coverage almost regardless of the shape of an object to be processed. In particular, the ALD method enables excellent step coverage and excellent thickness uniformity and thus is suitable for covering a surface of an opening portion with a high aspect ratio, for example. Meanwhile, the ALD method has a relatively low deposition rate, and thus is preferably used in combination with another deposition method with a high deposition rate, such as a sputtering method or a CVD method, in some cases. In the case where a metal oxide has a stacked-layer structure of a first metal oxide and a second metal oxide, a method in which the first metal oxide is formed by a sputtering method and the second metal oxide is formed by an ALD method over the first metal oxide can be given as an example. For example, in the case where the first metal oxide has a crystal part, crystal growth occurs in the second metal oxide with the use of the crystal part as a nucleus.

When an ALD method is employed, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be deposited. In the case where the film is formed while the source gas is changed, as compared to the case where a film is formed using a plurality of film formation chambers, the time taken for the film formation can be shortened because the time taken for transfer and pressure adjustment is omitted. Thus, the productivity of the semiconductor device can be increased in some cases.

Note that there is no particular limitation on the method for forming an oxide semiconductor film to be the oxide semiconductor 230. For example, the oxide semiconductor film may be formed by a CVD method, an MBE method, a PLD method, or the like.

There is no particular limitation on the crystallinity of a semiconductor material used for the oxide semiconductor 230, and any of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

It is preferable that the oxide semiconductor 230 include a metal oxide layer having crystallinity. Examples of the structure of a metal oxide having crystallinity include a CAAC (c-axis-aligned crystal) structure, a polycrystalline (Poly-crystal) structure, and a nano-crystal (nc) structure. By using a metal oxide layer having crystallinity as the oxide semiconductor 230, the density of defect states in the oxide semiconductor 230 can be reduced, which enables the semiconductor device to have high reliability. Note that the CAAC structure is a crystal structure in which a plurality of microcrystals (typically, a plurality of IGZO microcrystals) have c-axis alignment and the above plurality of microcrystals are connected in the a-b plane without alignment. Observation of the cross section of an OS film having the CAAC structure with use of a high-resolution TEM image confirms that metal atoms are arranged in a layered manner in the crystal parts. Thus, the CAAC structure of the OS film can also be referred to as a structure including the layered crystal parts.

The polycrystalline structure includes a crystal grain boundary (grain boundary). When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. A CAAC structure has fewer crystal grain boundaries (grain boundaries) in the a-b plane than the polycrystalline structure; thus, a highly reliable semiconductor device can be achieved.

The higher the crystallinity of the metal oxide layer used for the oxide semiconductor 230 is, the lower the density of defect states in the oxide semiconductor 230 can be. By contrast, the use of a metal oxide layer having low crystallinity enables a transistor through which a large amount of current can flow.

The higher the substrate temperature (the stage temperature) in the formation of the metal oxide layer is, the higher the crystallinity of the metal oxide layer can be. The crystallinity of the metal oxide layer can be increased as the proportion of a flow rate of an oxygen gas to the whole deposition gas (also referred to as an oxygen flow rate ratio) used in formation is higher.

The crystallinity of the oxide semiconductor 230 can be analyzed with X-ray diffraction (XRD), a transmission electron microscope (TEM), or electron diffraction (ED), for example. Alternatively, some of these analysis methods may be performed in combination.

Note that although the oxide semiconductor 230 has a single layer in FIG. 1A and FIG. 1B, the present invention is not limited thereto. The oxide semiconductor 230 may have a stacked-layer structure of a plurality of oxide layers with different chemical compositions. For example, a structure may be employed in which a plurality of kinds of metal oxides selected from the metal oxides described in the section [Metal oxide] below are stacked as appropriate.

The oxide semiconductor 230 can have a stacked-layer structure of two or more metal oxide layers having different crystallinities. In that case, the compositions of the two or more metal oxide layers may be different from, the same as, or substantially the same as each other. For example, as illustrated in FIG. 3A, the oxide semiconductor 230 may have a two-layer structure of an oxide semiconductor 230a and an oxide semiconductor 230b on the inner side than the oxide semiconductor 230a. The two-layer structure can be formed in the following manner: a metal oxide film to be the oxide semiconductor 230a is formed, and a metal oxide film to be the oxide semiconductor 230b is formed thereover. Here, the oxide semiconductor 230b can include a region having higher crystallinity than the oxide semiconductor 230a. Alternatively, the oxide semiconductor 230b can include a region having lower crystallinity than the oxide semiconductor 230a. Note that in the case where the oxide semiconductor 230b includes a region having lower crystallinity than the oxide semiconductor 230a, the crystallinity of the oxide semiconductor 230b can be increased by performing heat treatment (also referred to as crystallization treatment) after the formation of the oxide semiconductor 230b.

For example, a metal oxide with a composition of In:M:Zn=1:3:2 [atomic ratio] or a composition in the neighborhood thereof or a metal oxide with a composition of In:M:Zn=1:3:4 [atomic ratio] or a composition in the neighborhood thereof is preferably used for the oxide semiconductor 230a, and a metal oxide with a composition of In:M:Zn=1:1:1 [atomic ratio] or a composition in the neighborhood thereof is preferably used for the oxide semiconductor 230b. The use of a metal oxide in which the ratio of Zn to In is high for the oxide semiconductor 230a can increase the crystallinity of the oxide semiconductor 230a. Furthermore, forming the oxide semiconductor 230b over the oxide semiconductor 230a with high crystallinity facilitates increasing the crystallinity of the oxide semiconductor 230b. This is preferable because the crystallinity of the whole oxide semiconductor 230 can be increased. In this case, it is particularly preferable to use gallium, aluminum, or tin as the element M. For example, two IGZO layers having different compositions may be stacked. For another example, a stacked-layer structure of one selected from indium oxide, indium gallium oxide, and IGZO, and one selected from IAZO, IAGZO, and ITZO (registered trademark) may be employed.

Furthermore, the oxide semiconductor 230 may have a stacked-layer structure of three or more layers. As illustrated in FIG. 3B, the oxide semiconductor 230 positioned in the opening portion 290 can have a three-layer structure including an oxide semiconductor 230c in contact with the sidewall of the opening portion 290, the oxide semiconductor 230a in contact with a side surface of the oxide semiconductor 230c on the center side of the opening portion 290, and the oxide semiconductor 230b in contact with a side surface of the oxide semiconductor 230a on the center side of the opening portion 290, for example.

The above-described structure can be applied to each of the oxide semiconductor 230a and the oxide semiconductor 230b. The structure of the oxide semiconductor 230c positioned on the outer side than the oxide semiconductor 230a can be similar to the structure that can be applied to the oxide semiconductor 230b.

For example, it is preferable to use, for the oxide semiconductor 230a, a metal oxide having an atomic ratio of In:Zn=1:1 or a composition in the neighborhood thereof, a metal oxide having an atomic ratio of In:Zn=2:1 or a composition in the neighborhood thereof, a metal oxide having an atomic ratio of In:Sn:Zn=2:0.1:1 or a composition in the neighborhood thereof, a metal oxide having an atomic ratio of In:Zn=4:1 or a composition in the neighborhood thereof, a metal oxide having an atomic ratio of In:Sn:Zn=4:0.1:1 or a composition in the neighborhood thereof, or an indium oxide. It is preferable to use, for each of the oxide semiconductor 230b and the oxide semiconductor 230c, a metal oxide with a composition of In:Ga:Zn=1:1:1 [atomic ratio] or a composition in the neighborhood thereof, a metal oxide with a composition of In:Ga:Zn=1:3:2 [atomic ratio] or a composition in the neighborhood thereof, or a metal oxide with a composition of In:Ga:Zn=1:3:4 [atomic ratio] or a composition in the neighborhood thereof.

The oxide semiconductor 230b and the oxide semiconductor 230c each preferably have a larger band gap than the oxide semiconductor 230a. In that case, the oxide semiconductor 230a is sandwiched between the oxide semiconductor 230b and the oxide semiconductor 230c each having a large band gap, and the oxide semiconductor 230a mainly functions as a current path (channel). When the oxide semiconductor 230a is sandwiched between the oxide semiconductor 230b and the oxide semiconductor 230c, the trap states at the interfaces with the oxide semiconductor 230a and the vicinity thereof can be reduced. Accordingly, a buried-channel transistor where a channel is distanced from the interface with an insulating layer can be achieved, whereby the field-effect mobility can be increased. Furthermore, the influence of interface states that can be formed on the back channel side is reduced, so that light deterioration (e.g., light negative bias deterioration) of the transistor can be inhibited and the reliability of the transistor can be increased.

The thickness of the oxide semiconductor 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet still further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a miniaturized semiconductor device, the thickness of the oxide semiconductor 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

In the deposition of the oxide semiconductor layer, two kinds of deposition methods, that is, a sputtering method and an ALD method, are preferably used. For example, after a first oxide semiconductor layer having a CAAC structure is formed by a sputtering method, a second oxide semiconductor layer having lower crystallinity than the CAAC structure is formed by an ALD method, in which case, an atomic layer of the second oxide semiconductor layer is expected to fill or repair a gap between crystal parts in the atomic level in the CAAC structure of the first oxide semiconductor layer. After the second oxide semiconductor layer is formed by an ALD method, heat treatment (e.g., at a temperature higher than or equal to 100 °C and lower than or equal to 500 °C, preferably higher than or equal to 200 °C and lower than or equal to 450 °C, further preferably higher than or equal to 300 °C and lower than or equal to 400 °C) is preferably performed. By the heat treatment, the gap between crystal parts in the atomic level in the CAAC structure of the first oxide semiconductor layer is expected to be repaired by the second oxide semiconductor layer (i.e., crystal molecules formed by the ALD method). The oxide semiconductor layer formed by the two kinds of deposition methods may be referred to as a hybrid OS.

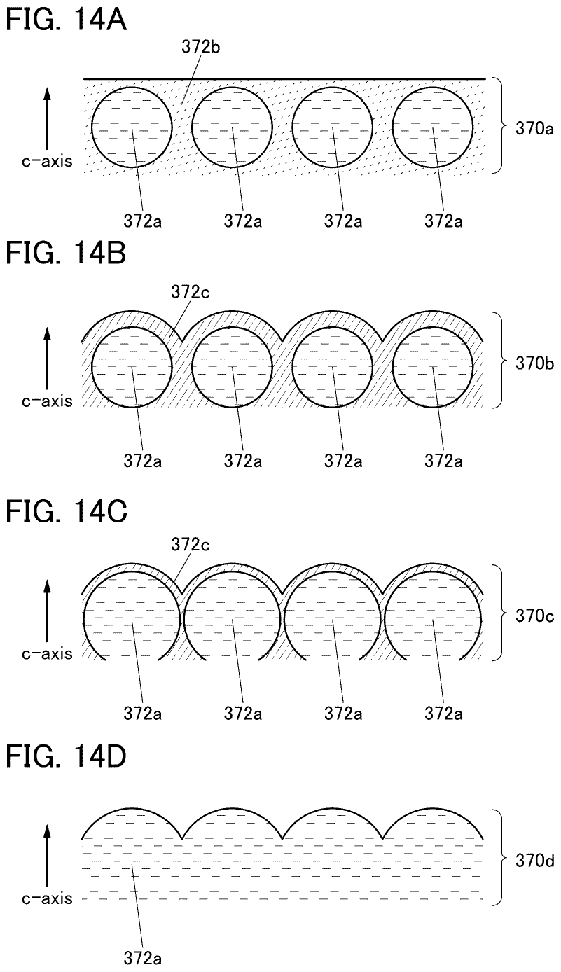

Here, a concept of the heat treatment that increases the crystallinity of an oxide semiconductor layer is described with reference to FIG. 14A, FIG. 14B, FIG. 14C, and FIG. 14D. Note that FIG. 14A, FIG. 14B, FIG. 14C, and FIG. 14D are conceptual diagrams each illustrating a cross section of an oxide semiconductor layer having a CAAC structure. In each of the drawings, the c-axis is indicated by an arrow.

An oxide semiconductor layer 370a illustrated in FIG. 14A includes regions 372a and a region 372b positioned between the regions 372a. The regions 372a each correspond to a region having a CAAC structure (i.e., a structure including a layered crystal part), and the region 372b corresponds to a region between the CAAC structures. The CAAC structure has fewer crystal grain boundaries in the a-b plane than a polycrystalline structure. As described above, even in the oxide semiconductor layer 370a having the CAAC structure, a minute gap or a minute space (the region 372b in FIG. 14A) can exist between crystal parts in some cases.

In view of the above, in order to increase the crystallinity of an oxide semiconductor layer, that is, in order to reduce the region 372b illustrated in FIG. 14A, after an oxide semiconductor layer having a CAAC structure is formed by a sputtering method as the first oxide semiconductor layer, an oxide semiconductor layer having a microcrystalline or an amorphous structure with lower crystallinity than the CAAC structure is formed by an ALD method as the second oxide semiconductor layer.

Specifically, as illustrated in FIG. 14B, after an oxide semiconductor layer including the regions 372a is formed by a sputtering method as the first oxide semiconductor layer, an oxide semiconductor layer including a region 372c having lower crystallinity than the CAAC structure is formed by an ALD method as the second oxide semiconductor layer. Note that in FIG. 14B, an oxide semiconductor layer 370b includes the regions 372a and the region 372c. Since atomic layers can be deposited one by one by an ALD method, the second oxide semiconductor layer can be formed so as to fill the region 372b.

Then, heat treatment is performed, whereby the regions 372a included in the first oxide semiconductor layer serve as seeds and the crystallinity of the region 372c included in the second oxide semiconductor layer is increased. In other words, the regions 372a included in the first oxide semiconductor layer can serve as seeds in crystal growth of the region 372c included in the second oxide semiconductor layer. Alternatively, the regions 372a of the first oxide semiconductor layer having the CAAC structure can serve as nuclei in crystal growth of the region 372c included in the second oxide semiconductor layer having the amorphous structure. In FIG. 14C, an oxide semiconductor layer 370c includes the regions 372a and the region 372c. The regions 372a illustrated in FIG. 14C are each a region with higher crystallinity or higher density of crystal parts than the regions 372a illustrated in FIG. 14B. By the heat treatment, the crystallinity of one or both of the regions 372a and the region 372c can be increased. The region 372c includes a crystal part having a crystal structure similar to that of the crystal part included in the regions 372a, for example. Alternatively, the region 372c includes a crystal part that is connected with the crystal part included in the region 372a, for example.

In FIG. 14D, an oxide semiconductor layer 370d includes the region 372a. The region 372a is a region having higher crystallinity than the regions 372a illustrated in FIG. 14B and FIG. 14C, where there is no boundary between the region 372a and the region 372c or the boundary between the region 372a and the region 372c is not confirmed. Thus, the whole oxide semiconductor layer 370d has a CAAC structure. When the whole oxide semiconductor layer 370d has a CAAC structure as illustrated in FIG. 14D, a highly reliable semiconductor device can be achieved. The presence or absence of a boundary between the region 372a and the region 372c can be confirmed using, for example, cross-sectional TEM, cross-sectional STEM, or the like.

Even in the case where a minute gap or a minute space is included in the first oxide semiconductor layer, depositing the second oxide semiconductor layer over the first oxide semiconductor layer or depositing the second oxide semiconductor layer and performing heat treatment can fill the minute gap or the minute space in the first oxide semiconductor layer. When an oxide semiconductor layer having a CAAC structure is used as the first oxide semiconductor layer and an oxide semiconductor layer having a microcrystalline or an amorphous structure is used as the second oxide semiconductor layer in this manner, a dense oxide semiconductor layer with increased crystallinity can be obtained. Using the dense oxide semiconductor layer with increased crystallinity in a channel formation region of a transistor is promising for inhibiting an increase in electric resistance of the oxide semiconductor layer or improving initial characteristics (particularly on-state current) of the transistor, thereby achieving a transistor suitable for high-speed operation.

In the case where an oxide semiconductor layer is formed by both a sputtering method and an ALD method and the oxide semiconductor layer formed by an ALD method is thin, the obtained oxide semiconductor layer can be regarded not as a stacked-layer structure of the oxide semiconductor layer formed by a sputtering method and the oxide semiconductor layer formed by an ALD method, but as an oxide semiconductor layer having a single-layer structure. For example, when the thickness of the oxide semiconductor layer formed by an ALD method is greater than 0 nm and less than or equal to 3 nm, preferably greater than 0 nm and less than or equal to 2 nm, further preferably greater than 0 nm and less than or equal to 1 nm, the oxide semiconductor layer formed by two kinds of deposition methods, which are a sputtering method and an ALD method, can be regarded as having a single-layer structure. Meanwhile, when the thickness of the oxide semiconductor layer formed by an ALD method exceeds 3 nm, the oxide semiconductor layer can be regarded as having a stacked-layer structure, a multilayer structure, or a multi-structure of the oxide semiconductor layer formed by a sputtering method and the oxide semiconductor layer formed by an ALD method, in some cases.

In the case where an oxide semiconductor layer is formed by both a sputtering method and an ALD method, different compositions are preferably used. For example, a metal oxide film formed by a sputtering method preferably has a composition suitable for forming a CAAC structure. By contrast, a metal oxide film formed by an ALD method preferably has a composition in which the content of indium is higher than that in the metal oxide film formed by a sputtering method. Typically, a metal oxide with a composition of In:Ga:Zn=1:1:1 [atomic ratio] or a composition in the neighborhood thereof can be deposited by a sputtering method, and then a metal oxide with a composition of In:Ga:Zn=4:0.1:1 [atomic ratio] or a composition in the neighborhood thereof can be deposited by an ALD method. The oxide semiconductor layer having the above compositions can have high reliability owing to the metal oxide layer with In:Ga:Zn=1:1:1 [atomic ratio] and have high on-state current or high field-effect mobility owing to the metal oxide with a composition In:Ga:Zn=4:0.1:1 [atomic ratio] or a composition in the neighborhood thereof. For example, in the case of the two-layer structure of the oxide semiconductor 230a and the oxide semiconductor 230b illustrated in FIG. 3A, a metal oxide with a composition of In:Ga:Zn=1:1:1 [atomic ratio] or a composition in the neighborhood thereof deposited by a sputtering method may be used as the oxide semiconductor 230a and a metal oxide with a composition of In:Ga:Zn=4:0.1:1 [atomic ratio] or a composition in the neighborhood thereof deposited by an ALD method may be used as the oxide semiconductor 230b.

In the case of the three-layer structure of the oxide semiconductor 230c, the oxide semiconductor 230a, and the oxide semiconductor 230b illustrated in FIG. 3B, the oxide semiconductor 230c is preferably deposited by an ALD method. For example, first, as the oxide semiconductor 230c, a metal oxide with a composition of In:Ga:Zn=4:0.1:1 [atomic ratio] or a composition in the neighborhood thereof is deposited by an ALD method. Next, as the oxide semiconductor 230a, a metal oxide with a composition of In:Ga:Zn=1:1:1 [atomic ratio] or a composition in the neighborhood thereof is deposited by a sputtering method. Then, as the oxide semiconductor 230b, a metal oxide with a composition of In:Ga:Zn=4:0.1:1 or a composition in the neighborhood thereof is deposited by an ALD method. With such a structure, the vicinity of the formation surface of the oxide semiconductor 230a can be prevented from being alloyed, resulting in increased crystallinity of the oxide semiconductor 230a.

Note that in the above, instead of the metal oxide with a composition of In:Ga:Zn=4:0.1:1 [atomic ratio] or a composition in the neighborhood thereof, a metal oxide with a composition of In:Ga:Zn=1:0:0 [atomic ratio], that is, indium oxide or a metal oxide with a high proportion of In can be used. For example, a metal oxide with a composition of In:Zn=4:1 [atomic ratio] or a composition in the neighborhood thereof can be used instead of the metal oxide with a composition of In:Ga:Zn=4:0.1:1 [atomic ratio] or a composition in the neighborhood thereof.

The oxide semiconductor layer formed by the two kinds of deposition methods can be regarded as having a structure where a space between crystal parts of the CAAC structure is filled with an atomic layer formed by an ALD method. Note that this structure can be analyzed by analysis methods such as cross-sectional SEM, cross-sectional STEM, cross-sectional TEM, SIMS, and EDX.

The oxide semiconductor layer having the CAAC structure formed by the two kinds of deposition methods sometimes has one or more of a higher dielectric constant, higher film density, and higher film hardness than the oxide semiconductor layer having a CAAC structure formed by one kind of deposition method. With the use of the oxide semiconductor layer having the CAAC structure formed by the two kinds of deposition methods for a channel formation region of a transistor as described above, the transistor can have excellent characteristics (e.g., a high on-state current, high field-effect mobility, a low S value, high frequency characteristics (also referred to as f characteristics), and high reliability).

In order to improve the electrical characteristics and reliability of an OS transistor, it is important to sufficiently reduce the hydrogen concentration in the channel formation region of the oxide semiconductor. For example, the hydrogen concentration in the channel formation region of the oxide semiconductor, which is measured by secondary ion mass spectrometry (SIMS), is preferably lower than 1×10²⁰ atoms/cm³, further preferably lower than 5×10¹⁹ atoms/cm³, still further preferably lower than 1×10¹⁹ atoms/cm³, yet further preferably lower than 5×10¹⁸ atoms/cm³, yet still further preferably lower than 1×10¹⁸ atoms/cm³, yet still further preferably lower than 1×10¹⁷ atoms/cm³.

Here, a barrier insulator against hydrogen is preferably used as the insulator 440 provided below the capacitor 400 and the insulator 283 provided above the transistor 200. With such a structure, the insulator 440 and the insulator 283 can be provided to sandwich the memory cell 450. When the insulator 440 and the insulator 283 provided outside the transistor 200 including the oxide semiconductor 230 have a barrier property against hydrogen, diffusion of hydrogen into the oxide semiconductor 230 can be inhibited.

Note that in this specification and the like, a barrier insulator refers to an insulator having a barrier property. The barrier property refers to a property that does not easily allow diffusion of a target substance (also referred to as a property that does not easily allow passage of a target substance, a property with low permeability to a target substance, or a function of inhibiting diffusion of a target substance). Hydrogen described as a target substance refers to at least one of a hydrogen atom, a hydrogen molecule, and a substance bonded to hydrogen, such as a water molecule or OH, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

Examples of the barrier insulator against hydrogen include aluminum oxide, magnesium oxide, hafnium oxide, gallium oxide, silicon nitride, and silicon nitride oxide.

For example, silicon nitride is preferably used for the insulator 440 and the insulator 283. In that case, the insulator 440 and the insulator 283 contain silicon and nitrogen.

Silicon nitride that can be used for the insulator 440 and the insulator 283 has a barrier property against hydrogen when having a thickness of 2 nm or more, for example. In order to enhance the barrier property against hydrogen, the thickness of silicon nitride is preferably greater than or equal to 3 nm, further preferably greater than or equal to 5 nm. Note that silicon nitride has a barrier property against oxygen when having a thickness of 1 nm or more, for example. In order to enhance the barrier property against oxygen, the thickness of silicon nitride is preferably greater than or equal to 2 nm. That is, silicon nitride formed to have such a thickness that it has a barrier property against hydrogen also has a barrier property against oxygen.

As illustrated in FIG. 4, an insulator 480b having a function of capturing or fixing hydrogen is preferably used in an upper part of the insulator 480. When the insulator 480b has a function of capturing or fixing hydrogen, the hydrogen concentration in the oxide semiconductor 230 positioned inward from the insulator 440 and the insulator 283 can be reduced. In that case, hydrogen in the oxide semiconductor 230 is captured or fixed by the insulator 480b, causing the hydrogen concentration in the insulator 480b to be increased. For example, the hydrogen concentration, which is obtained by SIMS, in the insulator 480b may be higher than or equal to 1 ×10¹⁹ atoms/cm³ or higher than or equal to 1×10²⁰ atoms/cm³. In that case, the hydrogen concentration in at least part of the insulator 480b is higher than the hydrogen concentration in the oxide semiconductor 230. In other words, the oxide semiconductor 230 includes a region having a lower hydrogen concentration than the insulator 480b.

Note that a function of capturing or fixing a target substance can also be referred to as a property that does not easily allow diffusion of a target substance. Thus, a function of capturing or fixing a target substance can be rephrased as a barrier property.

As the insulator having a function of capturing or fixing hydrogen, a metal oxide containing hafnium or the like (e.g., hafnium oxide) is preferable. The metal oxide preferably includes an oxygen atom having a dangling bond. Such a metal oxide has a property of capturing or fixing hydrogen with the dangling bond in some cases. For example, the metal oxide preferably has an amorphous structure. This is because some oxygen atoms in a metal oxide having an amorphous structure have dangling bonds. Although the metal oxide preferably has an amorphous structure, a crystal region is formed in part of the metal oxide in some cases. The metal oxide partly includes a crystal grain boundary in some cases.

Here, when silicon is added to hafnium oxide, crystallization of the hafnium oxide can be inhibited. That is, an oxide containing hafnium and silicon (hereinafter, sometimes referred to as hafnium silicate) is likely to have an amorphous structure. Thus, hafnium silicate has a property of capturing or fixing hydrogen, and so is suitable for the insulator 480b. In that case, the insulator 480b contains hafnium, silicon, and oxygen.

Although an oxide containing hafnium is given above as an example of the insulator having a function of capturing or fixing hydrogen, the present invention is not limited thereto. Examples of the insulator include an oxide containing magnesium, an oxide containing aluminum, and an oxide containing aluminum and hafnium (hafnium aluminate). Alternatively, the above-described metal oxide further containing zirconium may be used. For example, an oxide containing hafnium and zirconium and the like are given. These metal oxides preferably have an amorphous structure by addition of silicon.

The insulator 280 is provided to cover the conductor 220, the conductor 420, and the insulator 430 and is in contact with the side surface of the oxide semiconductor 230 and the bottom surface of the conductor 240 (see FIG. 1A and FIG. 1B). The insulator 280 is preferably formed using a material with a low relative dielectric constant. In that case, the insulator 280 functions as an interlayer insulating film, thereby reducing the parasitic capacitance between the conductor 240 and the conductor 220. Accordingly, frequency characteristics of the transistor 200 can be improved.

As the insulator 280, a single layer or stacked layers of an insulator containing any of the materials with a low relative dielectric constant described in the section [Insulator] below can be used. Specifically, silicon oxide or silicon oxynitride can be used for the insulator 280. The concentration of impurities such as water and hydrogen in the insulator 280 is preferably reduced. This can inhibit entry of impurities such as water and hydrogen into the channel formation region of the oxide semiconductor 230.

As the insulator 280, an insulator containing oxygen is preferably used. Increasing the oxygen content in the insulator 280 facilitates supply of oxygen to the oxide semiconductor 230 in contact with the insulator 280 to reduce oxygen vacancies.

It is further preferable that a film from which oxygen is released by heating be used as the insulator 280. When the insulator 280 releases oxygen by being heated during the manufacturing process of the transistor 200, the oxygen can be supplied to the oxide semiconductor 230. Supply of oxygen from the insulator 280 to the oxide semiconductor 230, particularly to the channel formation region of the oxide semiconductor 230, can reduce oxygen vacancies and VoH in the channel formation region of the oxide semiconductor 230, so that the transistors can have favorable electrical characteristics and high reliability.

For example, the amount of oxygen molecules released from the insulator 280b is preferably greater than or equal to 1.0×10¹⁴ molecules/cm² and less than 1.0×10¹⁵ molecules/cm². Note that the amount of released oxygen molecules can be measured by thermal desorption spectrometry.

Particularly in the case where the channel length of the transistor 200 is short, oxygen vacancies and VoH in the channel formation region significantly affect the electrical characteristics and reliability. Accordingly, when the hydrogen concentration in the oxide semiconductor 230 is sufficiently reduced and the amount of oxygen supplied to the oxide semiconductor 230 is optimized, a transistor with a short channel length, excellent electrical characteristics, and high reliability can be provided.

The insulator 280 is preferably formed by a deposition method such as a sputtering method or a plasma-enhanced chemical vapor deposition (PECVD) method. In particular, a sputtering method, which does not need to use a hydrogen gas as a deposition gas, enables a film having an extremely low hydrogen content. This can inhibit supply of hydrogen to the oxide semiconductor 230 and stabilize the electrical characteristics of the transistor 200.

In the case where the amount of oxygen supplied to the oxide semiconductor 230 is increased, heat treatment in an oxygen-containing atmosphere or plasma treatment in an oxygen-containing atmosphere is preferably performed after formation of the insulator 280, for example. Alternatively, an oxide film may be formed over the top surface of the insulator 280 by a sputtering method in an oxygen atmosphere to supply oxygen. After that, the oxide film may be removed. Such treatment can supply oxygen to the insulator 280 and increase the amount of oxygen supplied to the oxide semiconductor 230.

A barrier insulator against hydrogen can be used also as the insulator 280. For example, silicon nitride is used for the insulator 280. Such a structure can inhibit diffusion of hydrogen into the oxide semiconductor 230. The concentration of impurities such as water and hydrogen in the insulator 280 is preferably reduced. This can inhibit entry of impurities such as water and hydrogen into the channel formation region of the oxide semiconductor 230.

Note that although FIG. 1A and FIG. 1B illustrate the insulator 280 having a single-layer structure as an example, the present invention is not limited thereto, and the insulator 280 can have a stacked-layer structure. For example, the insulator 280 can have a two-layer structure in which the top surface of the first-layer insulator is level with the top surface of the conductor 220 and the second-layer insulator is provided over the first insulator.

Alternatively, as illustrated in FIG. 3A, the insulator 280 may have a stacked-layer structure of an insulator 280a, an insulator 280b over the insulator 280a, and an insulator 280c over the insulator 280b.

The insulator 280a is in contact with the top surface of the insulator 480, the side surface of the insulator 430, the side surface of the conductor 420, and the top surface and the side surface of the conductor 220. The insulator 280b is in contact with the top surface of the insulator 280a and the bottom surface of the insulator 280c. The insulator 280c is in contact with the bottom surface of the conductor 240.

For the insulator 280b, any of the above-described insulating materials that can be used for the insulator 280 is used. Specifically, for the insulator 280b, silicon oxide or silicon oxynitride can be used. The concentration of impurities such as water and hydrogen in the insulator 280b is preferably reduced.

In the case where an insulator containing oxygen is used as the insulator 280b, any of the barrier insulators against oxygen described in the section [Insulator] below is preferably used as each of the insulator 280a and the insulator 280c. The insulator 280a provided between the insulator 280b and the conductor 220 and the conductor 420 can inhibit excessive oxidation of the conductor 220 and the conductor 420 and an increase in the resistance of the conductor 220 and the conductor 420. The insulator 280c provided between the insulator 280b and the conductor 240 can inhibit excessive oxidation of the conductor 240 and an increase in the resistance of the conductor 240.

As each of the insulator 280a and the insulator 280c, a barrier insulator against hydrogen may be used. In that case, the insulator 280b can be sandwiched between barrier insulators against hydrogen. Thus, diffusion of hydrogen into the insulator 280b from below the insulator 280a or above the insulator 280c can be inhibited. A silicon nitride film and a silicon nitride oxide film can be suitably used for the insulator 280a and the insulator 280c because they release fewer impurities (e.g., water and hydrogen) and are less likely to transmit oxygen and hydrogen. For the insulator 280a and the insulator 280c, the same material or different materials may be used.

An insulator having a function of capturing or fixing hydrogen may be used as one or both of the insulator 280a and the insulator 280c. With such a structure, diffusion of hydrogen from below the insulator 280a or above the insulator 280c into the insulator 280b can be inhibited, and hydrogen contained in the insulator 280b can be captured or fixed. Thus, the hydrogen concentration in the oxide semiconductor 230 and the vicinity thereof can be reduced. For the insulator 280a, magnesium oxide, aluminum oxide, hafnium oxide, an oxide containing hafnium and silicon, or the like can be used. For another example, a stacked-layer film of aluminum oxide and silicon nitride over the aluminum oxide may be used as the insulator 280a. As the insulator 280c, a stacked-layer film of silicon nitride and aluminum nitride over the silicon nitride may be used, for example.

For example, silicon nitride can be used for the insulator 280a and the insulator 280c, and silicon oxide can be used for the insulator 280b. In that case, each of the insulator 280a and the insulator 280c contains at least silicon and nitrogen. The insulator 280b contains at least silicon and oxygen.

Although FIG. 3A illustrates the structure in which the insulator 280c is provided over the planarized insulator 280b, the present invention is not limited thereto. For example, the insulator 280c may be formed without performing planarization treatment on the insulator 280b. By not performing planarization treatment, the manufacturing cost can be reduced and the productivity can be increased. In addition, the insulator 280a, the insulator 280b, and the insulator 280c can be successively formed without exposure to the air. By the formation without exposure to the air, impurities or moisture from the atmospheric environment can be prevented from being attached onto the insulator 280a to the insulator 280c, so that the vicinity of the interface between the insulator 280a and the insulator 280b and the vicinity of the interface between the insulator 280b and the insulator 280c can be kept clean.

A region of the oxide semiconductor 230 that is in contact with the insulator 280a and a region of the oxide semiconductor 230 that is in contact with the insulator 280c are supplied with a smaller amount of oxygen than a region of the oxide semiconductor 230 that is in contact with the insulator 280b. Thus, the region of the oxide semiconductor 230 that is in contact with the insulator 280a and the region of the oxide semiconductor 230 that is in contact with the insulator 280c each have a low resistance in some cases. That is, by adjusting the thickness of the insulator 280a, the range of a region functioning as one of a source region and a drain region can be controlled. Similarly, by adjusting the thickness of the insulator 280c, the range of a region functioning as the other of the source region and the drain region can be controlled. Accordingly, the thicknesses of the insulator 280a and the insulator 280c can be set as appropriate in accordance with the characteristics required for the transistor 200.

Although FIG. 3A illustrates the structure in which the insulator 280 has a stacked-layer structure of three layers, the present invention is not limited thereto. The insulator 280 may have a stacked-layer structure of two layers or four or more layers.

The insulator 270 is provided to cover the conductor 240 and the oxide semiconductor 230. The insulator 270 is preferably formed using a material with a low relative dielectric constant. In that case, the insulator 270 functions as an interlayer insulating film, so that the parasitic capacitance between the conductor 260 and the conductor 240 can be reduced. Accordingly, the transistor 200 can have improved frequency characteristics. For the insulator 270, any of the above-described insulating materials that can be used for the insulator 280 may be used. Specifically, for the insulator 270, silicon oxide or silicon oxynitride can be used. The concentration of impurities such as water and hydrogen in the insulator 270 is preferably reduced. As illustrated in FIG. 3A, the insulator 270 can also have a stacked-layer structure of an insulator 270a and an insulator 270b. In that case, the insulator 270a is preferably positioned in contact with the bottom surface of the insulator 270b and a side surface of the insulator 270b on the opening portion 290 side. For example, aluminum oxide is used for the insulator 270a, and silicon oxide is used for the insulator 270b.

As illustrated in FIG. 1B, the insulator 270 preferably covers an end portion of the side surface of the oxide semiconductor 230, an end portion of the side surface of the conductor 240a, and an end portion of the side surface of the conductor 240b. This can prevent a short circuit between the conductor 260 and the oxide semiconductor 230, the conductor 240a, and the conductor 240b.

The conductor 240 preferably includes the conductor 240a and the conductor 240b over the conductor 240a. The conductor 240a and the conductor 240b have the opening portion 290 overlapping with the insulator 425.

It is preferable that the conductor 240 not be provided in the opening portion included in the insulator 280. That is, it is preferable that the conductor 240 not include a region in contact with the side surface of the insulator 280 in the opening portion 290. With such a structure, the opening portion of the conductor 240 and the opening portion of the insulator 280 can be collectively formed. When the side surface of the conductor 240 in the opening portion 290 is flush with the side surface of the insulator 280 in the opening portion 290, the thickness distribution of the oxide semiconductor 230 provided in the opening portion 290 can be uniform. In addition, the oxide semiconductor 230 can be inhibited from being divided by a step between the conductor 240 and the insulator 280.

Although FIG. 1A and FIG. 1B illustrate the structure in which the side surface of the conductor 240 in the opening portion 290 is flush with the side surface of the insulator 280 in the opening portion 290, the present invention is not limited thereto. For example, the side surface of the conductor 240 in the opening portion 290 and the side surface of the insulator 280 in the opening portion 290 may be discontinuous. The inclination of the side surface of the conductor 240 in the opening portion 290 and the inclination of the side surface of the insulator 280 in the opening portion 290 may be different from each other. In that case, for example, the angle between the side surface of the conductor 240 in the opening portion 290 and the top surface of the insulator 440 is preferably smaller than the angle between the side surface of the insulator 280 in the opening portion 290 and the top surface of the insulator 440. With such a structure, the coverage of the side surface of the conductor 240 with the oxide semiconductor 230 in the opening portion 290 is improved, so that the number of defects such as voids can be reduced.

The bottom surface of the conductor 240a is in contact with the insulator 280, one side surface thereof is in contact with the oxide semiconductor 230, and the other side surface thereof is in contact with the insulator 270.

The conductor 240a is preferably formed using a metal having higher conductivity than the conductor 240b. The conductor 240a is preferably formed using a metal having lower sheet resistance than the conductor 240b. With such a structure, the conductor 240 including the conductor 240a can function as a wiring electrically connected to one of the source electrode and the drain electrode.

For the conductor 240a, one or more of ruthenium, tantalum, nickel, titanium, molybdenum, tungsten, hafnium, vanadium, niobium, aluminum, chromium, copper, silver, gold, platinum, zinc, manganese, iron, cobalt, magnesium, zirconium, beryllium, indium, iridium, strontium, and lanthanum, an alloy including one or more of these metals as its components, or the like can be used. For example, tungsten is preferably used for the conductor 240a.

Part of the conductor 240a contains a metal oxide of the above metal in some cases. In that case, a layer of the metal oxide is sometimes formed in the vicinity of an interface between the conductor 240a and the conductor 240b and in the vicinity of an interface between the conductor 240a and the oxide semiconductor 230. Here, ruthenium and an alloy of ruthenium are preferable because they are materials that maintain relatively low electric resistance even after being oxidized.

One side surface of the conductor 240b is in contact with the oxide semiconductor 230. The bottom surface of the conductor 240b is in contact with the conductor 240a. The other side surface of the conductor 240b is in contact with the insulator 270.

The conductor 240b is preferably in ohmic contact with the oxide semiconductor 230 and the contact resistance between the conductor 240b and the oxide semiconductor 230 is preferably low. For example, the contact resistance between the conductor 240b and the oxide semiconductor 230 is preferably lower than the contact resistance between the oxide semiconductor 230 and the metal layer used for the conductor 240a. Thus, as the conductor 240b, a metal oxide having conductivity (sometimes referred to as a conductive oxide) is preferably used. When the conductor 240b has the above-described structure, the on-state current, field-effect mobility, S value, and the frequency characteristics of the transistor 200 can be improved.

As the conductive oxide (also referred to as OC: Oxide Conductor or a conductive material containing oxygen) used for the conductor 240b, a conductive oxide containing indium is preferable. As the conductive oxide containing indium, indium oxide, indium tin oxide (sometimes referred to as ITO), indium zinc oxide, indium tin oxide to which silicon is added (also referred to as ITSO), or the like is preferably used. Indium oxide may contain tungsten, titanium, or the like; for example, an In—W oxide, an In—W—Zn oxide, an In—Ti oxide, an In—Ti—Sn oxide, or the like may be used. Alternatively, a conductive oxide containing zinc may be used; for example, zinc oxide, zinc oxide to which gallium is added, In—Ga—Zn oxide, or the like can be used. As the conductive oxide, ruthenium oxide, an oxide including strontium and ruthenium, an oxide including lanthanum and nickel, or the like can be used. A conductive oxide containing indium is particularly preferable because of its high conductivity.

For example, indium tin oxide to which silicon is added can be used for the conductor 240b. In that case, the conductor 240b contains indium, tin, silicon, and oxygen. Here, addition of silicon to indium tin oxide can inhibit polycrystallization of the indium tin oxide. That is, indium tin oxide to which silicon is added is likely to have an nc structure (nanocrystal structure) or an amorphous structure. Note that the present invention is not limited to the above. Polycrystallized indium tin oxide can also be used for the conductor 240b. In that case, the conductor 240b contains indium, tin, and oxygen.

Although the example in which the conductor 240 has a stacked-layer structure of two layers of the conductor 240a and the conductor 240b is described above, the present invention is not limited thereto. The conductor 240 may have a stacked-layer structure of three or more layers. Although the structure in which the conductor 240b is stacked over the conductor 240a is described above, the present invention is not limited thereto. A structure in which the conductor 240a is stacked over the conductor 240b can be employed.

The conductor 220 is provided over the conductor 420 and the insulator 425 and can have an island shape as illustrated in FIG. 1A and FIG. 1B. Here, the bottom surface of the conductor 220 is in contact with the top surface of the conductor 420, whereby one of the source and the drain of the transistor 200 can be electrically connected to the upper electrode of the capacitor 400. As the conductor 220, a single layer or stacked layers of any of the conductors described in the section [Conductor] below can be used. A conductive material that is less likely to be oxidized, a conductive material having a function of inhibiting diffusion of oxygen, or the like is preferably used for the conductor 220.

A conductive oxide is preferably used for the conductor 220 in contact with the oxide semiconductor 230. Thus, for example, a conductive oxide that can be used for the conductor 240b is used for the conductor 220. For example, indium tin oxide to which silicon is added is used for the conductor 220. In that case, the conductor 220 contains indium, tin, silicon, and oxygen. Accordingly, the conductor 220 can be in ohmic contact with the oxide semiconductor 230, so that the contact resistance between the conductor 220 and the oxide semiconductor 230 can be reduced. Thus, the on-state current, field-effect mobility, S value, and frequency characteristics of the transistor 200 can be improved.

As illustrated in FIG. 1A, FIG. 1B, FIG. 3A, and FIG. 3B, the opening portion 290 is preferably formed to penetrate the conductor 220. When the side surface of the conductor 220 and the oxide semiconductor 230 are in contact with each other in the opening portion 290, the area where the conductor 220 and the oxide semiconductor 230 are in ohmic contact with each other can be increased, so that the contact resistance between the conductor 220 and the oxide semiconductor 230 can be further reduced.

As illustrated in FIG. 3B, the conductor 220 can also have a stacked-layer structure of a conductor 220a and a conductor 220b over the conductor 220a. Here, a metal having high conductivity is preferably used for the conductor 220a. Thus, for example, a metal that can be used for the conductor 240a can be used for the conductor 220a. For example, tungsten can be used for the conductor 220a. For the conductor 220b, any of the above-described conductive materials that can be used for the conductor 220 can be used. With such a structure, the conductivity of the conductor 220 including the conductor 220a can be improved.

As illustrated in FIG. 3A and the like, the insulator 250 is provided in contact with the insulator 270, the oxide semiconductor 230, the conductor 420, and the insulator 425. At the bottom surface of the opening portion 290, the insulator 250 is preferably in contact with the top surface of the conductor 420 and the top surface of the insulator 425. Such a structure can increase the distance between the conductor 260, which overlaps with the insulator 425, and the conductor 420, so that the parasitic capacitance can be reduced. Note that in the case where the opening portion 490 is sufficiently larger than the opening portion 290, the entire bottom surface of the insulator 250 is in contact with the insulator 425 and the insulator 250 is not in contact with the conductor 420 in some cases.

Note that as illustrated in FIG. 3B, a structure in which the upper end portion of the insulator 250 and the top surface of the insulator 270 are level with or substantially level with each other and the insulator 250 is not provided over the insulator 270 can be employed.

As illustrated in FIG. 3A, the insulator 250 may have a stacked-layer structure of an insulator 250a, an insulator 250b over the insulator 250a, and an insulator 250c over the insulator 250b. The insulator 250a is in contact with the conductor 220, the oxide semiconductor 230, and the insulator 270. The insulator 250c is in contact with the conductor 260 and the insulator 283. The insulator 250b is provided between the insulator 250a and the insulator 250c.

As the insulator 250a and the insulator 250c, an insulator having a barrier property against oxygen is preferably used. Furthermore, as the insulator 250a and the insulator 250c, an insulator having a function of capturing or fixing hydrogen is preferably used. For the insulator 250a and the insulator 250c, an insulating material that can be used for the insulator 480b is used. Providing the above insulator 250a and insulator 250c can inhibit oxidation of the conductor 220 in contact with the insulator 250a and the conductor 260 in contact with the insulator 250c. Moreover, hydrogen contained in the oxide semiconductor 230 and the vicinity thereof can be captured or fixed more effectively by the insulator 250a and the insulator 250c. Thus, the hydrogen concentration in the oxide semiconductor 230 can be reduced. For example, aluminum oxide can be used for the insulator 250a and hafnium oxide can be used for the insulator 250c. As the insulator 250a and the insulator 250c, a single layer or stacked layers of any of the insulators described in the section [Insulator] below may be used.

Aluminum oxide and hafnium oxide are each a high dielectric constant (high-k) material. Accordingly, in the case where the insulator 250a and the insulator 250c are used as a gate insulator, a gate potential applied during operation of the transistor can be reduced while the physical thickness of the gate insulator is maintained. In addition, the equivalent oxide thickness (EOT) of the insulator functioning as the gate insulator can be reduced.

For the insulator 250b, silicon oxide, silicon oxynitride, or the like having high withstand voltage is preferably used. In order to increase the withstand voltage, the insulator 250b may have a larger thickness than the insulator 250a. Providing the above insulator 250b can improve the withstand voltage of the insulator 250 and reduce leakage current.

As illustrated in FIG. 3B, an insulator 250d having a barrier property against hydrogen may be provided between the insulator 250c and the conductor 260. In that case, diffusion of impurities such as hydrogen contained in the conductor 260 into the oxide semiconductor 230 can be inhibited. As the insulator having a barrier property against hydrogen, an insulator that can be used as the insulator 440 and the insulator 283 can be used. For example, silicon nitride is suitable because of having a high barrier property against hydrogen. In the case where the insulator 250d has a barrier property against hydrogen, the insulator 250d also has a barrier property against oxygen. Thus, providing the insulator 250d can prevent excessive oxidation of the conductor 260.

The thickness of each of the insulator 250a to the insulator 250d is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. Note that at least part of each of the insulator 250a to the insulator 250d includes a region having the above-described thickness. For example, the thickness of the insulator 250a can be 1 nm, the thickness of the insulator 250b can be 2 nm, the thickness of the insulator 250c can be 2 nm, and the thickness of the insulator 250d can be 1 nm. By reducing the thicknesses of the insulator 250a to the insulator 250d as described above, the S value of the transistor 200 can be reduced. When the insulator 250 has a four-layer structure of the insulator 250a to the insulator 250d, the thickness of the insulator 250 can be reduced and the S value of the transistor 200 can be reduced. Note that the thicknesses of the insulator 250a to the insulator 250d are not limited to the above-described thicknesses. For example, one or more of the insulator 250a to the insulator 250d can have a thickness of 15 nm or more.

The conductor 260 is provided in contact with the top surface of the insulator 250. As illustrated in FIG. 1A and FIG. 1B, a portion of the conductor 260 that is above the insulator 270 can be extended in the Y direction to function as a wiring.

As the conductor 260, a single layer or stacked layers of any of the conductors described in the section [Conductor] below can be used. For example, a conductive material with high conductivity such as tungsten can be used for the conductor 260.

In addition, a conductive material that is less likely to be oxidized, a conductive material having a function of inhibiting diffusion of oxygen, or the like is preferably used for the conductor 260. Examples of the conductive material include a conductive material containing nitrogen (e.g., titanium nitride or tantalum nitride) and a conductive material containing oxygen (e.g., ruthenium oxide). In that case, a decrease in the conductivity of the conductor 260 can be inhibited.

Note that although the conductor 260 has a single layer in FIG. 1A and FIG. 1B, the present invention is not limited thereto. The conductor 260 may have a stacked-layer structure. For example, as illustrated in FIG. 3A, the conductor 260 may have a stacked-layer structure of a conductor 260a and a conductor 260b over the conductor 260a. In that case, titanium nitride may be used as the conductor 260a and tungsten may be used as the conductor 260b, for example. When a layer containing tungsten is provided in this manner, the conductor 260 can have improved conductivity and can serve well as a wiring.

Although FIG. 3A illustrates the structure in which the conductor 260 has a stacked-layer structure of two layers of the conductor 260a and the conductor 260b, the present invention is not limited thereto. The conductor 260 may have a stacked-layer structure of three or more layers.

For example, as illustrated in FIG. 3B, the conductor 260a and the conductor 260b may be provided only in a portion below the top surface of the insulator 270, and a conductor 260c functioning as a wiring may be provided over the conductor 260a and the conductor 260b. Here, the upper end portion of the conductor 260a and the top surface of the conductor 260b are level with or substantially level with the top surface of the insulator 270. The conductor 260c functions as a wiring and thus can be formed to extend in the Y direction, for example. For the conductor 260c, a conductive material that can be used for the conductor 260a or the conductor 260b is used. For example, tungsten can be used for the conductor 260c. The conductor 260c can also have a stacked-layer structure of titanium nitride and tungsten, for example.

As the insulator 283, a barrier insulator against hydrogen is preferably used. In that case, diffusion of hydrogen from above the insulator 283 into the oxide semiconductor 230 can be inhibited. A silicon nitride film and a silicon nitride oxide film can be suitably used for the insulator 283 because the silicon nitride film and the silicon nitride oxide film release fewer impurities (e.g., water and hydrogen) and are less likely to transmit oxygen and hydrogen.

Silicon nitride formed by a sputtering method is particularly preferably used for the insulator 283. In that case, the insulator 283 contains silicon and nitrogen. Since a sputtering method does not need to use a molecule containing hydrogen as a deposition gas, the hydrogen concentration in the insulator 283 can be reduced. When the insulator 283 is formed by a sputtering method, high-density silicon nitride can be formed.

Alternatively, silicon nitride deposited by a PEALD method may be used for the insulator 283. When the insulator 283 is formed by a PEALD method, the conductor 260 can be covered with good coverage.

Such a structure can inhibit diffusion of hydrogen into the oxide semiconductor 230 from above the insulator 283. Thus, the hydrogen concentration in the oxide semiconductor 230 can be reduced.

### Structure Example of Capacitor

As illustrated in FIG. 1A and FIG. 1B, the capacitor 400 is provided in the opening portion 490 formed in the insulator 480. The capacitor 400 includes the conductor 415 over the conductor 410, the insulator 430 over the conductor 415, and the conductor 420 over the insulator 430. Furthermore, the insulator 425 is formed over the conductor 420. The conductor 410 is preferably provided to be embedded in an opening formed in the insulator 485. The conductor 410 and the insulator 485 are formed over the insulator 440. The insulator 480 is formed over the conductor 410 and the insulator 440.

The opening portion 490 reaching the conductor 410 is provided in the insulator 480. At least part of the conductor 415 is placed in the opening portion 490. The conductor 415 can have a structure including a region in contact with the top surface of the conductor 410 in the opening portion 490, a region in contact with the side surface of the insulator 480 in the opening portion 490, and a region in contact with at least part of the top surface of the insulator 480. The insulator 430 is placed so as to be at least partly positioned in the opening portion 490. The conductor 420 is placed so as to be at least partly positioned in the opening portion 490. The insulator 425 is placed so as to be at least partly positioned in the opening portion 490.

The conductor 415, the insulator 430, and the conductor 420 are stacked along the sidewall of the opening portion 490 and the top surface of the conductor 410. The insulator 425 is provided to fill a depressed portion that is defined by the conductor 420 and reflects the shape of the opening portion 490.

Note that the sidewall of the opening portion 490 is preferably perpendicular to the top surface of the conductor 410. In that case, the opening portion 490 has a cylindrical shape. Such a structure enables miniaturization or high integration of the semiconductor device.

By increasing the depth of the opening portion 490 is, the larger the capacitance of the capacitor 400 can be increased. The depth of the opening portion 490 can be set as appropriate in accordance with the capacitance required for the memory cell 450, and is preferably larger than the depth of the opening portion 290. For example, the depth of the opening portion 490 can be greater than or equal to 1.1 times and less than or equal to 20 times, preferably greater than or equal to 2 times and less than or equal to 10 times, further preferably greater than or equal to 3 times and less than or equal to 5 times the depth of the opening portion 290. Here, the depth of the opening portion 490 can be defined as the distance between the top surface of the conductor 410 and the top surface of the insulator 480. The depth of the opening portion 290 can be defined as the distance between the top surface of the insulator 425 or the top surface of the conductor 420 and the top surface of the conductor 240b.

As illustrated in FIG. 2C, the conductor 415, the insulator 430, the conductor 420, and the insulator 425 are provided concentrically in the opening portion 490. When the opening portion 490 is formed to be circular in a plan view, the distance between the conductor 415 and the conductor 420 is substantially uniform, so that an electric field can be substantially uniformly applied to the insulator 430.

Although this embodiment describes the example in which the opening portion 490 is circular in the plan view, the present invention is not limited thereto. For example, the opening portion 490 in the plan view may have a substantially circular shape such as an elliptical shape, a polygonal shape such as a quadrangular shape, or a polygonal shape such as a quadrangular shape with rounded corners.

Although the opening portion 490 is provided such that the sidewall of the opening portion 490 is perpendicular to the top surface of the conductor 410 in FIG. 1A and FIG. 1B, the present invention is not limited thereto. For example, the sidewall of the opening portion 490 is not strictly perpendicular and has a tapered shape in some cases. The taper angle formed by the side surface of the insulator 480, which is part of the sidewall of the opening portion 490, and the top surface of the conductor 410 (which may also be the top surface of the insulator 440) is preferably 90° or an angle close to 90°. For example, the taper angle is preferably greater than or equal to 75° and less than or equal to 90°.

As illustrated in FIG. 1A and FIG. 1B, the capacitor 400 is preferably provided to overlap with the transistor 200. For example, the opening portion 490 preferably includes a region overlapping with the opening portion 290. It is particularly preferable that the insulator 425 be provided in contact with the bottom surface of the insulator 250. With such a structure, the transistor 200 and the capacitor 400 can be provided without a great increase in the occupation area in a plan view. Thus, the occupation area of the memory cell 450 can be reduced, so that the memory cells 450 can be arranged densely and the memory capacity of the memory device can be increased. In other words, the memory device can be highly integrated.

Note that although the diameter of the opening portion 490 is larger than the diameter of the opening portion 290 in FIG. 2A, the present invention is not limited thereto and the diameter of the opening portion 490 can be smaller than the diameter of the opening portion 290. The diameter of the opening portion 490 can be the same or substantially the same as the diameter of the opening portion 290.

As described above, a barrier insulator against hydrogen is preferably used as the insulator 440. For example, silicon nitride is used for the insulator 440. Such a structure can inhibit diffusion of impurities such as hydrogen from below the insulator 440 into the insulator 480 and the like.

As the insulator 485, an insulator that can be used as the insulator 270 described above may be used. For example, silicon oxide is used for the insulator 485.

The conductor 410 is provided over the insulator 440. As the conductor 410, a single layer or stacked layers of any of the conductors described in the section [Conductor] below can be used. For example, a conductive material with high conductivity such as tungsten can be used for the conductor 410. With the use of a conductive material with high conductivity, the conductor 410 can have improved conductivity and can work well as a wiring.

A single layer or stacked layers of a conductive material that is less likely to be oxidized, a conductive material having a function of inhibiting diffusion of oxygen, or the like is preferably used for the conductor 410. For example, titanium nitride, indium tin oxide to which silicon is added, or the like may be used. As illustrated in FIG. 4, the conductor 410 may have a stacked-layer structure of a conductor 410a and a conductor 410b. In that case, the conductor 410a can be formed in contact with the bottom surface and a side surface of the conductor 410b. For example, titanium nitride is used for the conductor 410a and tungsten is used for the conductor 410b. Furthermore, a structure in which a titanium nitride film is provided over the conductor 410b can be employed. Such a structure can inhibit the conductor 410 from being oxidized by the insulator 480 and the insulator 485 when an oxide insulator is used as the insulator 480 and the insulator 485.

The insulator 480, which functions as an interlayer film, preferably has a low relative dielectric constant. When a material with a low relative dielectric constant is used for an interlayer film, the parasitic capacitance generated between wirings can be reduced. As the insulator 480, a single layer or stacked layers of any of the insulators each containing a material with low relative dielectric constant described in the section [Insulator] below can be used. Silicon oxide and silicon oxynitride are preferable because they are thermally stable. In that case, the insulator 480 contains at least silicon and oxygen.

As illustrated in FIG. 4, the insulator 480 can also have a stacked-layer structure of an insulator 480a and an insulator 480b over the insulator 480a. As the insulator 480a, an insulator containing any of the above-described materials with a low relative dielectric constant (e.g., silicon oxide) may be used. As the insulator 480b, an insulator having a function of capturing or fixing hydrogen is preferably used as described above. For example, hafnium silicate is used for the insulator 480b. Such a structure enables the hydrogen concentration in the oxide semiconductor 230 and the vicinity thereof to be reduced.

In the case where the insulator 480 has a stacked-layer structure, any of the insulators having a barrier property against hydrogen, which are described in the section [Insulator], may be used for one or more layers of the insulator 480. In that case, diffusion of hydrogen into the insulator 430 from below through the insulator 480. Silicon nitride and silicon nitride oxide can be suitably used for the insulator 480 because they release fewer impurities (e.g., water and hydrogen) and are less likely to transmit oxygen and hydrogen.

As the conductor 415, a single layer or stacked layers of any of the conductors described in the section [Conductor] can be used. A conductive material that is less likely to be oxidized, a conductive material having a function of inhibiting diffusion of oxygen, or the like is preferably used for the conductor 415. For example, titanium nitride, tantalum nitride, or the like can be used. For another example, a structure in which tantalum nitride is stacked over titanium nitride may be employed. Such a structure can inhibit the conductor 415 from being oxidized by the insulator 430 when an oxide insulator is used as the insulator 430. Such a structure can also inhibit the conductor 415 from being oxidized by the insulator 480 when an oxide insulator is used as the insulator 480. However, without limitation to this structure, tungsten or the like may be used for the conductor 415. For example, the conductor 415 may have a structure in which tungsten is stacked over titanium nitride.

The insulator 430 is provided over the conductor 415. The insulator 430 is provided in contact with the top surface and the side surface of the conductor 415. Here, the insulator 430 preferably covers a side end portion of the conductor 415. In that case, a short circuit between the conductor 415 and the conductor 420 can be prevented.

For the insulator 430, any of the materials with a high relative dielectric constant, that is, high-k materials, described in the section [Insulator] is preferably used. Using a high-k material for the insulator 430 allows the insulator 430 to be thick enough to inhibit leakage current and the capacitor 400 to have a sufficiently large capacitance.

For the insulator 430, a stack of insulating layers formed of high-k materials is preferably used, and a stacked-layer structure of a high relative dielectric constant (high-k) material and a material having higher dielectric strength than the high-k material is preferably used. For the insulator 430, an insulating film in which zirconium oxide, aluminum oxide, and zirconium oxide are stacked in this order can be used, for example. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor 400.

A material that can have ferroelectricity may be used for the insulator 430. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the ratio of the number of hafnium atoms to the number of element J1 atoms can be set as appropriate; the ratio of the number of hafnium atoms to the number of element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The ratio of the number of zirconium atoms to the number of element J2 atoms can be set as appropriate; the ratio of the number of zirconium atoms to the number of element J2 atoms can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1, the element M2, and the element M3 can be set as appropriate.

Examples of the material that can have ferroelectricity also include a perovskite-type oxynitride such as SrTaO₂N or BaTaO₂N, GaFeO₃ with a κ-alumina-type structure, and the like.

In the above description, metal oxides and metal nitrides are presented as non-limiting examples. For example, a metal oxynitride in which nitrogen is added to any of the above metal oxides, a metal nitride oxide in which oxygen is added to any of the above metal nitrides, or the like may be used.

The material that can have ferroelectricity can be, for example, a mixture or a compound formed of a plurality of materials selected from the above-listed materials. Alternatively, the insulator 430 can have a stacked-layer structure of a plurality of materials selected from the above-listed materials. Note that the crystal structures (properties) of the above-listed materials and the like can be changed depending on the processes as well as the deposition conditions; thus, only a material that exhibits ferroelectricity is referred to as a material that can have ferroelectricity as well as a ferroelectric in this specification and the like.

A metal oxide containing one or both of hafnium and zirconium is preferable because the metal oxide can have ferroelectricity even when being a thin film of several nanometers. Here, the thickness of the insulator 430 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness is preferably greater than or equal to 8 nm and less than or equal to 12 nm, for example. When a ferroelectric layer that can be thinned is used, the capacitor 400 can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even a ferroelectric layer with an area less than or equal to 10000 nm² or less than or equal to 1000 nm² has ferroelectricity in some cases. With a small-area ferroelectric layer, the occupation area of the capacitor 400 can be reduced.

The ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 400, the semiconductor device described in this embodiment functions as a ferroelectric memory.

It is considered that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulator 430 can exhibit ferroelectricity, the insulator 430 needs to include a crystal. It is particularly preferable that the insulator 430 include a crystal having an orthorhombic crystal structure, in which case the insulator 430 exhibits ferroelectricity. Note that a crystal structure of a crystal included in the insulator 430 may be one or more selected from a cubic crystal structure, a tetragonal crystal structure, an orthorhombic crystal structure, a monoclinic crystal structure, and a hexagonal crystal structure. Alternatively, the insulator 430 may have an amorphous structure. In that case, the insulator 430 may have a composite structure including an amorphous structure and a crystal structure.

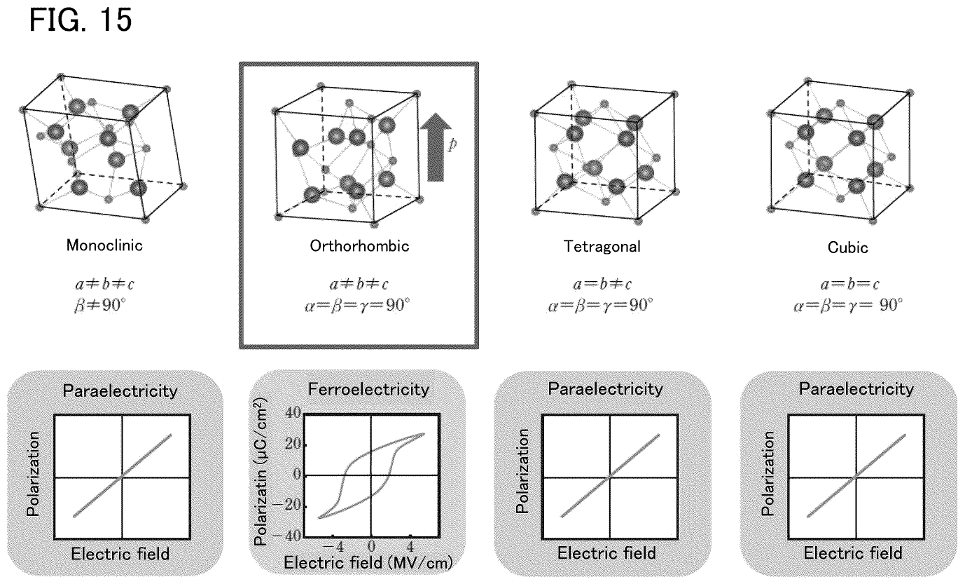

Crystal structures of hafnium oxide, which is a material that can be used for the insulator 430, are described here. As reported in Non-Patent Document 2, hafnium oxide is known to adopt a variety of crystal structures. As an example, FIG. 15 shows possible crystal structures of hafnium oxide such as monoclinic (space group: P2₁/c), orthorhombic (space group: Pbca or Pca2₁), tetragonal (space group: P4₂/nmc), cubic (space group: Fm-3m) crystal structures and the polarization-electric field characteristics of the crystal structures. Phase transition can occur between the above-described crystal structures. Note that the same applies to hafnium zirconium oxide.

The monoclinic, tetragonal, and cubic crystal structures of hafnium oxide each have an inversion center. Thus, hafnium oxide containing crystals with these crystal structures is a paraelectric that does not have remanent polarization. By contrast, the orthorhombic crystal structure whose space group is Pca2₁ is non-centrosymmetric. In the orthorhombic crystal structure whose space group is Pca2₁, oxygen is displaced by an external electric field; thus, ferroelectricity is exhibited in hafnium oxide containing crystals with the orthorhombic crystal structure whose space group is Pca2₁. Note that the same applies to hafnium zirconium oxide.

The conductor 420 is provided in contact with the top surface of the insulator 430. As the conductor 420, like the conductor 415, a single layer or stacked layers of any of the conductors described in the section [Conductor] can be used. A conductive material that is less likely to be oxidized, a conductive material having a function of inhibiting diffusion of oxygen, or the like is preferably used for the conductor 420. For example, titanium nitride, tantalum nitride, or the like can be used. For another example, a structure in which tantalum nitride is stacked over titanium nitride may be used. Such a structure can inhibit the conductor 420 from being oxidized by the insulator 430 and the insulator 425 when an oxide insulator is used as the insulator 430 and the insulator 425. Such a structure can also inhibit the conductor 420 from being oxidized by the conductor 220 when an oxide conductor is used as the conductor 220. However, without limitation to this structure, a conductor such as tungsten may be used as the conductor 415.

Here, a structure in which a side end portion of the insulator 430 and a side end portion of the conductor 420 are aligned with each other is preferably employed. In that case, the insulator 430 and the conductor 420 can be formed using the same mask. Furthermore, a structure in which a side end portion of the conductor 220, the side end portion of the insulator 430, and the side end portion of the conductor 420 are aligned with each other is preferably employed. In that case, the conductor 220, the insulator 430, and the conductor 420 can be formed using the same mask. With the above-described structures, the manufacturing process of the semiconductor device can be simplified.

The insulator 425 is provided in contact with the conductor 420 and the insulator 250. The top surface of the insulator 425 and the top surface of the conductor 420 are preferably flush with each other. Such a structure allows favorable flatness of the surface where the insulator 250 is formed, thereby inhibiting generation of disconnection, a void, or the like in the insulator 250.

The insulator 425 preferably has a low relative dielectric constant. As the insulator 425, a single layer or stacked layers of any of the insulators each containing a material with a low relative dielectric constant described in the section [Insulator] can be used. Silicon oxide and silicon oxynitride are preferable because they are thermally stable. In that case, the insulator 425 contains at least silicon and oxygen.

By forming the insulator 425 with a low relative dielectric constant, the distance between the conductor 260 and the conductor 420 can be increased. This can reduce the parasitic capacitance between the gate of the transistor 200 and the upper electrode of the capacitor 400 can be reduced. Accordingly, the operation speed of the memory cell 450 including the transistor 200 and the capacitor 400 can be improved.

### Example of Method for Manufacturing Semiconductor Device

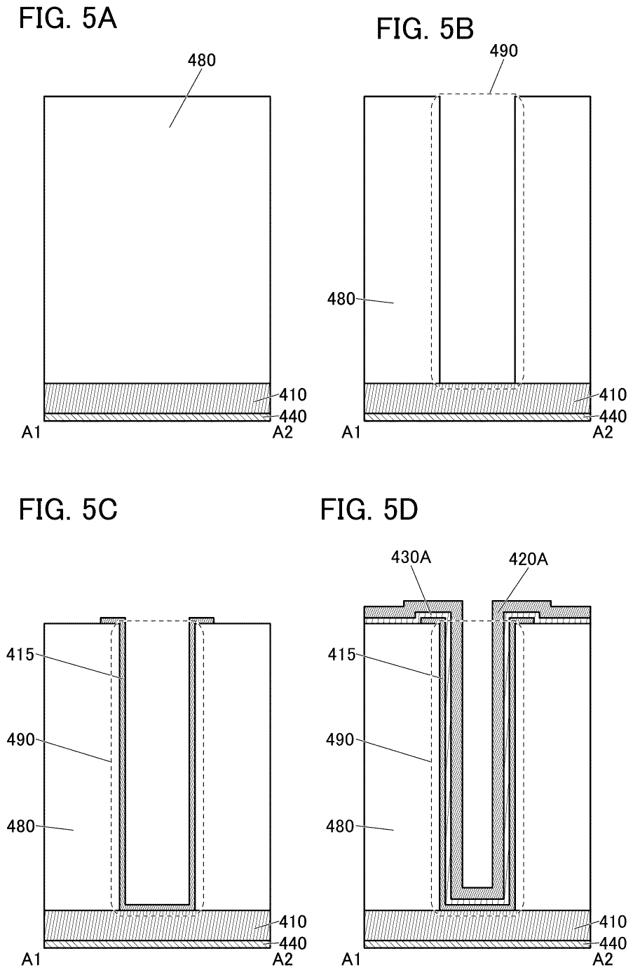

Next, a method for manufacturing the semiconductor device illustrated in FIG. 1A to FIG. 2C and the like will be described with reference to FIG. 5A to FIG. 8F.

Hereinafter, a film of an insulating material for forming an insulator, a film of a conductive material for forming a conductor, or a film of a semiconductor material for forming a semiconductor can be formed using a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. An RF sputtering method is mainly used in the case where an insulating film is formed, and a DC sputtering method is mainly used in the case where a metal conductive film is formed. The pulsed DC sputtering method is mainly used in the case where a compound such as an oxide, a nitride, or a carbide is formed by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. A thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of a thermal CVD method, which does not use plasma, and thus the yield of the semiconductor device can be increased. In addition, a thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are deposition methods that enable favorable step coverage almost regardless of the shape of an object to be processed. In particular, an ALD method enables excellent step coverage and excellent thickness uniformity and thus is suitable for covering a surface of an opening portion with a high aspect ratio, for example. Meanwhile, an ALD method has a relatively low deposition rate, and thus is preferably used in combination with another deposition method with a high deposition rate, such as a CVD method, in some cases.

By a CVD method, a film with a certain composition can be deposited depending on the flow rate ratio of the source gases. For example, by a CVD method, a film whose composition is continuously changed can be deposited by changing the flow rate ratio of the source gases during deposition. In the case where a film is deposited while the flow rate ratio of the source gases is changed, the time taken for transfer or pressure adjustment is saved, and thus, the time taken for the deposition can be shortened as compared to the case where a film is deposited using a plurality of deposition chambers. Thus, the productivity of the semiconductor device can be increased in some cases.

By an ALD method, a film with a certain composition can be formed by introducing different kinds of precursors. For example, in the case where different kinds of precursors are introduced, a film with a certain composition can be formed by controlling the number of cycles for each of the precursors.

In the case where different kinds of precursors are introduced by an ALD method, the kind of oxidizer may be changed depending on each precursor. For example, in the case where at least a first precursor and a second precursor are introduced, ozone (O₃) may be used as an oxidizer for the first precursor and oxygen (O₂) may be used as an oxidizer for the second precursor.

Heat treatment may be performed before formation of a film. This heat treatment may be performed under reduced pressure, and the film may be successively formed without exposure to the air. Such treatment can remove moisture and hydrogen adsorbed onto the surface over which the film is to be formed, and further can reduce the moisture concentration and the hydrogen concentration in a structure body that serves as the surface over which the film is to be formed. The temperature of the heat treatment is preferably higher than or equal to 100 °C and lower than or equal to 600 °C.

### Example of Method for Manufacturing Capacitor

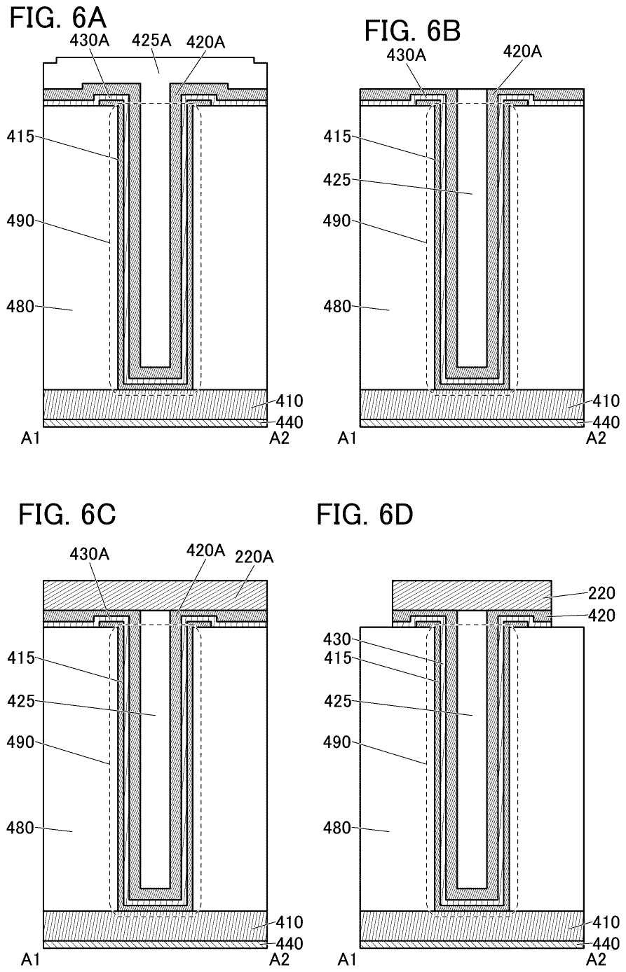

First, a method for manufacturing the capacitor 400 will be described with reference to FIG. 5A to FIG. 6D. Note that FIG. 5A to FIG. 5D and FIG. 6A to FIG. 6D correspond to the capacitor 400 in FIG. 1A.

First, a substrate (not illustrated) is prepared, and the insulator 440 is formed over the substrate (see FIG. 5A). The insulator 440 is formed using a sputtering method, a CVD method, an MBE method, a PLD method, an ALD method, or the like as appropriate. For example, silicon nitride can be deposited by a sputtering method as the insulator 440.

Next, the conductor 410 is formed over the insulator 440 (see FIG. 5A). The conductor 410 is preferably formed to be embedded in the insulator 485 as illustrated in FIG. 1B. Any of the above-described materials can be used for the conductor 410 and the insulator 485. For example, after the insulator 485 is formed, an opening is formed in the insulator 485, a conductive film to be the conductor 410 is formed to fill the opening, and an upper portion of the conductive film is removed by CMP treatment, so that the conductor 410 can be formed in the opening.

Conductive films to be the insulator 485 and the conductor 410 can be deposited using a sputtering method, a CVD method, an MBE method, a PLD method, an ALD method, or the like as appropriate. For example, silicon oxide can be deposited by a sputtering method as the insulator 485. In the case where the conductor 410 has the stacked-layer structure of the conductor 410a and the conductor 410b as illustrated in FIG. 4, titanium nitride can be deposited by an ALD method or a CVD method as a conductive film to be the conductor 410a, and tungsten can be deposited by a CVD method as a conductive film to be the conductor 410b.

Next, the insulator 480 is formed over the conductor 410 (see FIG. 5A). Any of the above-described insulating materials is used for the insulator 480 as appropriate. The insulator 480 is formed using a sputtering method, a CVD method, an MBE method, a PLD method, an ALD method, or the like as appropriate. For example, as the insulator 480, silicon oxide can be deposited by a CVD method using an organosilane gas (e.g., TEOS (Tetra-Ethyl-Ortho-Silicate)) and silicon oxide can be deposited thereover by a sputtering method. Here, with the use of a CVD method with a high deposition rate, the insulator 480 with a large thickness can be deposited with high productivity. Furthermore, by using a sputtering method that does not require hydrogen-containing molecules as a deposition gas, the concentration of hydrogen in a layer of the insulator 480 that is close to the oxide semiconductor 230 can be reduced.

In the case where the insulator 480 has the stacked-layer structure of the insulator 480a and the insulator 480b as illustrated in FIG. 4, silicon oxide can be deposited as described above as the insulator 480a, and hafnium silicate can be deposited as the insulator 480b by a sputtering method. In this case, a deposition target containing hafnium and silicon is used. For example, a co-sputtering method using a silicon oxide target and a hafnium oxide target is used. When an insulator having a function of capturing or fixing hydrogen is used as the insulator 480b in this manner, the concentration of hydrogen in the insulator 480 can be reduced and oxygen vacancies and VoH in the channel formation region of the oxide semiconductor 230 can be reduced.

Next, part of the insulator 480 is processed to form the opening portion 490 reaching the conductor 410 (see FIG. 5B). The opening portion 490 is formed by a lithography method. For details of the lithography method, the method for forming the opening portion 290 of the transistor 200 can be referred to.

A dry etching method or a wet etching method can be used to form the opening portion 490. A dry etching method enables anisotropic etching and thus is suitable for forming the opening portion 490 with a high aspect ratio. However, the opening portion 490 can also be formed using a dry etching method and a wet etching method as appropriate. For details of the dry etching method and the wet etching method, the method for forming the opening portion 290 of the transistor 200 can be referred to.

The top surface of the deposited insulator 480 is preferably planarized by CMP treatment. The planarization treatment performed on the insulator 480 allows the conductor 420 functioning as an electrode to be formed favorably. Note that the CMP treatment is not necessarily performed. By not performing the CMP treatment, the manufacturing process of the semiconductor device can be shortened and the manufacturing cost can be reduced.

Next, a conductive film to be the conductor 415 is deposited to cover the opening portion 490 and the insulator 480. The conductive film to be the conductor 415 is deposited using a sputtering method, a CVD method, an MBE method, a PLD method, an ALD method, or the like as appropriate. The conductive film is preferably formed in contact with the sidewall and bottom surface of the opening portion 490 with a high aspect ratio. Thus, the conductive film is preferably deposited by a deposition method that offers good coverage, such as an ALD method or a CVD method. For example, titanium nitride can be deposited by an ALD method or CVD.

Then, the conductive film is processed by a lithography method to form the conductor 415 (see FIG. 5C). Accordingly, the conductor 415 is formed in contact with the sidewall and bottom surface of the opening portion 490. Part of the conductor 415 is formed over the opening portion 490 to be in contact with part of the top surface of the insulator 480. When the conductor 415 is formed, part of the top surface of the insulator 480 may be removed. This may cause the thickness of a portion of the insulator 480 that overlaps with the conductor 415 to be larger than the thickness of a portion of the insulator 480 that does not overlap with the conductor 415.

Next, an insulating film 430A is deposited over the conductor 415 and the insulator 480 (see FIG. 5D). The insulating film 430A is an insulating film to be the insulator 430 in a later step. The insulating film 430A is deposited using a sputtering method, a CVD method, an MBE method, a PLD method, an ALD method, or the like as appropriate. The insulating film 430A is deposited in the opening portion 490 with a high aspect ratio, and thus is preferably deposited by a deposition method that offers good coverage, such as an ALD method or a CVD method. For example, an ALD method can be used to deposit zirconium oxide, aluminum oxide, and zirconium oxide in this order.

Then, a conductive film 420A is deposited over the insulating film 430A (see FIG. 5D). The conductive film 420A is a conductive film to be the conductor 420 in a later step. The conductive film 420A is deposited using a sputtering method, a CVD method, an MBE method, a PLD method, an ALD method, or the like as appropriate. The conductive film 420A is deposited in the opening portion 490 with a high aspect ratio, and thus is preferably deposited by a deposition method that offers good coverage, such as an ALD method or a CVD method. For example, titanium nitride can be deposited by an ALD method or CVD. The conductive film 420A is subjected to CMP treatment in a later step, and thus is preferably thicker than the conductor 415.

Next, an insulating film 425A is deposited to fill a depressed portion defined by the conductive film 420A (see FIG. 6A). The insulating film 425A is an insulating film to be the insulator 425 in a later step. The insulating film 425A is deposited using a sputtering method, a CVD method, an MBE method, a PLD method, an ALD method, or the like as appropriate. For example, silicon oxide can be deposited by a sputtering method as the insulating film 425A. Note that the insulator 425 can function as an interlayer film with a low relative dielectric constant as described above. Thus, the insulating film 425A is not necessarily deposited with good coverage in the opening portion 490 and a pore may be formed in the insulating film 425A in the opening portion 490.

Then, CMP treatment is performed on the insulating film 425A to remove a portion of the insulating film 425A that is positioned above the conductive film 420A, so that the insulator 425 is formed (see FIG. 6B). By the CMP treatment, only a portion of the insulating film 425A that is positioned in the opening portion 490 remains to be the insulator 425. The CMP treatment is performed until the top surface of the conductive film 420A is exposed. At this time, part of the top surface of the conductive film 420A may be removed. In addition, part of the insulating film 425A may remain in a region not overlapping with the opening portion 490.

Next, a conductive film 220A is deposited over the conductive film 420A and the insulator 425 (see FIG. 6C). The conductive film 220A is a conductive film to be the conductor 220 in a later step. The conductive film 220A is deposited using a sputtering method, a CVD method, an MBE method, a PLD method, an ALD method, or the like as appropriate. For example, as the conductive film 220A, ITSO can be deposited by a sputtering method. In the case where the conductor 220 has the stacked-layer structure of the conductor 220a and the conductor 220b as illustrated in FIG. 3B, as the conductive film 220A, tungsten can be deposited first by a sputtering method and then ITSO can be deposited by a sputtering method.

Next, the conductive film 220A, the conductive film 420A, and the insulating film 430A are processed into island shapes by a lithography method to form the conductor 220, the conductor 420, and the insulator 430 (see FIG. 6D). A dry etching method or a wet etching method can be used to process the conductive film 220A, the conductive film 420A, and the insulating film 430A. Processing by a dry etching method is suitable for microfabrication. However, a dry etching method and a wet etching method can also be used as appropriate to perform the processing.

Here, the processing is preferably performed such that the conductor 220, the conductor 420, and the insulator 430 overlap with the opening portion 490. By forming the conductor 220, the conductor 420, and the insulator 430 in this manner, the transistor 200 can be manufactured to overlap with the capacitor 400; thus, high integration of the semiconductor element can be achieved. In addition, by forming the conductor 220, the conductor 420, and the insulator 430 at a time as described above, the side surface of the conductor 220, the side surface of the conductor 420, and the side surface of the insulator 430 are flush with each other. By forming the conductor 220, the conductor 420, and the insulator 430 at a time, the manufacturing process of the semiconductor device can be simplified and the manufacturing cost can be reduced. Note that without limitation to the above, the conductor 220, the conductor 420, and the insulator 430 can be processed using different masks.

### Example of Method for Manufacturing Transistor

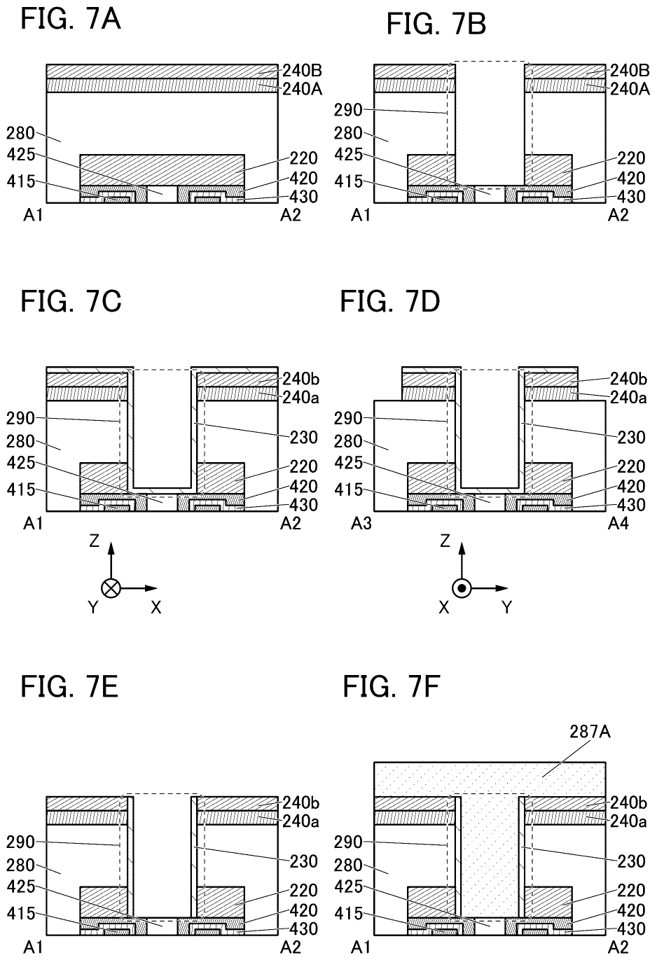

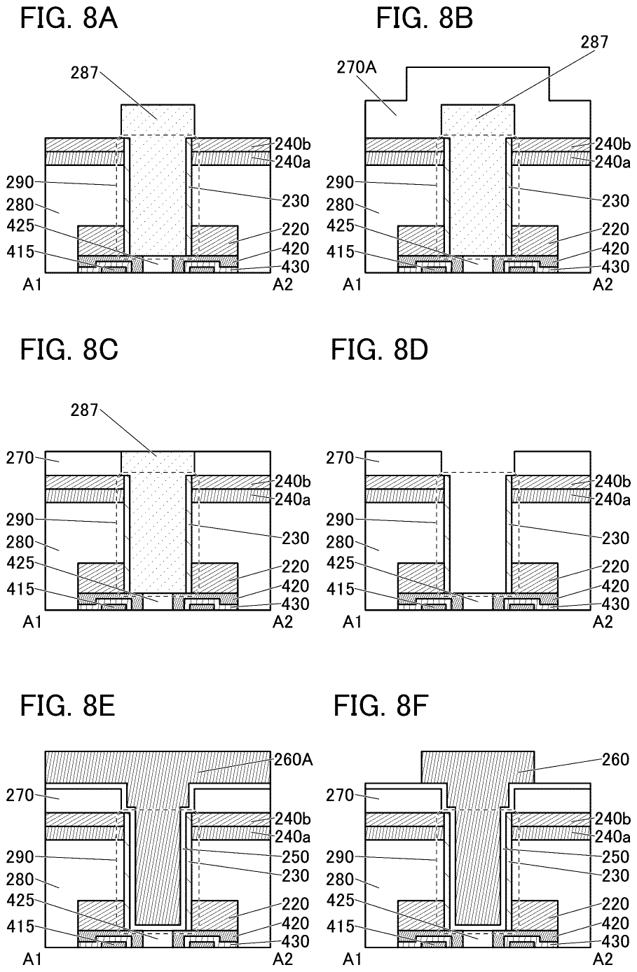

Next, a method for manufacturing the transistor 200 will be described with reference to FIG. 7A to FIG. 8F. Note that FIG. 7A to FIG. 7C and FIG. 7E to FIG. 8F correspond to the transistor 200 in FIG. 1A. FIG. 7D corresponds to the transistor 200 in FIG. 1B.

First, the insulator 280 is formed over the insulator 480 and the conductor 220 (see FIG. 7A). Any of the above-described insulating materials is used for the insulator 280 as appropriate. The insulator 280 can be deposited by a sputtering method, a CVD method, an MBE method, a PLD method, an ALD method, or the like as appropriate. For example, the insulator 280 can have the structure including the insulator 280a, the insulator 280b, and the insulator 280c as illustrated in FIG. 3A. In that case, silicon nitride can be deposited by a PEALD method as the insulator 280a, silicon oxide can be deposited by a sputtering method as the insulator 280b, and silicon nitride can be deposited by a sputtering method as the insulator 280c. The top surface of the deposited insulator 280 is preferably planarized by CMP treatment. The planarization treatment performed on the insulator 280 allows the conductor 240 functioning as a wiring to be formed favorably.

Note that the CMP treatment may be skipped in some cases. In that case, the top surface of the insulator 280 has an upward-convex curved shape. By not performing planarization treatment, the manufacturing cost can be reduced and the production yield can be increased.

Note that planarization treatment is not always performed after the insulator 280a to the insulator 280c are formed. For example, planarization treatment may be performed after the insulator 280a and the insulator 280b are formed, and then the insulator 280c may be formed.

By using a sputtering method that does not need to use a molecule containing hydrogen in a deposition gas for formation of the insulator 280, the hydrogen concentration in the insulator 280 can be reduced. When the insulator 280 is formed in this manner, the amount of hydrogen diffused from the insulator 280 into the oxide semiconductor 230 can be reduced and oxygen vacancies and VoH in the channel formation region can be reduced.

Next, a conductive film 240A is deposited over the insulator 280, and a conductive film 240B is deposited over the conductive film 240A (see FIG. 7A). The conductive film 240A is to be the conductor 240a in a later step, and the conductive film 240B is to be the conductor 240b in a later step. Any of the above-described conductive materials is used for the conductive film 240A and the conductive film 240B as appropriate. The conductive film 240A and the conductive film 240B are each deposited by a sputtering method, a CVD method, an MBE method, a PLD method, an ALD method, or the like as appropriate. For example, as the conductive film 240A, tungsten can be deposited by a sputtering method. As the conductive film 240B, ITSO can be deposited by a sputtering method.

Then, part of the conductive film 240A, part of the conductive film 240B, part of the insulator 280, and part pf the conductor 220 are processed to form the opening portion 290 reaching the insulator 425 and the conductor 420 (see FIG. 7B). The opening portion 290 is formed by a lithography method.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

Note that the resist mask that is no longer needed after the processing can be removed by dry etching treatment such as ashing using oxygen plasma (hereinafter, sometimes referred to as oxygen plasma treatment), wet etching treatment, wet etching treatment after dry etching treatment, or dry etching treatment after wet etching treatment.

An SOC (Spin On Carbon) film and an SOG (Spin On Glass) film may be formed between an object to be processed and the resist mask. Using the SOC film and the SOG film as masks can improve the durability of a mask pattern. For example, the SOC film, the SOG film, and the resist mask are formed in this order over the object to be processed and a lithography method can be performed. A hard mask formed of an insulator or a conductor can be provided between the object to be processed and the SOC film.

For example, an SOC film, an SOG film, and a resist mask are formed in this order over the conductive film 240B and the resist mask can be patterned into the shape of the opening portion 290.

A dry etching method or a wet etching method can be used to form the opening portion 290. A dry etching method enables anisotropic etching and thus is suitable for forming the opening portion 290 with a high aspect ratio. However, a dry etching method and a wet etching method can also be used as appropriate to form the opening portion 290.

Here, as an etching gas for the dry etching treatment, an etching gas containing a halogen can be used, and specifically, an etching gas containing one or more of fluorine, chlorine, and bromine can be used. As the etching gas, for example, a C₄F₆ gas, a C₅F₆ gas, a C₄F₈ gas, a CF₄ gas, a SF₆ gas, a CHF₃ gas, a CH₂F₂ gas, a CH₃F gas, a Cl₂ gas, a BCl₃ gas, a SiCl₄ gas, a CCl₄gas, a HBr gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that contains a hydrocarbon gas or a hydrogen gas and does not contain a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes can have a structure in which a high-frequency voltage is applied to one of the parallel plate electrodes. Alternatively, a structure can be employed in which high-frequency voltages with the same frequency are applied to the parallel plate electrodes. Alternatively, a structure can be employed in which different high-frequency voltages are applied to the parallel plate electrodes. Such a CCP etching apparatus is referred to as a dual frequency capacitively coupled plasma (DF-CCP) etching apparatus. In the DF-CCP etching apparatus, a structure can be employed in which high-frequency voltages with different frequencies are applied to the parallel plate electrodes. Alternatively, a structure can be employed in which different high-frequency voltages are applied to one of the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched. Note that in the above dry etching apparatus, a high-frequency voltage is applied to the electrode on the substrate side to generate a self-bias potential, whereby reactive ion etching can be performed. In reactive ion etching, ion species in plasma are accelerated to collide with an object to be processed, whereby etching with high anisotropy can be performed.

Note that the following steps of forming the opening portion 290 are preferably performed successively without exposure to the air. For example, the treatment is performed without exposure to the air by using a multi-chamber etching apparatus.

The above-described etching gas and etching apparatus can be selected as appropriate according to the structures of the SOG film, the SOC film, the conductive film 240B, the conductive film 240A, and the insulator 280. For example, in the case where an ITSO film is used as the conductive film 240B, the treatment can be performed with a DF-CCP etching apparatus using CH₄ and an argon gas as etching gases. For example, in the case where a tungsten film is used as the conductive film 240A, the treatment can be performed with a DF-CCP etching apparatus using Cl₂, CF₄, and an oxygen gas as etching gases. For example, in the case where a stacked-layer film of silicon oxide and silicon nitride is used as the insulator 280, the treatment can be performed with a DF-CCP etching apparatus using C₄F₈, C₄F₆, an oxygen gas, and an argon gas as etching gases. The conductor 220 is exposed to the etching gases for the insulator 280.

In order to remove impurities and the like attached to the opening portion 290 in the etching step, cleaning treatment is preferably performed. As a cleaning method, wet cleaning using a cleaning solution or the like (which can also be referred to as wet etching treatment) can be employed. The conductor 220 can be etched by the wet cleaning to form the opening portion 290.

The wet cleaning may be performed using an aqueous solution in which one or more of oxalic acid, phosphoric acid, and hydrofluoric acid are diluted with carbonated water or pure water. The wet cleaning may be performed using an aqueous solution in which ammonia water is diluted with carbonated water or pure water. The wet cleaning may be performed using pure water, carbonated water, or the like. Alternatively, ultrasonic cleaning using such an aqueous solution, pure water, or carbonated water may be performed. Alternatively, these cleanings may be performed in combination as appropriate. The cleaning treatment may be performed a plurality of times, and the cleaning solution may be changed in every cleaning treatment. For example, the wet cleaning is performed using diluted hydrofluoric acid obtained by diluting hydrofluoric acid with pure water. By performing wet cleaning using diluted hydrofluoric acid, the conductor 220 exposed to the etching gases for the insulator 280 is etched, so that the opening portion 290 reaching the insulator 425 and the conductor 420 can be formed.

The opening portion 290 of the conductor 220 is not necessarily formed by the wet cleaning. For example, the opening portion 290 of the conductor 220 may be formed by a dry etching method successively after the dry etching treatment performed on the insulator 280.

After formation of the opening portion 290, microwave treatment may be performed in an oxygen-containing atmosphere to reduce the impurity concentration in the insulator 280. Here, the microwave treatment refers to, for example, treatment using an apparatus including a power source that generates high-density plasma with use of a microwave. In this specification and the like, a microwave refers to an electromagnetic wave having a frequency higher than or equal to 300 MHz and lower than or equal to 300 GHz. Specific examples of the impurity include hydrogen and carbon. When the insulator 280 is subjected to microwave treatment in an oxygen-containing atmosphere, hydrogen contained in the insulator 280 can be released as H₂O to the outside. Release of hydrogen from the insulator 280 positioned in the vicinity of the oxide semiconductor 230 enables formation of a highly reliable semiconductor device.

Next, heat treatment may be performed. The heat treatment may be performed without exposure to the air successively after the microwave treatment. The heat treatment is performed at higher than or equal to 250 °C and lower than or equal to 650 °C, preferably higher than or equal to 300 °C and lower than or equal to 500 °C, further preferably higher than or equal to 320 °C and lower than or equal to 450 °C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas can be approximately 20%. The heat treatment may be performed under reduced pressure. Alternatively, the heat treatment may be performed in an atmosphere containing an oxidizing gas at 10ppm or more, 1% or more, or 10% or more after heat treatment is performed in a nitrogen gas or inert gas atmosphere. By the above-described heat treatment, impurities such as water contained in the insulator 280 or the like can be reduced before formation of the later-described oxide semiconductor film to be the oxide semiconductor 230. Note that the heat treatment is preferably performed under the condition where the conductor 220 and the conductor 240 are not excessively oxidized.

The gas used in the above heat treatment is preferably highly purified. For example, the amount of moisture contained in the gas used in the above heat treatment can be less than or equal to 1 ppb, preferably less than or equal to 0.1 ppb, further preferably less than or equal to 0.05 ppb. The heat treatment using a highly purified gas can prevent entry of moisture or the like into the insulator 280 and the like as much as possible.

Although the heat treatment is performed after the microwave treatment in the above description, the present invention is not limited thereto. The microwave treatment can be performed after the heat treatment.

Next, an oxide semiconductor film to be the oxide semiconductor 230 is formed in contact with the top surface of the insulator 425, the top surface of the conductor 420, the side surface of the insulator 280, the side surface of the conductive film 240A, and the top surface and side surface of the conductive film 240B. For the oxide semiconductor film, any of the above-described metal oxides that can be used for the oxide semiconductor 230 is used as appropriate. The oxide semiconductor film is formed using a sputtering method, a CVD method, an MBE method, a PLD method, an ALD method, or the like as appropriate.

For example, as in FIG. 3A, a stacked-layer film of oxide semiconductors can be formed such that a stacked-layer structure of the oxide semiconductor 230a and the oxide semiconductor 230b is obtained. In that case, an oxide semiconductor film to be the oxide semiconductor 230a can be deposited by a sputtering method, and an oxide semiconductor film to be the oxide semiconductor 230b can be deposited thereover by an ALD method. The oxide semiconductor film to be the oxide semiconductor 230a can be formed using a target with a composition of In:Ga:Zn=1:1:1.2 [atomic ratio] or in the neighborhood thereof. The oxide semiconductor film to be the oxide semiconductor 230b can be formed to have a composition of In:Ga:Zn=1:1:1 [atomic ratio] or in the neighborhood thereof.

The microwave treatment and the heat treatment may be performed after the deposition of the oxide semiconductor film.

Next, the oxide semiconductor film to be the oxide semiconductor 230, the conductive film 240A, and the conductive film 240B are processed by a lithography method to form the oxide semiconductor 230, the conductor 240a, and the conductor 240b (see FIG. 7C and FIG. 7D). A dry etching method or a wet etching method can be used to process the oxide semiconductor film to be the oxide semiconductor 230, the conductive film 240A, and the conductive film 240B. Processing by a dry etching method is suitable for microfabrication.

Thus, the conductor 240a and the conductor 240b are formed to extend in the X direction and can function as wirings. Like the conductor 240a and the conductor 240b, the oxide semiconductor 230 is formed to extend in the X direction. However, part of the oxide semiconductor 230 is formed in the opening portion 290. Here, as illustrated in FIG. 7D, the side surface of the oxide semiconductor 230, the side surface of the conductor 240a, and the side surface of the conductor 240b are preferably formed to be flush with each other.

Although the oxide semiconductor 230, the conductor 240a, and the conductor 240b are formed at a time in the above description, the present invention is not limited thereto. For example, the conductive film 240A and the conductive film 240B can be processed after the oxide semiconductor 230 is formed. In that case, the side surface of the oxide semiconductor 230 is positioned inward from the side surface of the conductor 240a and the side surface of the conductor 240b.

Next, the oxide semiconductor 230 is processed by anisotropic etching, so that the oxide semiconductor 230 having a sidewall shape is formed in the opening portion 290 (see FIG. 7E). A portion of the oxide semiconductor 230 that is in contact with the top surface of the conductor 240b and a portion of the oxide semiconductor 230 that is in contact with the bottom surface of the opening portion 290 are removed by the processing. Thus, the top surfaces of the insulator 425 and the conductor 420 in the opening portion 290 and the top surface of the conductor 240b are exposed from the oxide semiconductor 230 by the processing.

A dry etching method is preferably employed for the anisotropic etching. For example, reactive ion etching is preferably performed. By performing anisotropic etching, the oxide semiconductor 230 can be processed into a sidewall shape even in the opening portion 290 having a high aspect ratio. Note that in some cases, part of the oxide semiconductor 230 remains in contact with the side surface of the conductor 240b on the opening portion 290 side and the side surfaces of the conductor 240a and the conductor 240b on the side opposite to the opening portion 290. With such a method, part of the bottom surface of the oxide semiconductor can be removed without using a mask.

Here, the oxide semiconductor 230 is preferably formed in contact with the side surface of the conductor 220, the side surface of the insulator 280, the side surface of the conductor 240a, and the side surface of the conductor 240b in the opening portion 290. When the oxide semiconductor 230 is formed in contact with the side surface of the conductor 220, the conductor 220 functions as one of a source electrode and a drain electrode of the transistor 200. When the oxide semiconductor 230 is formed in contact with the conductor 240b, the conductor 240a and the conductor 240b function as the other of the source electrode and the drain electrode of the transistor 200.

Next, a coating film 287A is formed to fill the opening portion 290 (see FIG. 7F). The coating film 287A can be formed in the following manner: an SOC film is applied first, and an SOG film is applied thereover. The coating film 287A functions as a sacrificial layer at the time of forming the insulator 270.

Next, the coating film 287A is processed by a lithography method to form a sacrificial layer 287 that protrudes from the opening portion 290 (see FIG. 8A). The sacrificial layer 287 can be patterned in accordance with the shape of an opening of the insulator 270 to be formed later. A dry etching method or a wet etching method can be used to process the coating film 287A. Processing by a dry etching method is suitable for microfabrication. Here, when the sacrificial layer 287 has a structure in which an SOG film is stacked over an SOC film, the sacrificial layer 287 can be prevented from losing its shape during the above processing.

Next, an insulating film 270A to be the insulator 270 is deposited to cover the sacrificial layer 287 and the oxide semiconductor 230 (see FIG. 8B). Any of the above-described insulating materials is used for the insulating film 270A as appropriate. The insulating film 270A is deposited using a sputtering method, a CVD method, an MBE method, a PLD method, an ALD method, or the like as appropriate. For example, silicon oxide can be deposited by a sputtering method as the insulating film 270A. By using a sputtering method that does not need to use a molecule containing hydrogen in a deposition gas for formation of the insulating film 270A, the hydrogen concentration in the insulating film 270A can be reduced. When the insulating film 270A is deposited in this manner, the amount of hydrogen diffused from the insulating film 270A into the oxide semiconductor 230 can be reduced and oxygen vacancies and VoH in the channel formation region can be reduced.

In the case where the insulator 270 has the stacked-layer structure of the insulator 270a and the insulator 270b as illustrated in FIG. 3A and the like, as the insulating film 270A, an aluminum oxide film can be deposited first by an ALD method and then a silicon oxide film can be deposited by a sputtering method. In that case, an upper portion of the sacrificial layer 287 is covered with the aluminum oxide film. When the silicon oxide film is deposited by a sputtering method while the sacrificial layer 287 is covered with the aluminum oxide film in this manner, the sacrificial layer 287 can be prevented from losing its shape during the deposition of the silicon oxide film.

Next, the insulating film 270A is subjected to CMP treatment until the sacrificial layer 287 is exposed, whereby the insulator 270 is formed (see FIG. 8C). In this case, the SOG film, which is in the upper portion of the sacrificial layer 287, is also removed so that the SOC film of the sacrificial layer 287 is exposed.

Next, the sacrificial layer 287 is removed to form an opening overlapping with the opening portion 290 in the insulator 270 (see FIG. 8D). The sacrificial layer 287 can be removed by dry etching treatment such as ashing, wet etching treatment, wet etching treatment after dry etching treatment, or dry etching treatment after wet etching treatment.

Next, the insulator 250 is deposited over the insulator 270, the oxide semiconductor 230, the conductor 420, and the insulator 425 (see FIG. 8E). Any of the above-described insulating materials is used for the insulator 250 as appropriate. The insulator 250 can be deposited using a sputtering method, a CVD method, an MBE method, a PLD method, an ALD method, or the like as appropriate. The insulator 250 is preferably formed in contact with the oxide semiconductor 230 provided in the opening portion 290. The insulator 250 is preferably formed in contact with the insulator 425 and the conductor 420 that serve as the bottom surface of the opening portion 290. Thus, the insulator 250 is preferably deposited by a deposition method that offers good coverage, and is further preferably deposited by a CVD method, an ALD method, or the like. For example, as illustrated in FIG. 3A, the insulator 250 can have a stacked-layer structure of the insulator 250a, the insulator 250b, and the insulator 250c. For example, aluminum oxide can be deposited by a thermal ALD method as the insulator 250a, silicon oxide can be deposited by a PEALD method as the insulator 250b, and hafnium oxide can be deposited by a thermal ALD method as the insulator 250c.

The microwave treatment and the heat treatment may be performed after the formation of the insulator 250. In the case where the insulator 250 has a stacked-layer structure, the microwave treatment is not necessarily performed after all the insulators included in the insulator 250 are formed. For example, in the case of the structure illustrated in FIG. 3A, microwave treatment may be performed after the insulator 250b is formed, and then the insulator 250c may be formed. Alternatively, for example, microwave treatment may be performed after the insulator 250b is formed, and then microwave treatment may be performed after the insulator 250c is formed. In this manner, the microwave treatment in an oxygen-containing atmosphere may be performed multiple times.

Next, a conductive film 260A to be the conductor 260 is deposited to fill the depressed portion defined by the insulator 250. Any of the above-described conductive materials can be used for the conductive film 260A as appropriate. The conductive film 260A can be deposited using a sputtering method, a CVD method, an MBE method, a PLD method, an ALD method, or the like as appropriate. Here, the conductive film 260A is preferably formed in contact with the insulator 250 provided in the opening portion 290. Thus, the conductive film is preferably deposited by a deposition method that offers good coverage or a good filling property, and is further preferably deposited by a CVD method, an ALD method, or the like. For example, as the conductive film 260A, titanium nitride can be deposited by a CVD method or an ALD method and tungsten can be deposited over the titanium nitride by a CVD method.

Although the conductive film 260A is provided to fill the opening portion 290 in the above description, the present invention is not limited thereto. For example, a depressed portion reflecting the shape of the opening portion 290 is formed in a center portion of the conductive film in some cases. The depressed portion may be filled with an inorganic insulating material or the like.

Next, the conductive film to be the conductive film 260A is processed to form the conductor 260 (see FIG. 8F). The conductor 260 is formed by a lithography method. A dry etching method or a wet etching method can be used for the processing. Processing by a dry etching method is suitable for microfabrication.

Alternatively, CMP treatment can be performed on the conductive film 260A and the insulator 250 to remove portions of the conductive film 260A and the insulator 250 that are positioned above the insulator 270. In that case, the remaining portion of the conductive film 260A corresponds to the conductor 260a and the conductor 260b illustrated in FIG. 3B, and the remaining portion of the insulator 250 corresponds to the insulator 250 illustrated in FIG. 3B. After that, the conductor 260c functioning as a wiring can be formed over the conductor 260a and the conductor 260b.

Next, the insulator 283 is formed to cover the conductor 260 and the insulator 250 (see FIG. 1A and FIG. 1B). Any of the above-described insulating materials is used for the insulator 283 as appropriate. The insulator 283 can be deposited using a sputtering method, a CVD method, an MBE method, a PLD method, an ALD method, or the like as appropriate. As the insulator 283, for example, a silicon nitride film can be formed by a PEALD method.

The microwave treatment and the heat treatment may be performed after the formation of the insulator 283. In the case where an insulator having a function of inhibiting diffusion of hydrogen is used as the insulator 440 and the insulator 283 and an insulator having a function of capturing or fixing hydrogen is used as the insulator 480b and the insulator 250, heat treatment can be performed in a state where the insulator 480b and the insulator 250 are provided in a region sandwiched between the insulator 440 and the insulator 283. Accordingly, hydrogen in the region sandwiched between the insulator 440 and the insulator 283 can be captured or fixed by the insulator 480b and the insulator 250. Thus, the hydrogen concentration in the channel formation region of the oxide semiconductor 230 can be reduced. Therefore, the transistor can have favorable electrical characteristics and improved reliability. Moreover, a semiconductor device with a small variation in electrical characteristics of transistors can be provided.

Through the above process, the transistor 200 illustrated in FIG. 1A to FIG. 2C and the like can be manufactured.

### Variation Example of Semiconductor Device

Although the semiconductor device in FIG. 1A to FIG. 2C has a structure in which the insulator 250 is formed after the insulator 270 is formed, the present invention is not limited thereto. For example, the insulator 270 can be formed after the insulator 250 is formed.

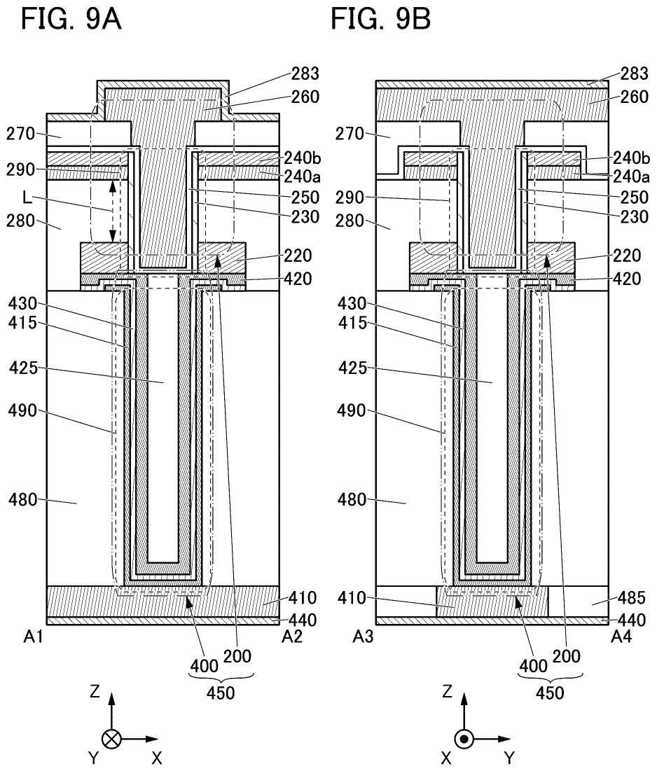

FIG. 9A and FIG. 9B illustrate another example of the semiconductor device of one embodiment of the present invention. FIG. 9A and FIG. 9B are cross-sectional views of the semiconductor device. Here, FIG. 9A corresponds to a cross-sectional view along A1-A2 in FIG. 1A. FIG. 9B corresponds to a cross-sectional view along A3-A4 in FIG. 1B.

The semiconductor device illustrated in FIG. 9 is different from the semiconductor device illustrated in FIG. 1A to FIG. 2C in that the insulator 270 is provided over the insulator 250. Differences from the description with reference to FIG. 1A to FIG. 2C are mainly described below; the description is referred to for the same portions, and the description of the same portions is omitted in some cases.

As illustrated in FIG. 9A, in a region not overlapping with the opening portion 290, the insulator 250 is provided in contact with the top surface of the conductor 240b, and the insulator 270 is provided in contact with the top surface of the insulator 250. The top surface of the insulator 270 is in contact with the conductor 260 and the insulator 283. As illustrated in FIG. 9B, the insulator 250 is provided to cover the side surface of the conductor 240b and the side surface of the conductor 240a. The insulator 250 is in contact with the top surface of the insulator 280 outside the conductor 240.

In the case where the transistor 200 has the shape illustrated in FIG. 9A and FIG. 9B, the insulator 250 can be deposited after the oxide semiconductor 230 is formed into a sidewall shape in the step illustrated in FIG. 7E. After that, the semiconductor device can be manufactured according to the steps in FIG. 7F to FIG. 8F.

Although the semiconductor device in FIG. 1A to FIG. 2C has a structure in which the insulator 270 is formed, the present invention is not limited thereto. For example, a structure in which the insulator 270 is not formed can be employed.

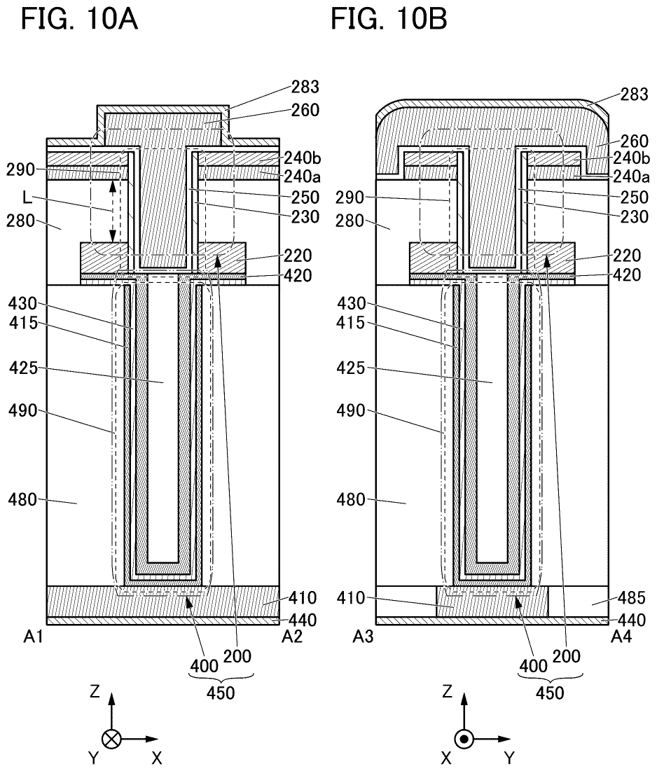

FIG. 10A and FIG. 10B illustrate another example of the semiconductor device of one embodiment of the present invention. FIG. 10A and FIG. 10B are cross-sectional views of the semiconductor device. Here, FIG. 10A corresponds to a cross-sectional view along A1-A2 in FIG. 1A. FIG. 10B corresponds to a cross-sectional view along A3-A4 in FIG. 1B.

The semiconductor device illustrated in FIG. 10A and FIG. 10B is different from the semiconductor device illustrated in FIG. 1A to FIG. 2C mainly in that the insulator 270 is not provided. Differences from the description with reference to FIG. 1A to FIG. 2C are mainly described below; the description is referred to for the same portions, and the description of the same portions is omitted in some cases.

As illustrated in FIG. 10A, the insulator 250 is provided in contact with the top surface of the conductor 240b. As illustrated in FIG. 10B, the insulator 250 is provided to cover the side surface of the conductor 240b and the side surface of the conductor 240a. The insulator 250 is in contact with the top surface of the insulator 280 outside the conductor 240.

In the case where the transistor 200 has the shape illustrated in FIG. 10A and FIG. 10B, the steps illustrated in FIG. 7F to FIG. 8D can be omitted. That is, the oxide semiconductor 230 is formed into a sidewall shape in the step illustrated in FIG. 7E, and then the steps illustrated in FIG. 8E and FIG. 8F are performed, whereby the semiconductor device can be manufactured. When the manufacturing steps are omitted as described above, the productivity of the semiconductor device can be improved.

The capacitor 400 illustrated in FIG. 10 is different from the capacitor 400 illustrated in FIG. 1A to FIG. 2C in that the upper end portion of the conductor 415 is flush with the top surface of the insulator 480. Such a shape prevents the conductor 415 from protruding from the opening portion 490, so that the conductor 415 can be sufficiently covered with the insulator 430 and a short circuit between the conductor 420 and the conductor 415 can be prevented.

In the case where the capacitor 400 has the shape illustrated in FIG. 10A and FIG. 10B, part of the conductive film to be the conductor 415 that is positioned above the insulator 480 can be removed by CMP treatment in the step illustrated in FIG. 5C.

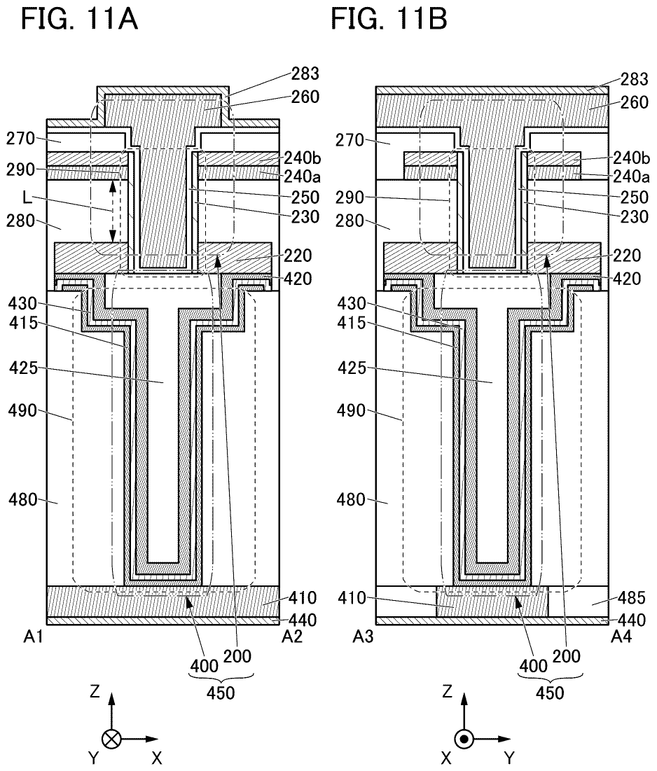

FIG. 11A and FIG. 11B illustrate another example of the semiconductor device of one embodiment of the present invention. FIG. 11A and FIG. 11B are cross-sectional views of the semiconductor device. Here, FIG. 11A corresponds to a cross-sectional view along A1-A2 in FIG. 1A. FIG. 11B corresponds to a cross-sectional view along A3-A4 in FIG. 1B.

The semiconductor device illustrated in FIG. 11A and FIG. 11B is different from the semiconductor device illustrated in FIG. 1A to FIG. 2C mainly in that the width of the opening portion 490 is increased in the vicinity of the top surface of the insulator 480. Differences from the description with reference to FIG. 1A to FIG. 2C are mainly described below; the description is referred to for the same portions, and the description of the same portions is omitted in some cases.

As illustrated in FIG. 11A and FIG. 11B, the width of the opening portion 490 in the vicinity of the top surface of the insulator 480 is larger than that in the vicinity of the bottom surface of the insulator 480. It can also be said that the diameter of the opening portion 490 in the vicinity of the top surface of the insulator 480 is larger than that in the vicinity of the bottom surface of the insulator 480. Accordingly, the width of the insulator 425 in the vicinity of the top surface of the insulator 480 is also larger than that in the vicinity of the bottom surface of the insulator 480. In this case, the bottom surface of the insulator 250 is not in contact with the conductor 420 but is in contact only with the insulator 425.

The above structure can increase the distance between the conductor 260 and the conductor 420. This can further reduce the parasitic capacitance between the gate of the transistor 200 and the upper electrode of the capacitor 400. Accordingly, the operation speed of the memory cell 450 including the transistor 200 and the capacitor 400 can be further improved.

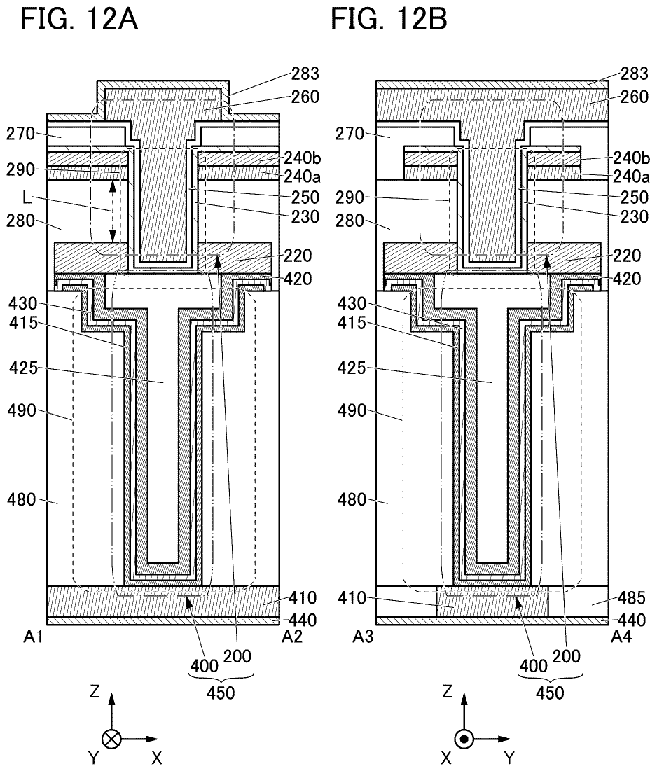

Although the oxide semiconductor 230 is removed at the bottom portion of the opening portion 290 in the transistor 200 illustrated in FIG. 11A, FIG. 11B, and the like, the present invention is not limited thereto. As illustrated in FIG. 12A and FIG. 12B, the oxide semiconductor 230 can be formed to the bottom portion of the opening portion 290. In that case, the bottom surface of the oxide semiconductor 230 is in contact with the top surface of the insulator 425.

In the case where the transistor 200 has the shape illustrated in FIG. 12A and FIG. 12B, the step illustrated in FIG. 7E can be omitted. Thus, as illustrated in FIG. 7D, the side surface of the oxide semiconductor 230 can be flush with the side surface of the conductor 240a opposite to the opening portion 290 and the side surface of the conductor 240b opposite to the opening portion 290. When the manufacturing step is omitted as described above, the productivity of the semiconductor device can be improved.

When the structure enabling the parasitic capacitance between the transistor 200 and the capacitor 400 to be reduced is employed as described above, the electrical characteristics and operation speed of the semiconductor device can be improved. For example, the on-state current of the transistor 200 can be higher than or equal to 30 μA. The S value of the transistor 200 can be greater than or equal to 60 m V/dec and less than or equal to 90 m V/dec, preferably greater than or equal to 60 m V/dec and less than or equal to 80 m V/dec, further preferably greater than or equal to 60 m V/dec and less than or equal to 70 m V/dec. The threshold voltage can be higher than 0 V and lower than or equal to 1 V, preferably higher than 0 V and lower than or equal to 0.5 V, further preferably higher than or equal to 0.1 V and lower than or equal to 0.3 V. In other words, the transistor 200 is capable of normally-off operation. In addition, when the operation speed of the memory cell 450 is improved, the writing speed of the memory cell 450 can be lower than 1.7 nsec by applying 1.8 V to the wiring WOL (the conductor 260). When the transistor 200 and the capacitor 400 of one embodiment of the present invention have the above-described structures, a semiconductor device that operates at high speed and has high reliability can be provided. Note that in a plan view, the size of the memory cell 450 can be greater than or equal to 30 nm and less than or equal to 100 nm, preferably greater than or equal to 40 nm and less than or equal to 50 nm. For example, the pitch of the wiring WOL (the conductor 260) connected to the memory cell 450 can be greater than or equal to 40 nm and less than or equal to 200 nm, preferably greater than or equal to 50 nm and less than or equal to 60 nm. When the memory cell 450 has the above-described size, high-density memory cells can be provided.

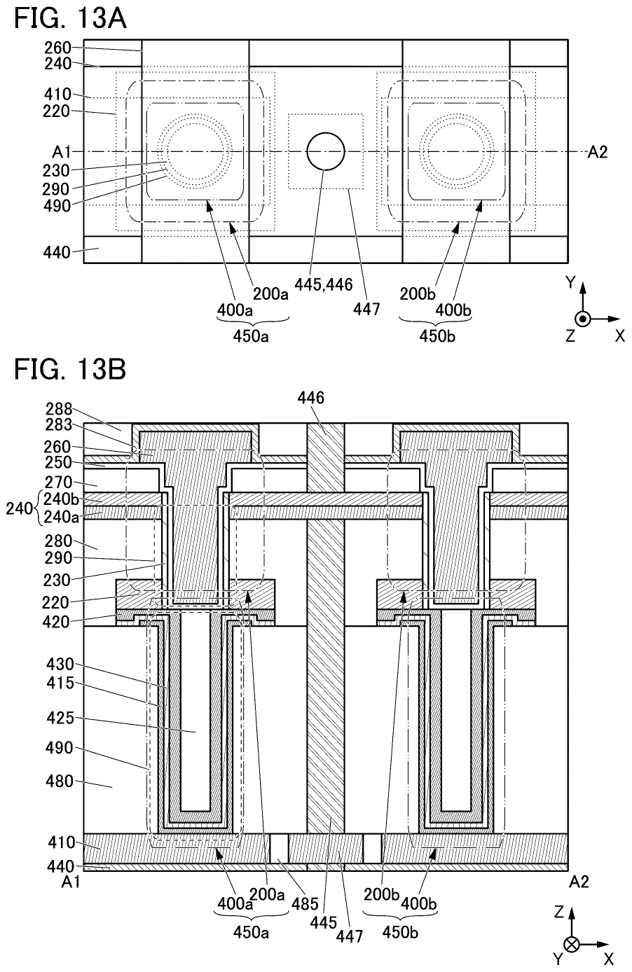

FIG. 13A and FIG. 13B illustrate another example of the semiconductor device of one embodiment of the present invention. FIG. 13A is a plan view of the semiconductor device. FIG. 13B is a cross-sectional view of a portion indicated by the dashed-dotted line A1-A2 in FIG. 13A. Note that some components are omitted in the plan view of FIG. 13A for clarity of the drawing.

The semiconductor device illustrated in FIG. 13A and FIG. 13B is different from the semiconductor device illustrated in FIG. 1A to FIG. 2C mainly in that two memory cells 450 (hereinafter referred to as a memory cell 450a and a memory cell 450b) are connected to a common wiring. The memory cell 450a and the memory cell 450b illustrated in FIG. 13A and FIG. 13B each have a structure similar to that of the memory cell 450. The memory cell 450a includes a capacitor 400a and a transistor 200a, and the memory cell 450b includes a capacitor 400b and a transistor 200b. Thus, in the semiconductor device illustrated in FIG. 13A and FIG. 13B, components having the same functions as the components of the semiconductor device illustrated in FIG. 1A to FIG. 2C are denoted by the same reference numerals.

As illustrated in FIG. 13A and FIG. 13B, the conductor 260 functioning as the wiring WOL is provided in each of the memory cell 450a and the memory cell 450b. The conductor 240 functioning as part of the wiring BIL is provided to be shared by the memory cell 450a and the memory cell 450b. That is, the conductor 240 is in contact with the oxide semiconductor 230 of the memory cell 450a and the oxide semiconductor 230 of the memory cell 450b.

Here, the semiconductor device illustrated in FIG. 13A and FIG. 13B includes a conductor 445 and a conductor 446 functioning as plugs (which can also be referred to as connection electrodes) electrically connected to the memory cell 450a and the memory cell 450b. The conductor 445 is placed in an opening formed in the insulator 480 and the insulator 280 and is in contact with the bottom surface of the conductor 240a and the top surface of the conductor 447 formed in the same layer as the conductor 410. Here, like the conductor 410, the conductor 447 is preferably provided to be embedded in the insulator 485. The conductor 446 is placed in an opening formed in an insulator 288, the insulator 283, the insulator 250, and the insulator 270 and is in contact with the top surface of the conductor 240b. A conductor similar to the conductor 446 may be provided under the conductor 447. Note that a conductive material or the like that can be used for the conductor 240 can be used for the conductor 445 and the conductor 446.

The insulator 288 is provided over the insulator 283. The insulator 288 functions as an interlayer film and thus preferably has a low relative dielectric constant. When a material with low relative dielectric constant is used for an interlayer film, the parasitic capacitance generated between wirings can be reduced. As the insulator 288, like the insulator 270, a single layer or stacked layers of any of the insulators each containing a material with a low relative dielectric constant described in the section [Insulator] can be used.

The conductor 445 and the conductor 446 function as plugs or wirings for electrically connecting the memory cell 450a and the memory cell 450b to a circuit element such as a switch, a transistor, a capacitor, an inductor, a resistor, or a diode, a wiring, an electrode, or a terminal. For example, the memory cell 450a and the memory cell 450b can be electrically connected to a sense amplifier provided below a semiconductor device functioning as a memory device or to another semiconductor device provided above the semiconductor device. In that case, the conductor 445 and the conductor 446 function as part of the wiring BIL. When the semiconductor device functioning as a memory device or the like is provided above or below the semiconductor device functioning as a memory device illustrated in FIG. 13A and FIG. 13B as described above, the memory capacity per unit area can be increased.

The memory cell 450a and the memory cell 450b have a line-symmetric structure with a perpendicular bisector of the dashed-dotted line A1-A2 as the symmetric axis. Thus, the transistor 200a and the transistor 200b are also placed symmetrically with the conductor 445 and the conductor 446 therebetween. Here, the conductor 240 has a function of the other of a source electrode and a drain electrode of the transistor 200a and a function of the other of a source electrode and a drain electrode of the transistor 200b. The transistor 200a and the transistor 200b share the conductor 445 and the conductor 446 functioning as plugs. With the above connection structure between the two transistors and the plugs, a semiconductor device that can be miniaturized or highly integrated can be provided.

Note that the conductor 410 functioning as the wiring CAL may be provided in each of the memory cell 450a and the memory cell 450b or may be provided to be shared by the memory cell 450a and the memory cell 450b. However, as illustrated in FIG. 13B, the conductor 410 is provided to be apart from the conductor 447 so that the conductor 410 and the conductor 447 are not short-circuited.

### Constituent Materials of Semiconductor Device

Constituent materials that can be used for the semiconductor device will be described below.

### [Substrate]

As a substrate where the transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of the insulator include an insulating oxide, an insulating nitride, an insulating oxynitride, an insulating nitride oxide, an insulating metal oxide, an insulating metal oxynitride, and an insulating metal nitride oxide.

As scaling down and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In addition, the equivalent oxide thickness (EOT) of the insulator functioning as the gate insulator can be reduced. By contrast, when a material with a low relative dielectric constant is used for an insulator functioning as an interlayer insulating film, the parasitic capacitance generated between wirings can be reduced. Thus, a material is preferably selected in accordance with the function of the insulator. Note that the material with a low relative dielectric constant is a material with high dielectric strength.

Examples of the material with a high relative dielectric constant (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of the inorganic insulating material with a low relative dielectric constant include silicon oxide to which fluorine is added, silicon oxide to which carbon is added, and silicon oxide to which carbon and nitrogen are added. Another example is porous silicon oxide. These silicon oxides may contain nitrogen.

A material that can have ferroelectricity may be used for the insulator. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the ratio of the number of hafnium atoms to the number of element J1 atoms can be set as appropriate; the ratio of the number of hafnium atoms to the number of element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The ratio of the number of zirconium atoms to the number of element J2 atoms can be set as appropriate; the ratio of the number of zirconium atoms to the number of element J2 atoms can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

When a transistor including a metal oxide is surrounded by an insulator having a function of inhibiting passage of impurities and oxygen, the transistor can have stable electrical characteristics. As the insulator having a function of inhibiting passage of impurities and oxygen, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulator that is in contact with a semiconductor or provided in the vicinity of a semiconductor layer, such as a gate insulator, preferably includes a region containing oxygen released by heating (hereinafter, sometimes referred to as excess oxygen). For example, when an insulator including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of a barrier insulator against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

The description in Embodiment 1 can be referred to for a barrier insulator against hydrogen.

The barrier insulator against oxygen and the barrier insulator against hydrogen can each be regarded as a barrier insulator against one or both of oxygen and hydrogen.

The description in Embodiment 1 can be referred to for an insulator having a function of capturing or fixing hydrogen.

### [Conductor]

As a conductor, it is preferable to use a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide, indium tin oxide containing titanium oxide, indium tin oxide to which silicon is added, indium zinc oxide, and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may also be employed. A stacked-layer structure combining a material containing the above metal element, a conductive material containing oxygen, and a conductive material containing nitrogen may also be employed.

In the case where a metal oxide is used for the channel formation region of the transistor, the conductor functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of the lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects in a semiconductor layer of a transistor may cause unstable electrical characteristics of the transistor. Hence, a metal oxide used in a semiconductor layer of a transistor preferably has a small number of lattice defects.

The kind of a lattice defect that is likely to exist in a metal oxide and the number of lattice defects that exist vary depending on the structure of the metal oxide, a method for depositing the metal oxide, or the like.

Structures of metal oxides are classified into a single crystal structure and other structures (non-single-crystal structures). Examples of the non-single-crystal structure include a CAAC structure, a polycrystalline structure, an nc structure, an amorphous-like (a-like) structure, and an amorphous structure. An a-like structure has a structure between an nc structure and an amorphous structure.

A metal oxide having an a-like structure and a metal oxide having an amorphous structure each include a void or a low-density region. That is, the metal oxide having the a-like structure and the metal oxide having the amorphous structure have lower crystallinity than a metal oxide having an nc structure and a metal oxide having a CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Therefore, a metal oxide with high crystallinity is preferably used for a semiconductor layer of a transistor. For example, it is preferable to use the metal oxide having the CAAC structure or the metal oxide having the single crystal structure. The use of such a metal oxide for a transistor enables the transistor to have excellent electrical characteristics. In addition, a transistor with high reliability can be achieved.

For a channel formation region of a transistor, a metal oxide that increases the on-state current of the transistor is preferably used. To increase the on-state current of the transistor, the carrier mobility of the metal oxide used for the transistor is preferably increased. To increase the carrier mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure in which a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS (c-axis-aligned crystalline oxide semiconductor), and the like.

The c-axis of the above crystal is preferably aligned in the normal direction with respect to the formation surface or the film surface of the metal oxide. This enables the plurality of layers to be placed parallel or substantially parallel to the formation surface or the film surface of the metal oxide. That is, the plurality of layers extend in the channel length direction.

The above three-layer crystal structure is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and variant structures of these structures.

Each of the first layer to the third layer is preferably composed of oxygen and one metal element or a plurality of metal elements with the same valence. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. Note that the element M is a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may include a metalloid element.

For example, as the metal oxide of one embodiment of the present invention, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide; also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers. Alternatively, the metal oxide may contain, in addition to indium, one or more kinds of metal elements with large period numbers in the periodic table. The larger the overlap between orbits of metal elements is, the more likely it is that the metal oxide will have high carrier conductivity. Thus, a transistor containing a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

By increasing the proportion of the number of In atoms in the total number of atoms of all the metal elements contained in the metal oxide, a high on-state current and high frequency characteristics of the transistor can be achieved.

In the description of this embodiment, an In—Ga—Zn oxide is sometimes taken as an example of the metal oxide.

For the formation of a metal oxide having the layered crystal structure, an atomic layer is preferably deposited one by one. Since an ALD method is used as the film formation method of a metal oxide in one embodiment of the present invention, a metal oxide having the layered crystal structure is easily formed.

### [Transistor Including Metal Oxide]

Next, the case where a metal oxide (oxide semiconductor) is used for a transistor will be described. Hereinafter, a transistor including silicon in a semiconductor layer is sometimes referred to as a Si transistor.

When a metal oxide (oxide semiconductor) of one embodiment of the present invention is used for a transistor, a transistor with high field-effect mobility can be achieved. In addition, a transistor with high reliability can be achieved. Furthermore, a miniaturized or highly integrated transistor can be achieved. For example, a transistor with a channel length greater than or equal to 2 nm and less than or equal to 30 nm can be manufactured.

An oxide semiconductor with a low carrier concentration is preferably used for a channel formation region of the transistor. For example, the carrier concentration in the channel formation region of the oxide semiconductor is lower than or equal to 1×10¹⁸ cm⁻³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a large band gap, and thus the short-channel effect can be suppressed. In other words, the OS transistor is a transistor in which the short-channel effect does not appear or hardly appears.

Note that the short-channel effect refers to degradation of electrical characteristics which becomes obvious along with miniaturization (a decrease in channel length) of a transistor. Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage keeps constant and the drain current changes by one order of magnitude.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to the short-channel effect than the Si transistor. That is, the OS transistor is more suitable than the Si transistor in the case where a short-channel transistor is to be manufactured.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n-type region and the source and drain regions become n⁺-type regions in the OS transistor.

An OS transistor having the above structure enables favorable electrical characteristics even when the semiconductor device is miniaturized or highly integrated. For example, the semiconductor device can have favorable electrical characteristics even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Therefore, the OS transistor can be used as a transistor having a short channel length more suitably the Si transistor. Note that the gate length refers to the length of a gate electrode in a direction in which carriers move inside a channel formation region during an operation of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

As described above, the OS transistor has effects superior to those of the Si transistor, such as a low off-state current and capability of having a short channel length.

### [Impurity in Metal Oxide]

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm 3, further preferably lower than or equal to 3×10¹⁸ atoms/cm³, and further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1 ×10¹⁹ atoms/cm³, further preferably lower than or equal to 3×10¹⁸ atoms/cm³, and further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, and further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, the transistor can have stable electrical characteristics.

### [Other Semiconductor Materials]

The oxide semiconductor 230 can be rephrased as a semiconductor layer including a channel formation region of the transistor. The semiconductor material that can be used for the semiconductor layer is not limited to the above metal oxides. A semiconductor material that has a band gap (a semiconductor material that is not a zero-gap semiconductor) may be used for the semiconductor layer. For example, a single-element semiconductor, a compound semiconductor, or a layered substance (also referred to as an atomic layer substance, a two-dimensional material, or the like) is preferably used as a semiconductor material.

Here, in this specification and the like, the layered substance generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure.

Examples of the layered substance include graphene, silicene, boron carbonitride, and chalcogenide. Boron carbonitride serving as the layered substance contains carbon atoms, nitrogen atoms, and boron atoms arranged in a hexagonal lattice structure on a plane. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer, transition metal chalcogenide functioning as a semiconductor is preferably used, for example. Specific examples of the transition metal chalcogenide which can be used for a semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

This embodiment can be combined with the other embodiments and the example as appropriate. In this specification, in the case where a plurality of structure examples are shown in one embodiment, the structure examples can be combined as appropriate.

### Embodiment 2

A semiconductor device 900 of one embodiment of the present invention will be described in this embodiment. The semiconductor device 900 can function as a memory device.

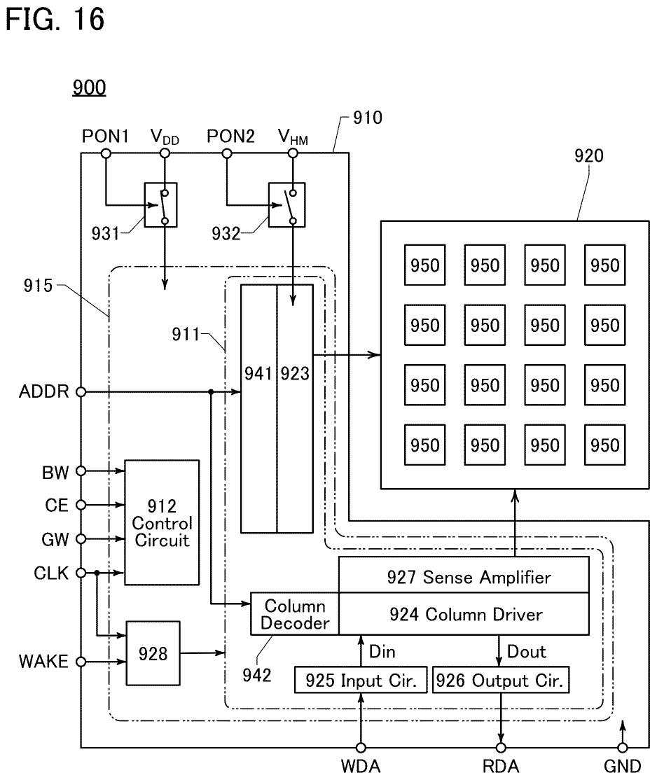

FIG. 16 is a block diagram showing a structure example of the semiconductor device 900. The semiconductor device 900 shown in FIG. 16 includes a driver circuit 910 and a memory array 920. The memory array 920 includes one or more memory cells 950. FIG. 16 shows an example in which the memory array 920 includes a plurality of the memory cells 950 arranged in a matrix.

The memory cell 450 including the transistor 200 and the capacitor 400, which is described as an example in Embodiment 1, can be used as the memory cell 950. The use of the memory cell 450 allows miniaturization and high integration of the memory device. In addition, the capacity per area of the memory device can be increased. Moreover, the operation speed of the memory device can be improved.

The driver circuit 910 includes a PSW 931 (a power switch), a PSW 932, and a peripheral circuit 915. The peripheral circuit 915 includes a peripheral circuit 911, a control circuit 912 (Control Circuit), and a voltage generation circuit 928.

In the semiconductor device 900, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 912.

The control circuit 912 is a logic circuit having a function of controlling the overall operation of the semiconductor device 900. For example, the control circuit 912 performs logical operation on the signal CE, the signal GW, and the signal BW to determine an operation mode of the semiconductor device 900 (e.g., write operation or read operation). Alternatively, the control circuit 912 generates a control signal for the peripheral circuit 911 so that the operation mode is executed.

The voltage generation circuit 928 has a function of generating a negative voltage. The signal WAKE has a function of controlling the input of the signal CLK to the voltage generation circuit 928. For example, when an H-level signal is supplied as the signal WAKE, the signal CLK is input to the voltage generation circuit 928, and the voltage generation circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed, and the column decoder 942 is a circuit for specifying a column to be accessed. The row driver 923 has a function of selecting the row specified by the row decoder 941. The column driver 924 has a function of writing data to the memory cell 950, a function of reading data from the memory cell 950, a function of retaining the read data, and the like.

The input circuit 925 has a function of retaining the signal WDA. Data retained by the input circuit 925 is output to the column driver 924. Data output from the input circuit 925 is data (Din) to be written to the memory cell 950. Data (Dout) read from the memory cell 950 by the column driver 924 is output to the output circuit 926. The output circuit 926 has a function of retaining Dout. In addition, the output circuit 926 has a function of outputting Dout to the outside of the semiconductor device 900. Data output from the output circuit 926 is the signal RDA.

The PSW 931 has a function of controlling the supply of VDD to the peripheral circuit 915. The PSW 932 has a function of controlling supply of VHM to the row driver 923. Here, in the semiconductor device 900, a high power supply voltage is VDD and a low power supply voltage is GND (a ground potential). In addition, VHM is a high power supply voltage used to set the word line at a high level and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 16 but can be more than one. In that case, a power switch is provided for each power domain.

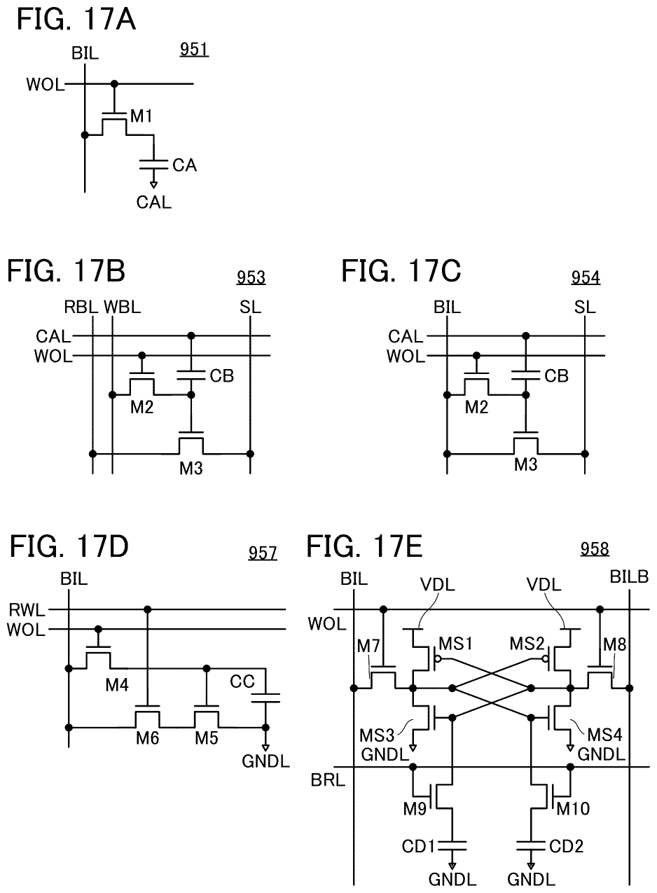

Structure examples of other memory cells that can be used for the memory cell 950 will be described with reference to FIG. 17A to FIG. 17E.

### [DOSRAM]

FIG. 17A illustrates a circuit structure example of a memory cell of DRAM. In this specification and the like, a DRAM using an OS transistor is referred to as a DOSRAM (Dynamic Oxide Semiconductor Random Access Memory). A memory cell 951 includes a transistor M1 and a capacitor CA.

Note that the transistor M1 may include a front gate (simply referred to as a gate in some cases) and a back gate. In that case, the back gate may be connected to a wiring supplied with a constant potential or a signal, and the front gate and the back gate may be connected to each other.

A first terminal of the transistor M1 is connected to a first terminal of the capacitor CA, a second terminal of the transistor MI is connected to a wiring BIL, and a gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. In data writing and reading, a low-level potential (referred to as a reference potential in some cases) is preferably applied to the wiring CAL.

Data writing and reading are performed as follows: a high-level potential is applied to the wiring WOL to turn on the transistor M1 so that the wiring BIL is connected to the first terminal of the capacitor CA.

Note that the transistor 200 is preferably used as the transistor M1 and the capacitor 400 is preferably used as the capacitor CA. The use of the memory cell 450 including the transistor 200 and the capacitor 400 enables the area occupied by the memory cell to be reduced. Furthermore, the parasitic capacitance is reduced in the memory cell 450 as described above; thus, the operation speed can be improved. The transistor 200 that is an OS transistor has a feature of an extremely low off-state current. The use of the transistor 200 as the transistor M1 enables the leakage current of the transistor M1 to be extremely low. That is, written data can be retained for a long time with the transistor M1; thus, the frequency of refresh operation for the memory cell can be reduced. Alternatively, refresh operation for the memory cell can be unnecessary. In addition, extremely low leakage current allows multi-level data or analog data to be retained in the memory cell 951.

### [NOSRAM]

FIG. 17B illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell including an OS transistor as the transistor M2 is referred to as a NOSRAM (Nonvolatile Oxide Semiconductor RAM).

A first terminal of the transistor M2 is connected to a first terminal of the capacitor CB, a second terminal of the transistor M2 is connected to the wiring WBL, and a gate of the transistor M2 is connected to the wiring WOL. A second terminal of the capacitor CB is connected to the wiring CAL. A first terminal of the transistor M3 is connected to the wiring RBL, a second terminal of the transistor M3 is connected to a wiring SL, and a gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, during data retention, and at the time of data reading, a low-level potential (sometimes referred to as a reference potential) is preferably applied to the wiring CAL.

Data writing is performed in the following manner: a high-level potential is applied to the wiring WOL to turn on the transistor M2 so that the wiring WBL is electrically connected to the first terminal of the capacitor CB. Specifically, when the transistor M2 is in an on state, a potential corresponding to information to be stored is applied to the wiring WBL, whereby the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. Current flowing between a source and a drain of the transistor M3 and the potential of the first terminal of the transistor M3 are determined by the potential of the gate of the transistor M3 and the potential of the second terminal of the transistor M3; thus, by reading the potential of the wiring RBL connected to the first terminal of the transistor M3, the potential retained in the first terminal of the capacitor CB (or the gate of the transistor M3) can be read. In other words, information written into the memory cell can be read out from the potential retained at the first terminal of the capacitor CB (or the gate of the transistor M3).

For example, the wiring WBL and the wiring RBL may be combined into one wiring BIL. FIG. 17C illustrates a circuit structure example of the memory cell. In a memory cell 954, one wiring BIL corresponds to the wiring WBL and the wiring RBL in the memory cell 953, and the second terminal of the transistor M2 and the first terminal of the transistor M3 are connected to the wiring BIL. In other words, the memory cell 954 has a structure in which one wiring BIL operates as a write bit line and a read bit line.

Note that the transistor 200 and the capacitor 400 are preferably used as at least the transistor M2 and the capacitor CB. The OS transistor described in the above embodiment is preferably used as the transistor M2 and the transistor M3. The use of the transistor 200 and the capacitor 400 enables the area occupied by the memory cell to be reduced and the operation speed to be improved.

Since the OS transistor has a feature of an extremely low off-state current, written data can be retained for a long time with the transistor M2; thus, the frequency of refresh operation for the memory cell can be reduced. Alternatively, refresh operation for the memory cell can be unnecessary. In addition, the extremely low leakage current allows multi-level data or analog data to be retained in the memory cell 953 and the memory cell 954.

The memory cell 953 and the memory cell 954 each including the OS transistor as the transistor M2 are embodiments of a NOSRAM.

Note that a Si transistor may be used as the transistor M3. A Si transistor can have high field-effect mobility and can be a p-channel transistor, so that circuit design flexibility can be increased.

In the case where an OS transistor is used as the transistor M3, the memory cell can be composed of a single-polarity circuit.

FIG. 17D illustrates a gain-cell memory cell 957 including three transistors and one capacitor. The memory cell 957 includes a transistor M4 to a transistor M6 and a capacitor CC.

A first terminal of the transistor M4 is connected to a first terminal of the capacitor CC, a second terminal of the transistor M4 is connected to the wiring BIL, and a gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6, and a gate of the transistor M5 is connected to the first terminal of the capacitor CC. A second terminal of the transistor M6 is connected to the wiring BIL, and a gate of the transistor M6 is connected to the wiring RWL.

The wiring BIL functions as a bit line, the wiring WOL functions as a write word line, and the wiring RWL functions as a read word line. The wiring GNDL is a wiring for supplying a low-level potential.

Data writing is performed in the following manner: a high-level potential is applied to the wiring WOL to turn on the transistor M4 so that the wiring BIL is electrically connected to the first terminal of the capacitor CC. Specifically, when the transistor M4 is in an on state, a potential corresponding to information to be stored is applied to the wiring BIL, whereby the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then bringing the wiring BIL into an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; however, the potential of the second terminal of the transistor M5 and the potential of the wiring BIL change depending on the potential retained at the first terminal of the capacitor CC (or the gate of the transistor M5). Here, by reading the potential of the wiring BIL, the potential retained at the first terminal of the capacitor CC (or the gate of the transistor M5) can be read. In other words, information written into the memory cell can be read out from the potential retained at the first terminal of the capacitor CC (or the gate of the transistor M5).

Note that the transistor 200 and the capacitor 400 are preferably used as at least the transistor M4 and the capacitor CC. The use of the transistor 200 and the capacitor 400 enables the area occupied by the memory cell to be reduced and the operation speed to be improved.

Note that a Si transistor may be used as each of the transistors M5 and M6. As described above, a Si transistor has a higher field-effect mobility than an OS transistor in some cases depending on the crystal state of silicon used in a semiconductor layer, for example.

In the case where OS transistors are used as the transistors M5 and M6, the memory cell can be composed of a single-polarity circuit.

### [OS-SRAM]

FIG. 17E illustrates an example of an SRAM (Static Random Access Memory) using an OS transistor. In this specification and the like, an SRAM using an OS transistor is referred to as an OS-SRAM (Oxide Semiconductor-SRAM). Note that a memory cell 958 illustrated in FIG. 17E is a memory cell of an SRAM capable of backup.

The memory cell 958 includes a transistor M7 to a transistor M10, a transistor MS1 to a transistor MS4, a capacitor CD1, and a capacitor CD2. Note that the transistor MS1 and the transistor MS2 are p-channel transistors, and the transistor MS3 and the transistor MS4 are n-channel transistors.

A first terminal of the transistor M7 is connected to the wiring BIL, and a second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB, and a second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1 and a gate of the transistor M9 is connected to the wiring BRL. A second terminal of the transistor M10 is connected to a first terminal of the capacitor CD2 and a gate of the transistor M10 is connected to the wiring BRL.

A second terminal of the capacitor CD1 is connected to the wiring GNDL, and a second terminal of the capacitor CD2 is connected to the wiring GNDL.

The wiring BIL and the wiring BILB function as bit lines, the wiring WOL functions as a word line, and the wiring BRL controls the on state and the off state of the transistor M9 and the transistor M10.

The wiring VDL is a wiring supplying a high-level potential, and the wiring GNDL is a wiring supplying a low-level potential.

Data writing is performed by applying a high-level potential to the wiring WOL and applying a high-level potential to the wiring BRL. Specifically, when the transistor M10 is in an on state, a potential corresponding to information to be stored is applied to the wiring BIL, and the potential is written to the second terminal side of the transistor M10.

In the memory cell 958, an inverter loop is constructed by the transistor MS1 to the transistor MS2; thus, an inverted signal of a data signal corresponding to the potential is input to the second terminal side of the transistor M8. Since the transistor M8 is in an on state, an inverted signal of the potential applied to the wiring BIL, that is, the signal input to the wiring BIL is output to the wiring BILB. Since the transistor M9 and the transistor M10 are in an on state, the potential of the second terminal of the transistor M7 is retained at the first terminal of the capacitor CD2, and the potential of the second terminal of the transistor M8 is retained at the first terminal of the capacitor CD1. After that, a low-level potential is applied to the wiring WOL and a low-level potential is applied to the wiring BRL to turn off the transistor M7 to the transistor M10, whereby the potentials of the first terminal of the capacitor CD1 and the first terminal of the capacitor CD2 are retained.

Data reading is performed as follows: the wiring BIL and the wiring BILB are precharged with a predetermined potential in advance, and then a high-level potential is applied to the wiring WOL and a high-level potential is applied to the wiring BRL, whereby the potential of the first terminal of the capacitor CD1 is refreshed by the inverter loop in the memory cell 958 and is output to the wiring BILB. Moreover, the potential of the first terminal of the capacitor CD2 is refreshed by the inverter loop in the memory cell 958 and is output to the wiring BIL. Since the potentials of the wiring BIL and the wiring BILB are changed from the precharged potentials to the potential of the first terminal of the capacitor CD2 and the potential of the first terminal of the capacitor CD1, respectively, the potential retained in the memory cell can be read from the potential of the wiring BIL or the wiring BILB.

Note that the transistor 200 is preferably used as each of the transistor M7 to the transistor M10 and the capacitor 400 is preferably used as each of the capacitor CD1 and the capacitor CD2. In that case, written data can be retained for a long time with the transistor M7 to the transistor M10; thus, the frequency of refresh operation for the memory cell can be reduced. Alternatively, refresh operation for the memory cell can be unnecessary. The use of the transistor 200 as the transistor M7 to the transistor M10 and the use of the capacitor 400 as the capacitor CD1 and the capacitor CD2 enable the area occupied by the memory cell to be reduced and the operation speed to be improved.

Note that a Si transistor may be used as the transistor MS1 to the transistor MS4.

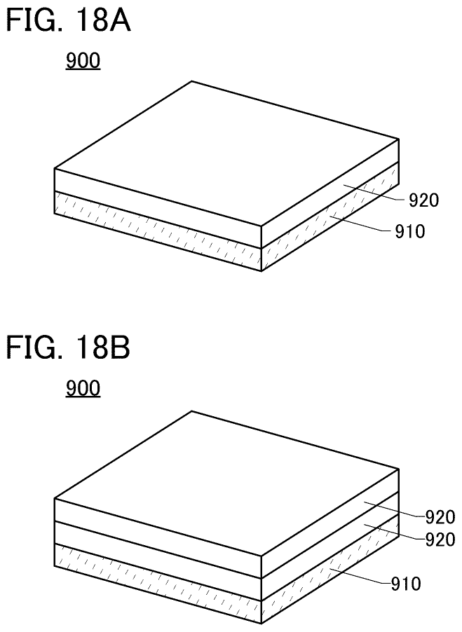

The driver circuit 910 and the memory array 920 that are included in the semiconductor device 900 may be provided on the same plane. As illustrated in FIG. 18A, the driver circuit 910 and the memory array 920 may be provided to overlap with each other. When the driver circuit 910 and the memory array 920 are provided to overlap with each other, the signal transmission distance can be shortened. Alternatively, a plurality of the memory arrays 920 may be provided over the driver circuit 910 as illustrated in FIG. 18B.

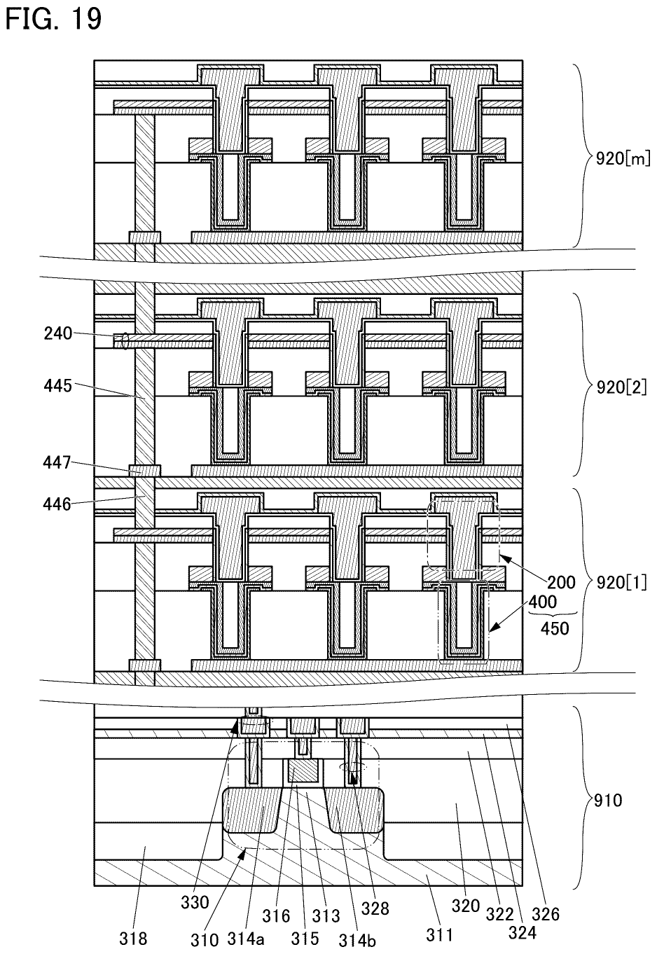

Here, an example of a structure in which a plurality of memory arrays are stacked over the driver circuit 910 is described with reference to FIG. 19. The memory device illustrated in FIG. 19 has a structure in which m layers (m is an integer greater than or equal to 2) of the memory arrays 920 each including the memory cells 450 are stacked. Here, FIG. 19 illustrates a memory array 920[1] as the layer provided in the first layer (the bottom layer), a memory array 920[2] as the layer provided in the second layer, and a memory array 920[m] as the layer provided in the m-th layer (the top layer). In other words, the memory device of one embodiment of the present invention may include a plurality of layers including the memory cells 450 and have a structure in which the plurality of layers are stacked. In each of the memory arrays 920, the conductor 446, the conductor 445, and the conductor 447 are provided as in FIG. 13.

As illustrated in FIG. 19, the conductor 446, the conductor 445, and the conductor 447 function as wirings that connect one memory array 920 provided in the upper layer and another memory array 920 provided in the lower layer. For example, the conductor 240 in the memory array 920[2] is electrically connected to the conductor 240 in the memory array 920[1] through the conductor 445, the conductor 447, and the conductor 446. As illustrated in FIG. 19, the conductor 446, the conductor 445, and the conductor 447 can be provided outside the memory array 920. Alternatively, the conductor 446, the conductor 445, and the conductor 447 can be provided in the memory array 920.

The driver circuit 910 is provided under the memory array 920. With such a structure in which a driver circuit is provided under the memory device, the area of the memory device can be increased and the memory capacity of the memory device can be increased.

FIG. 19 illustrates a transistor 310 included in the driver circuit 910 as an example. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. An element isolation layer 318 is preferably provided between adjacent transistors 310. The transistor 310 may be either a p-channel transistor or an n-channel transistor. As the substrate 311, a single crystal silicon substrate can be used, for example.

Here, in the transistor 310 illustrated in FIG. 19, the semiconductor region 313 (part of the substrate 311) in which a channel is formed has a protruding shape. The conductor 316 is provided to cover the side surface and the top surface of the semiconductor region 313 with the insulator 315 therebetween. Note that the conductor 316 may be formed using a material for adjusting the work function. The transistor 310 is also referred to as a FIN-type transistor because it utilizes a protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 310 illustrated in FIG. 19 is an example and the structure is not limited thereto; an appropriate transistor can be used in accordance with a circuit structure or a driving method.

A wiring layer provided with an interlayer film, a wiring, a plug, and the like may be provided between the memory array 920 and the driver circuit 910. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 310 as interlayer films. A conductor 328 and the like are embedded in the insulator 320 and the insulator 322. A conductor 330 and the like are embedded in the insulator 324 and the insulator 326. Note that the conductor 328 and the conductor 330 function as a contact plug or a wiring.

An insulator functioning as an interlayer film may function as a planarization film that covers an uneven shape thereunder. For example, the top surface of the insulator 322 may be planarized by CMP treatment to increase the level of planarity.

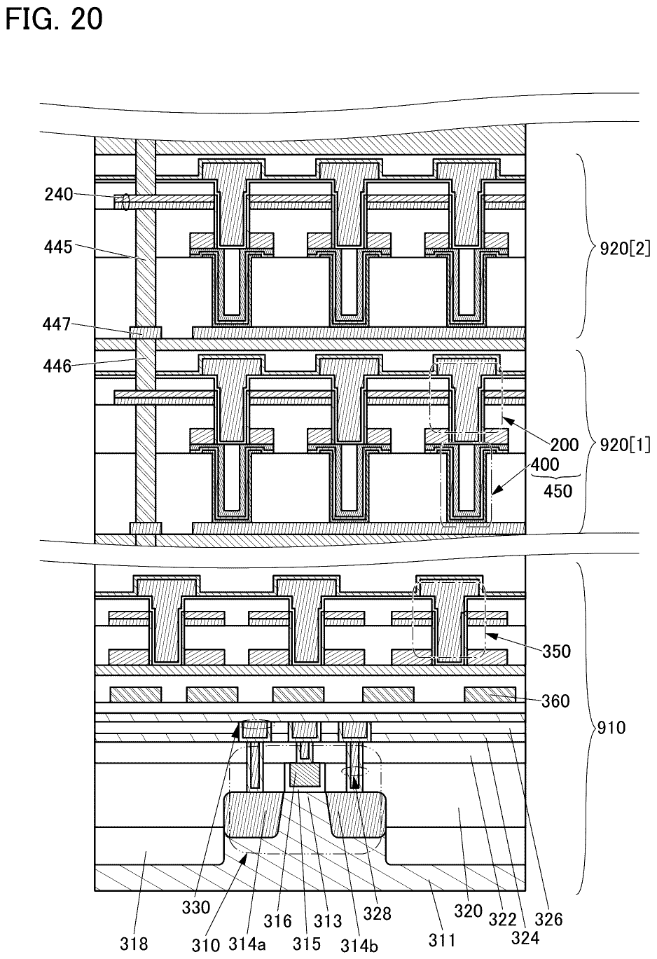

As illustrated in FIG. 20, in the driver circuit 910, a layer including a transistor 350 may be monolithically stacked over a layer including the transistor 310. Here, the transistor 350 has a structure similar to that of the transistor 200. As illustrated in FIG. 20, a wiring layer including a wiring 360 may be provided between the layer including the transistor 310 and the layer including the transistor 350. Note that although the wiring 360 in the wiring layer is a single layer in FIG. 20, the present invention is not limited thereto, and a plurality of wirings may be stacked in the wiring layer.

Here, the transistor 310 can be a p-channel MOSFET (PMOS) and the transistor 350 can be an n-channel MOSFET (NMOS). Thus, by combining the transistor 310 and the transistor 350, a CMOS (Complementary Metal Oxide Semiconductor) circuit can be formed. When the transistor 350 is provided to overlap with the transistor 310 as illustrated in FIG. 20, the area occupied by the CMOS circuit can be reduced and high integration can be achieved.

The transistor 350 can be electrically connected to the transistor 310 through the wiring layer including the wiring 360. Note that a structure can be employed in which the layer including the transistor 350 and the layer including the transistor 310 are connected to each other not through the wiring layer including the wiring 360 but through a via or the like.

Next, an example of an arithmetic processing unit that can include the semiconductor device such as the above-described memory device will be described.

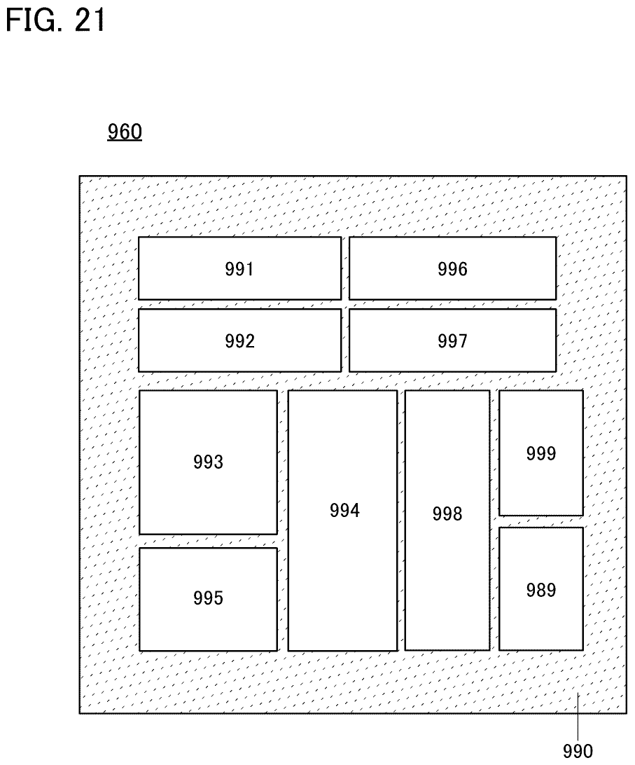

FIG. 21 is a block diagram of an arithmetic device 960. The arithmetic device 960 illustrated in FIG. 21 can be used for a CPU, for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), or an NPU (Neural Processing Unit).

The arithmetic device 960 illustrated in FIG. 21 includes, over a substrate 990, an ALU 991 (Arithmetic logic unit, arithmetic circuit), an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may include a rewritable ROM and a ROM interface. In addition, the cache 999 and the cache interface 989 may be provided in a separate chip.

The cache 999 is connected through the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in that case, the driver circuit 910 is preferably included in part of the cache interface 989.

Note that it is also possible that the cache 999 is not provided and only the memory array 920 is used as a cache.

The arithmetic device 960 illustrated in FIG. 21 is only an example with a simplified structure, and the actual arithmetic device 960 has a variety of structures depending on the application. For example, what is called a multicore structure is preferably employed in which a plurality of cores each including the arithmetic device 960 in FIG. 21 operate in parallel. The larger number of cores can further enhance the arithmetic performance. The number of cores is preferably larger; for example, the number is preferably 2, further preferably 4, still further preferably 8, yet further preferably 12, yet still further preferably 16 or more. For application requiring extremely high arithmetic performance, e.g., a server, it is preferable to employ the multicore structure including 16 or more, preferably 32 or more, further preferably 64 or more cores. The number of bits that the arithmetic device 960 can process in an internal arithmetic circuit, a data bus, or the like can be 8, 16, 32, or 64, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates the address of the register 996, and reads or writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 in FIG. 21, the register controller 997 selects operation of retaining data in the register 996 in accordance with an instruction from the ALU 991. That is, the register 996 selects whether data is stored by a flip-flop or by a capacitor in the memory cell included in the register 996. When data storing by the flip-flop is selected, a power supply voltage is supplied to the memory cell in the register 996. When data retention by the capacitor is selected, the data is rewritten into the capacitor, and supply of power supply voltage to the memory cell in the register 996 can be stopped.

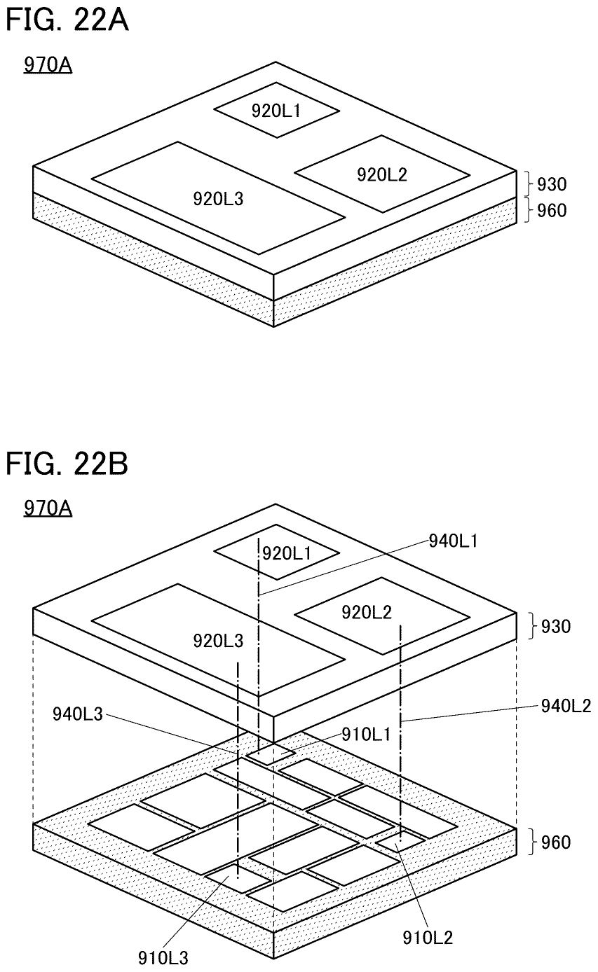

The memory array 920 and the arithmetic device 960 can be provided to overlap with each other. FIG. 22A and FIG. 22B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 includes regions overlapping with the memory arrays. For easy understanding of the structure of the semiconductor device 970A, the arithmetic device 960 and the layer 930 are separately illustrated in FIG. 22B.

Providing the arithmetic device 960 and the layer 930 including the memory arrays to overlap with each other can shorten the connection distance therebetween. Accordingly, the communication speed therebetween can be increased. Moreover, since the connection distance is short, power consumption can be reduced.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking) and a method in which the arithmetic device 960 and the layer 930 are formed over different substrates, the two substrates are bonded to each other, and the arithmetic device 960 and the layer 930 are electrically connected to each other using a through via or a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In that case, for example, the memory array 920L1 can be used as an L1 cache (also referred to as a level 1 cache), the memory array 920L2 can be used as an L2 cache (also referred to as a level 2 cache), and the memory array 920L3 can be used as an L3 cache (also referred to as a level 3 cache). Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 22B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that the case where the number of memory arrays functioning as caches is three is described here; however, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuit 910L2 and the driver circuit 910L3 may function as part of the cache interface 989 or be connected thereto.

Whether the memory array 920 functions as the cache or the main memory is determined by the control circuit 912 included in each of the driver circuits 910. The control circuit 912 can make some of the plurality of memory cells 950 included in the semiconductor device 900 function as RAM in accordance with a signal supplied from the arithmetic device 960.

In the semiconductor device 900, some of the plurality of memory cells 950 can function as the caches and other memory cells 950 can function as the main memory. That is, the semiconductor device 900 can have both the function of the cache and the function of the main memory. The semiconductor device 900 of one embodiment of the present invention can function as a universal memory, for example.

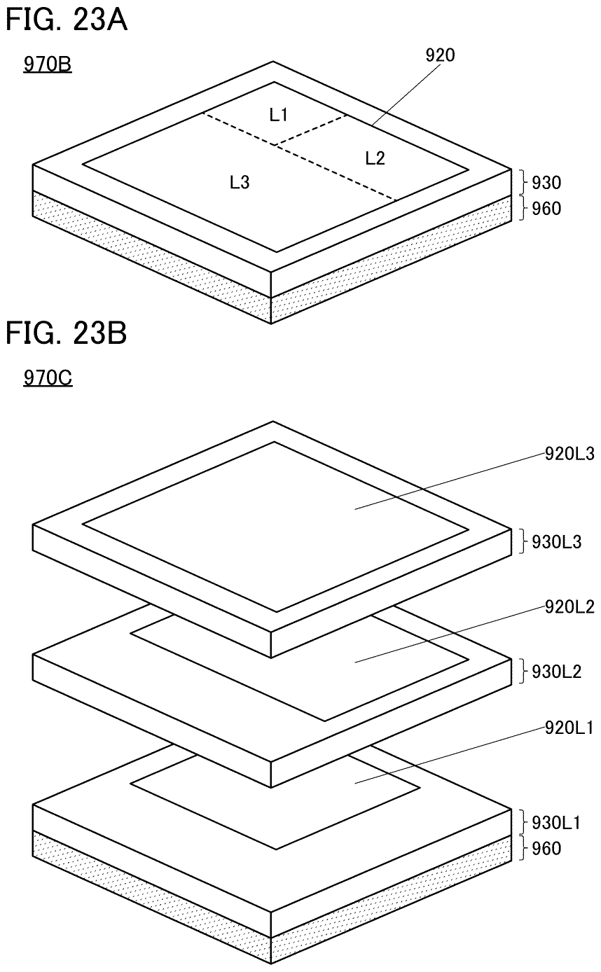

The layer 930 including one memory array 920 may be provided to overlap with the arithmetic device 960. FIG. 23A is a perspective view of a semiconductor device 970B.

In the semiconductor device 970B, one memory array 920 can be divided into a plurality of areas having different functions. FIG. 23A illustrates an example in which a region L1, a region L2, and a region L3 are used as the L1 cache, the L2 cache, and the L3 cache, respectively.

In the semiconductor device 970B, the capacity of each of the region LI to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 23B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, thereby improving processing capability.

Note that this embodiment can be combined with the other embodiments and the example in this specification as appropriate.

### Embodiment 3

In this embodiment, application examples of the memory device of one embodiment of the present invention will be described.

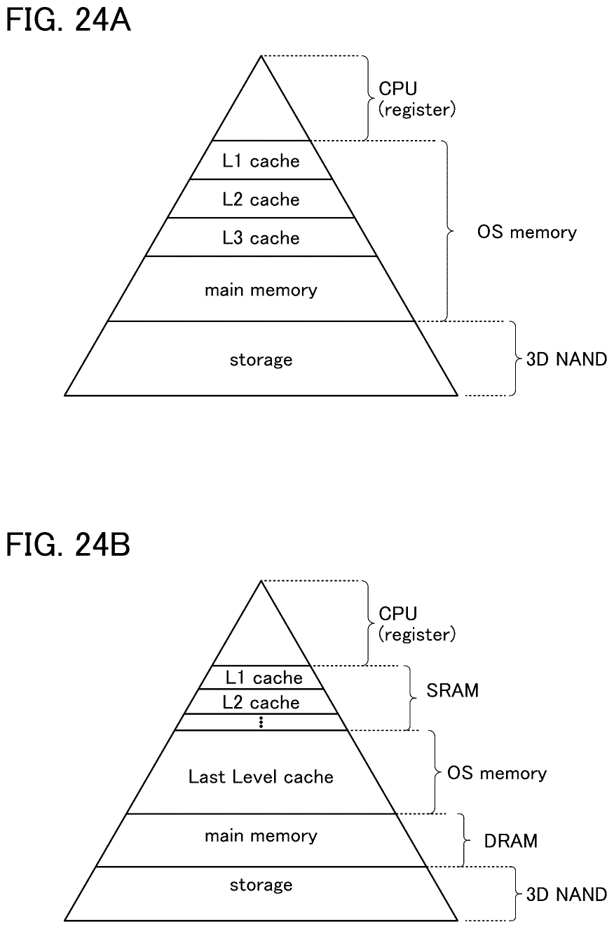

In general, a variety of memory devices are used in semiconductor devices such as computers in accordance with the intended use. FIG. 24A illustrates the hierarchy of various memory devices used in a semiconductor device. The memory devices at the upper levels require a higher operating speed, whereas the memory devices at the lower levels require a larger memory capacity and a higher memory density. FIG. 24A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may further be included.

A memory included as a register in an arithmetic processing unit such as a CPU is used for temporary storage of arithmetic operation results, for example, and thus is frequently accessed by the arithmetic processing unit. Accordingly, high operation speed is required rather than memory capacity. In addition, the register also has a function of retaining settings information of the arithmetic processing unit, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and programs used in an arithmetic processing device, for example. Therefore, a storage needs to have high memory capacity and high memory density rather than operating speed. For example, a high-capacity nonvolatile memory device such as a 3D NAND can be used.

The memory device including an oxide semiconductor (the OS memory) of one embodiment of the present invention operates at high speed and can retain data for a long time. Thus, as illustrated in FIG. 24A, the memory device of one embodiment of the present invention can be suitably used at both the level where the cache is positioned and the level where the main memory is positioned. The memory device of one embodiment of the present invention can also be used at the level where the storage is positioned.

FIG. 24B illustrates an example in which an SRAM is used as at least one of the caches and the OS memory of one embodiment of the present invention is used as the other caches Among the caches, the lowest-level cache can be referred to as an LLC (Last Level cache). The LLC does not require a higher operating speed than a higher-level cache, but desirably has a high memory capacity. The OS memory of one embodiment of the present invention operates at high speed and can retain data for a long time, and thus can be suitably used as the LLC. Note that the OS memory of one embodiment of the present invention can also be used as an FLC (Final Level cache).

For example, as illustrated in FIG. 24B, a structure can be employed in which an SRAM is used as the higher-level caches (the L1 cache, the L2 cache, and the like) and the OS memory of one embodiment of the present invention is used as the LLC. Moreover, instead of the OS memory, a DRAM can be used as the main memory as illustrated in FIG. 24B.

Note that this embodiment can be combined with the other embodiments and the example in this specification as appropriate.

### Embodiment 4

This embodiment will describe an electronic component, an electronic appliance, a large computer, space equipment, and a data center (also referred to as a DC) in which the semiconductor device described in the above embodiment can be used. An electronic appliance, a large computer, space equipment, and a data center in which the semiconductor device of one embodiment of the present invention is used are effective in improving performance, e.g., reducing power consumption.

### [Electronic Appliance]

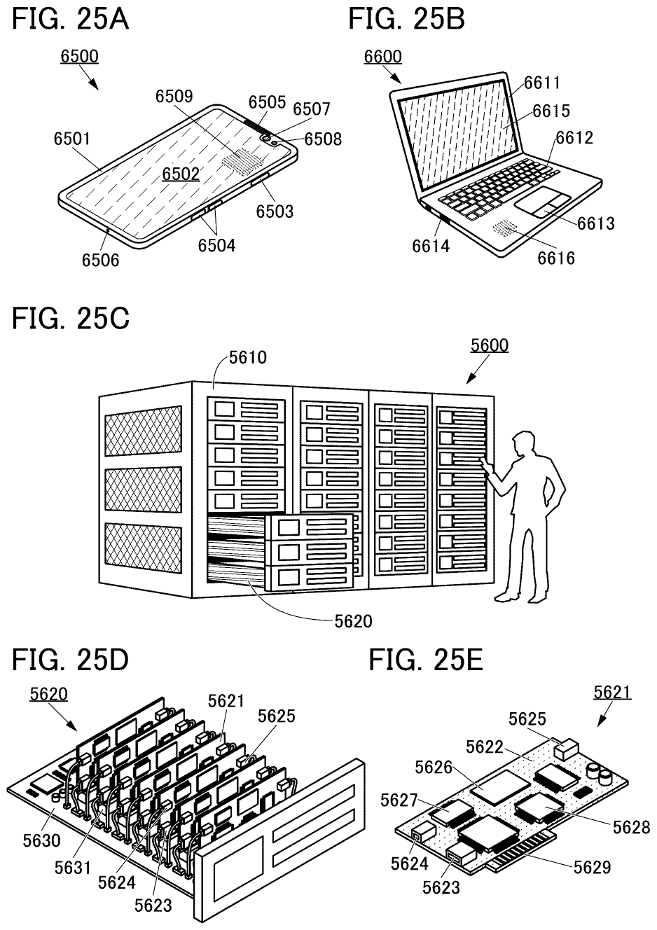

FIG. 25A is a perspective view of an electronic appliance 6500. The electronic appliance 6500 illustrated in FIG. 25A is a portable information terminal that can be used as a smartphone. The electronic appliance 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like.

An electronic appliance 6600 illustrated in FIG. 25B is an information terminal that can be used as a laptop personal computer. The electronic appliance 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 25C is a perspective view of a large computer 5600. In the large computer 5600 illustrated in FIG. 25C, a plurality of rack mount computers 5620 are stored in a rack 5610. Note that the large computer 5600 may be referred to as a supercomputer.

The computer 5620 can have a structure in a perspective view of FIG. 25D, for example. In FIG. 25D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 25E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 25E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment, such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

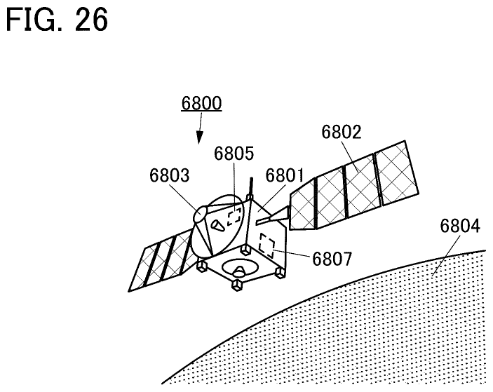

FIG. 26 illustrates an artificial satellite 6800 as an example of a device for space. The artificial satellite 6800 includes a body 6801, a solar panel 6802, an antenna 6803, a secondary battery 6805, and a control device 6807. In FIG. 26, a planet 6804 in outer space is illustrated as an example. Note that outer space refers to, for example, space at an altitude greater than or equal to 100 km, and outer space in this specification also includes thermosphere, mesosphere, and stratosphere in some cases.

Although not illustrated in FIG. 26, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment, such as a spacecraft, a space capsule, or a space probe, for example.

As described above, the OS transistor has excellent effects of achieving a wide memory bandwidth and being highly resistant to radiation as compared with the Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs an increase in building size for, for example, setting a storage and a server for storing an enormous amount of data, ensuring stable power supply for data retention, and ensuring cooling equipment for data retention.

With the use of the semiconductor device of one embodiment of the present invention for a storage system employed in a data center, electric power required for data retention can be reduced and a semiconductor device that retains data can be downsized. Accordingly, downsizing of the storage system, downsizing of the power supply for data retention, downscaling of the cooling equipment, and the like can be achieved. Therefore, space saving of the data center can be achieved.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that stably operates even in a high-temperature environment. Thus, the reliability of the data center can be increased.

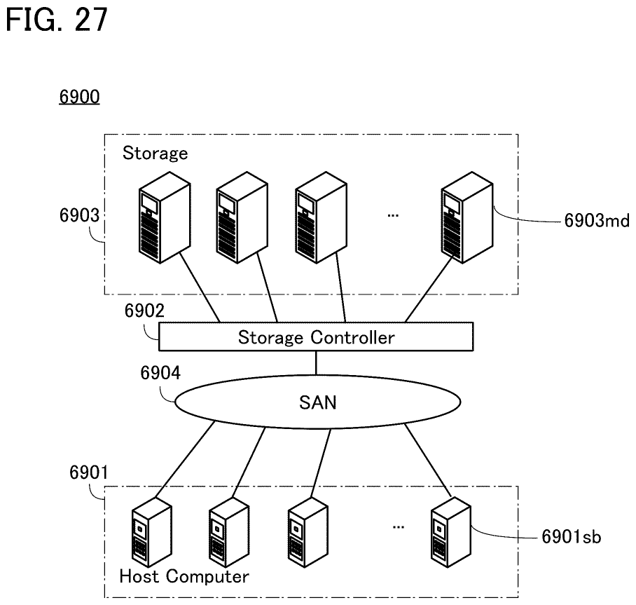

FIG. 27 illustrates a storage system that can be used in a data center. A storage system 6900 illustrated in FIG. 27 includes a plurality of servers 6901sb as a host 6901 (indicated as “Host Computer” in the diagram). The storage system 6900 includes a plurality of memory devices 6903md as a storage 6903 (indicated as “Storage” in the diagram). In the illustrated mode, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer that accesses data stored in the storage 6903. The hosts 6901 may be connected to each other through a network.

The data access speed, i.e., the time taken for storing and outputting data, of the storage 6903 is shortened by using a flash memory, but is still considerably longer than the data access speed of a DRAM that can be used as a cache memory in a storage. In the storage system, in order to solve the problem of low access speed of the storage 6903, a cache memory is normally provided in the storage to shorten the time required for data storage and output.

The above-described cache memory is used in the storage control circuit 6902 and the storage 6903. Data transmitted between the host 6901 and the storage 6903 is stored in the cache memory in the storage control circuit 6902 and the storage 6903 and then output to the host 6901 or the storage 6903.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic appliance, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO2) can be reduced with the use of the semiconductor device of one embodiment of the present invention. Furthermore, the semiconductor device of one embodiment of the present invention has low power consumption and thus is effective as a global warming countermeasure.

The configuration, structure, method, or the like described in this embodiment can be used in combination with the configuration, structure, method, or the like described in the other embodiments, examples, and the like as appropriate.

### REFERENCE NUMERALS

200a: transistor, 200b: transistor, 200: transistor, 220a: conductor, 220A: conductive film, 220b: conductor, 220: conductor, 230a: oxide semiconductor, 230b: oxide semiconductor, 230c: oxide semiconductor, 230: oxide semiconductor, 240a: conductor, 240A: conductive film, 240b: conductor, 240B: conductive film, 240: conductor, 250a: insulator, 250b: insulator, 250c: insulator, 250d: insulator, 250: insulator, 260a: conductor, 260A: conductive film, 260b: conductor, 260c: conductor, 260: conductor, 270a: insulator, 270A: insulating film, 270b: insulator, 270: insulator, 280a: insulator, 280b: insulator, 280c: insulator, 280: insulator, 283: insulator, 287A: coating film, 287: sacrificial layer, 288: insulator, 290: opening portion, 310: transistor, 311: substrate, 313: semiconductor region, 314a: low-resistance region, 314b: low-resistance region, 315: insulator, 316: conductor, 318: element isolation layer, 320: insulator, 322: insulator, 324: insulator, 326: insulator, 328: conductor, 330: conductor, 350: transistor, 360: wiring, 370a: oxide semiconductor layer, 370b: oxide semiconductor layer, 370c: oxide semiconductor layer, 370d: oxide semiconductor layer, 372a: region, 372b: region, 372c: region, 400a: capacitor, 400b: capacitor, 400: capacitor, 410a: conductor, 410b: conductor, 410: conductor, 415: conductor, 420A: conductive film, 420: conductor, 425A: insulating film, 425: insulator, 430A: insulating film, 430: insulator, 440: insulator, 445: conductor, 446: conductor, 447: conductor, 450a: memory cell, 450b: memory cell, 450: memory cell, 480a: insulator, 480b: insulator, 480: insulator, 485: insulator, 490: opening portion, 900: semiconductor device, 910: driver circuit, 911: peripheral circuit, 912: control circuit, 915: peripheral circuit, 920[1]: memory array, 920[2]: memory array, 920[m]: memory array, 920: memory array, 923: row driver, 924: column driver, 925: input circuit, 926: output circuit, 927: sense amplifier, 928: voltage generation circuit, 930: layer, 931: PSW, 932: PSW, 941: row decoder, 942: column decoder, 950: memory cell, 951: memory cell, 953: memory cell, 954: memory cell, 957: memory cell, 958: memory cell, 960: arithmetic device, 970A: semiconductor device, 970B: semiconductor device, 970C: semiconductor device, 989: cache interface, 990: substrate, 991: ALU, 992: ALU controller, 993: instruction decoder, 994: interrupt controller, 995: timing controller, 996: register, 997: register controller, 998: bus interface, 999: cache, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic appliance, 6501: housing, 6502: display portion, 6503: power button, 6504: button, 6505: speaker, 6506: microphone, 6507: camera, 6508: light source, 6509: control device, 6600: electronic appliance, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 6900: storage system, 6901sb: server, 6901: host, 6902: storage control circuit, 6903md: memory device, 6903: storage

1. A semiconductor device comprising:
a first insulator, a second insulator, a third insulator, a capacitor, and a transistor over the capacitor,
wherein the capacitor comprises a first conductor, a fourth insulator over the first conductor, and a second conductor over the fourth insulator,
wherein the first insulator is positioned over the second conductor,
wherein the second insulator is provided with a first opening portion,
wherein at least part of each of the first conductor, the fourth insulator, the second conductor, and the first insulator is positioned in the first opening portion,
wherein the transistor comprises a third conductor over the first insulator, a fourth conductor over the third conductor and the third insulator, an oxide semiconductor over the first insulator, a fifth insulator over the oxide semiconductor, and a fifth conductor over the fifth insulator,
wherein the third conductor, the third insulator, and the fourth conductor are provided with a second opening portion reaching the first insulator,
wherein at least part of each of the oxide semiconductor, the fifth insulator, and the fifth conductor is positioned in the second opening portion,
wherein the third conductor is in contact with a top surface of the second conductor,
wherein the oxide semiconductor is in contact with a side surface of the third conductor and a side surface of the fourth conductor, and
wherein the fifth conductor is positioned to overlap with the first insulator.
wherein at least part of a bottom surface of the oxide semiconductor is removed in the second opening portion.

3. The semiconductor device according to claim 2,
wherein the fifth insulator is in contact with a top surface of the first insulator.

4. The semiconductor device according to claim 3,
wherein the fourth conductor comprises a first layer and a second layer over the first layer,
wherein the first layer has higher conductivity than the second layer, and
wherein the second layer comprises a metal oxide.

5. The semiconductor device according to claim 4,
wherein the first layer comprises tungsten.

6. The semiconductor device according to claim 5,
wherein the second layer comprises indium.

7. The semiconductor device according to claim 4,
wherein a sixth insulator is positioned between the second layer and the fifth conductor.

8. The semiconductor device according to claim 1,
wherein the third conductor comprises a metal oxide.

9. The semiconductor device according to claim 8,
wherein the third conductor comprises indium.

10. The semiconductor device according to claim 8,
wherein the fourth insulator comprises a metal oxide comprising hafnium and zirconium.

11. The semiconductor device according to claim 8,
wherein a width of the first opening portion in a vicinity of the top surface of the first insulator is larger than a width of the first opening portion in a vicinity of a bottom surface of the first insulator.

12. The semiconductor device according to claim 8,
wherein a depth of the first opening portion is larger than a depth of the second opening portion.

13. The semiconductor device according to claim 8,
wherein the top surface of the first insulator and the top surface of the second conductor are flush with each other.

14. The semiconductor device according to claim 8,
wherein a side surface of the second conductor, a side surface of the fourth insulator, and the side surface of the third conductor are flush with each other.
